(19) United States
(12) Patent Application Publication
(10) Pub. No.: US 2019/0348537 A1
(43) Pub. Date: Nov. 14, 2019

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tomoki HIRAMATSU, Koto (JP); Ryunosuke HONDA, Isehara (JP)

(21) Appl. No.: 16/473,086

(22) PCT Filed: Dec. 14, 2017
(86) PCT No.: PCT/IB2017/057921

§ 371 Date: Jun. 24, 2019

(30) Foreign Application Priority Data
Dec. 27, 2016 (JP) 2016-253737

(51) Int. Cl. H01L 29/786; H01L 29/24; H01L 29/66; H01L 27/105; H01L 27/12

(52) U.S. Cl. CPC H01L 29/7869; H01L 29/24; H01L 29/78648; H01L 29/78696; H01L 27/1255; H01L 27/1052; H01L 27/1207; H01L 27/1225; H01L 27/124; H01L 29/66969

(57) ABSTRACT

A semiconductor device with a high on-state current is provided. The semiconductor device includes a first conductor over a substrate, a first insulator over the first conductor, a first oxide over the first insulator, a second oxide over the first oxide, a second insulator in contact with top and side surfaces of the second oxide, a second conductor over the second insulator, and a third insulator in contact with side surfaces of the second insulator and the second conductor. The thickness of the second oxide is greater than or equal to the length of the second oxide in a channel width direction. The second conductor has a region facing the top and side surfaces of the second oxide with the second insulator positioned therebetween. The carrier density of the side surface of the second oxide is higher than that of the top surface of the second oxide.

### TECHNICAL FIELD

One embodiment of the present invention relates to a semiconductor device and a manufacturing method thereof. Another embodiment of the present invention relates to a semiconductor wafer, a module, and an electronic device.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like may include a semiconductor device.

Note that one embodiment of the present invention is not limited to the above technical field. One embodiment of the invention disclosed in this specification and the like relates to an object, a method, or a manufacturing method. Furthermore, one embodiment of the present invention relates to a process, a machine, manufacture, or a composition of matter.

### BACKGROUND ART

In recent years, semiconductor devices have been developed to be used mainly for an LSI, a CPU, or a memory. A CPU is an aggregation of semiconductor elements each provided with an electrode which is a connection terminal, which includes a semiconductor integrated circuit (including at least a transistor and a memory) separated from a semiconductor wafer.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is applied to a wide range of electronic devices such as an integrated circuit (IC) or an image display device (also simply referred to as a display device). A silicon-based semiconductor material is widely known as a material for a semiconductor thin film applicable to the transistor; in addition, an oxide semiconductor has attracted attention as another material.

It is known that a transistor including an oxide semiconductor has an extremely low leakage current in an off state. For example, a low-power-consumption CPU utilizing a characteristic of low leakage current of the transistor including an oxide semiconductor has been disclosed (see Patent Document 1).

In addition, a technique in which oxide semiconductor layers with different electron affinities (or conduction band minimum states) are stacked to increase the carrier mobility of a transistor is disclosed (see Patent Documents 2 and 3).

In recent years, demand for an integrated circuit in which transistors and the like are integrated with high density has risen with reductions in the size and weight of an electronic device. In addition, the productivity of a semiconductor device including an integrated circuit is required to be improved.

### REFERENCE

### Patent Document

[Patent Document 1] Japanese Published Patent Application No. 2012-257187
[Patent Document 2] Japanese Published Patent Application No. 2011-124360
[Patent Document 3] Japanese Published Patent Application No. 2011-138934

### DISCLOSURE OF INVENTION

An object of one embodiment of the present invention is to provide a semiconductor device with a high on-state current. Another object of one embodiment of the present invention is to provide a semiconductor device that can be miniaturized or highly integrated. Another object of one embodiment of the present invention is to provide a semiconductor device with high frequency characteristics. Another object of one embodiment of the present invention is to provide a semiconductor device with normally-off electrical characteristics. Another object of one embodiment of the present invention is to provide a semiconductor device with favorable electrical characteristics. Another object of one embodiment of the present invention is to provide a semiconductor device that can be manufactured with high productivity.

Another object of one embodiment of the present invention is to provide a semiconductor device capable of retaining data for a long time. Another object of one embodiment of the present invention is to provide a semiconductor device capable of high-speed data writing. Another object of one embodiment of the present invention is to provide a semiconductor device with high design flexibility. Another object of one embodiment of the present invention is to provide a semiconductor device with low power consumption. Another object of one embodiment of the present invention is to provide a novel semiconductor device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a semiconductor device including a first conductor over a substrate, a first insulator over the first conductor, a first oxide over the first insulator, a second oxide over the first oxide, a second insulator in contact with a top surface and a side surface of the second oxide, a second conductor over the second insulator, and a third insulator in contact with a side surface of the second insulator and a side surface of the second conductor. A thickness of the second oxide is greater than or equal to a length of the second oxide in a channel width direction. The second conductor has a region facing the top surface and the side surface of the second oxide with the second insulator positioned therebetween. A carrier density of the side surface of the second oxide is higher than a carrier density of the top surface of the second oxide.

Another embodiment of the present invention is a semiconductor device including a first conductor over a substrate, a first insulator over the first conductor, a first oxide over the first insulator, a second oxide over the first oxide, a third oxide in contact with a side surface of the first oxide and a side surface of the second oxide, a second insulator in contact with a top surface of the second oxide and a side surface of the third oxide, a second conductor over the second insulator, and a third insulator in contact with a side surface of the second insulator and a side surface of the second conductor. A thickness of the second oxide is greater than or equal to a length of the second oxide in a channel width direction. The second conductor has a region facing the top surface and the side surface of the second oxide with the second insulator positioned therebetween. A carrier density of the side surface of the second oxide is higher than a carrier density of the top surface of the second oxide. A conduction band minimum of the third oxide is higher than a conduction band minimum of the second oxide.

In the above semiconductor device, the second oxide preferably has a curved surface between the side surface and the top surface of the second oxide. Furthermore, the curved surface of the second oxide preferably has a radius of curvature greater than or equal to 3 nm and less than or equal to 10 nm.

In the above semiconductor device, the second insulator preferably has a smaller thickness in a region near the side surface of the second oxide than in a region near the top surface of the second oxide.

In the above semiconductor device, the second oxide preferably includes a crystal structure having c-axis alignment. In the above semiconductor device, a conduction band minimum of the first oxide is preferably higher than the conduction band minimum of the second oxide. In the above semiconductor device, each of the first oxide and the second oxide preferably contains In, an element M (M is Al, Ga, Y, or Sn), and Zn. An atomic ratio of In to the element M in the second oxide is preferably greater than an atomic ratio of In to the element Min the first oxide.

In the above semiconductor device, each of the first oxide and the second oxide preferably has a tapered cross-sectional shape.

In the above semiconductor device, the second oxide preferably has alternately stacked first layers and second layers. A band gap of each of the first layers is larger than a band gap of each of the second layers.

One embodiment of the present invention can provide a semiconductor device with a high on-state current. One embodiment of the present invention can provide a semiconductor device that can be miniaturized or highly integrated. One embodiment of the present invention can provide a semiconductor device with high frequency characteristics. One embodiment of the present invention can provide a semiconductor device with normally-off electrical characteristics. One embodiment of the present invention can provide a semiconductor device with favorable electrical characteristics. One embodiment of the present invention can provide a semiconductor device that can be manufactured with high productivity.

A semiconductor device capable of retaining data for a long time can be provided. A semiconductor device capable of high-speed data writing can be provided. A semiconductor device with high design flexibility can be provided. A semiconductor device with low power consumption can be provided. A novel semiconductor device can be provided.

Note that the description of these effects does not preclude the existence of other effects. One embodiment of the present invention does not have to have all the effects listed above. Other effects will be apparent from and can be derived from the description of the specification, the drawings, the claims, and the like.

### BRIEF DESCRIPTION OF DRAWINGS

FIGS. 1A to 1C are a perspective view and cross-sectional views of a semiconductor device of one embodiment of the present invention.

FIG. 2 is a cross-sectional view of a semiconductor device of one embodiment of the present invention.

FIGS. 3A to 3C are a top view and cross-sectional views of a semiconductor device of one embodiment of the present invention.

FIGS. 4A to 4C are a top view and cross-sectional views illustrating a method for manufacturing a semiconductor device of one embodiment of the present invention.

FIGS. 5A to 5C are a top view and cross-sectional views illustrating a method for manufacturing a semiconductor device of one embodiment of the present invention.

FIGS. 6A to 6C are a top view and cross-sectional views illustrating a method for manufacturing a semiconductor device of one embodiment of the present invention.

FIGS. 7A to 7C are a top view and cross-sectional views illustrating a method for manufacturing a semiconductor device of one embodiment of the present invention.

FIGS. 8A to 8C are a top view and cross-sectional views illustrating a method for manufacturing a semiconductor device of one embodiment of the present invention.

FIGS. 9A to 9C are a top view and cross-sectional views illustrating a method for manufacturing a semiconductor device of one embodiment of the present invention.

FIGS. 10A to 10C are a top view and cross-sectional views illustrating a method for manufacturing a semiconductor device of one embodiment of the present invention.

FIGS. 11A to 11C are a top view and cross-sectional views illustrating a method for manufacturing a semiconductor device of one embodiment of the present invention.

FIGS. 12A to 12C are a top view and cross-sectional views of a semiconductor device of one embodiment of the present invention.

FIGS. 13A to 13C are a top view and cross-sectional views of a semiconductor device of one embodiment of the present invention.

FIGS. 14A to 14C are a top view and cross-sectional views of a semiconductor device of one embodiment of the present invention.

FIGS. 15A to 15C are a top view and cross-sectional views of a semiconductor device of one embodiment of the present invention.

FIGS. 16A to 16C are a top view and cross-sectional views of a semiconductor device of one embodiment of the present invention.

FIGS. 17A to 17C each illustrate an atomic ratio range of a metal oxide of the present invention.

FIG. 18 is a cross-sectional view illustrating a structure of a memory device of one embodiment of the present invention.

FIG. 19 is a block diagram illustrating a configuration example of a memory device of one embodiment of the present invention.

FIGS. 20A and 20B are a block diagram and a circuit diagram each illustrating a configuration example of a memory device of one embodiment of the present invention.

FIGS. 21A to 21C are block diagrams each illustrating a configuration example of a semiconductor device of one embodiment of the present invention.

FIGS. 22A and 22B are a block diagram and a circuit diagram each illustrating a configuration example of a semiconductor device of one embodiment of the present invention, and

FIG. 22C is a timing chart showing an operation example of the semiconductor device.

FIG. 23 is a block diagram illustrating a configuration example of a semiconductor device of one embodiment of the present invention.

FIG. 24A is a circuit diagram illustrating a configuration example of a semiconductor device of one embodiment of the present invention, and FIG. 24B is a timing chart showing an operation example of the semiconductor device.

FIG. 25 is a block diagram illustrating a semiconductor device of one embodiment of the present invention.

FIG. 26 is a circuit diagram illustrating a semiconductor device of one embodiment of the present invention.

FIGS. 27A and 27B are top views of a semiconductor wafer of one embodiment of the present invention.

FIGS. 28A and 28B are a flow chart showing an example of steps for manufacturing electronic components and a schematic perspective view thereof.

FIGS. 29A to 29F each illustrate an electronic device of one embodiment of the present invention.

FIG. 30 is a graph showing calculation results of the on-state current of transistors in Example.

### BEST MODE FOR CARRYING OUT THE INVENTION

Hereinafter, embodiments will be described with reference to drawings. Note that the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings are schematic views illustrating ideal examples, and embodiments of the present invention are not limited to shapes or values shown in the drawings. For example, in the actual manufacturing process, a layer, a resist mask, or the like might be unintentionally reduced in size by treatment such as etching, which is not illustrated in some cases for easy understanding. In the drawings, the same portions or portions having similar functions are denoted by the same reference numerals in different drawings, and explanation thereof will not be repeated in some cases. Furthermore, the same hatching pattern is applied to portions having similar functions, and the portions are not denoted by reference numerals in some cases.

Especially in a top view (also referred to as a “plan view”), a perspective view, or the like, some components might not be illustrated for easy understanding of the invention. In addition, some hidden lines and the like might not be shown.

Note that the ordinal numbers such as “first,” “second,” and the like in this specification and the like are used for convenience and do not denote the order of steps or the stacking order of layers. Therefore, for example, description can be made even when “first” is replaced with “second” or “third,” as appropriate. In addition, the ordinal numbers in this specification and the like are not necessarily the same as those which specify one embodiment of the present invention.

In this specification, terms for describing arrangement, such as “over,” “above,” “under,” and “below,” are used for convenience in describing a positional relation between components with reference to drawings. Furthermore, the positional relationship between components is changed as appropriate depending on the direction in which each component is described. Thus, there is no limitation on terms used in this specification, and description can be made appropriately depending on the situation.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, or a load) is not connected between X and Y, and the case where X and Y are connected without the element that allows the electrical connection between X and Y provided therebetween.

For example, in the case where X and Y are electrically connected, one or more elements that allow an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is turned on or off to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that allow a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

In this specification and the like, a transistor is an element having at least three terminals of a gate, a drain, and a source. The transistor has a channel formation region between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when a transistor of opposite polarity is employed or the direction of current flow is changed in circuit operation, for example. Therefore, the terms “source” and “drain” can be switched in some cases in this specification and the like.

Note that the channel length refers to, for example, the distance between a source (a source region or a source electrode) and a drain (a drain region or a drain electrode) in a region where a semiconductor (or a portion where current flows in a semiconductor when a transistor is on) and a gate electrode overlap with each other or a region where a channel is formed in a plan view of the transistor. In one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

The channel width refers to, for example, the length of a portion where a source and a drain face each other in a region where a semiconductor (or a portion where current flows in a semiconductor when a transistor is on) and a gate electrode overlap with each other, or a region where a channel is formed. In one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter referred to as an “effective channel width”) is different from a channel width shown in a top view of a transistor (hereinafter referred to as an “apparent channel width”) in some cases. For example, in a transistor having a gate electrode covering the side surface of a semiconductor, an effective channel width is greater than an apparent channel width, and its influence cannot be ignored in some cases. For example, in a miniaturized transistor having a gate electrode covering the side surface of a semiconductor, the proportion of a channel formation region formed in the side surface of a semiconductor is increased. In that case, an effective channel width is greater than an apparent channel width.

In such a case, an effective channel width is difficult to measure in some cases. For example, to estimate an effective channel width from a design value, it is necessary to assume that the shape of a semiconductor is known as an assumption condition. Accordingly, in the case where the shape of a semiconductor is not known accurately, it is difficult to measure an effective channel width accurately.

Thus, in this specification, an apparent channel width is referred to as a surrounded channel width (SCW) in some cases. Furthermore, in this specification, in the case where the term “channel width” is simply used, it may represent a surrounded channel width or an apparent channel width. Alternatively, in this specification, in the case where the term “channel width” is simply used, it may represent an effective channel width. Note that a channel length, a channel width, an effective channel width, an apparent channel width, a surrounded channel width, and the like can be determined by analyzing a cross-sectional TEM image and the like.

Note that an impurity in a semiconductor refers to, for example, elements other than the main components of a semiconductor. For example, an element with a concentration lower than 0.1 atomic % can be regarded as an impurity. When an impurity is contained, the density of states (DOS) in a semiconductor may be increased, or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; there are hydrogen, lithium, sodium, silicon, boron, phosphorus, carbon, and nitrogen, for example. For an oxide semiconductor, water also serves as an impurity in some cases. For an oxide semiconductor, entry of impurities may lead to formation of oxygen vacancies, for example. Furthermore, when the semiconductor is silicon, examples of an impurity which changes the characteristics of the semiconductor include oxygen, Group 1 elements except hydrogen, Group 2 elements, Group 13 elements, and Group 15 elements.

In this specification and the like, a silicon oxynitride film contains more oxygen than nitrogen. A silicon oxynitride film preferably contains, for example, oxygen, nitrogen, silicon, and hydrogen in the ranges of 55 atomic % to 65 atomic % inclusive, 1 atomic % to 20 atomic % inclusive, 25 atomic % to 35 atomic % inclusive, and 0.1 atomic % to 10 atomic % inclusive, respectively. A silicon nitride oxide film contains more nitrogen than oxygen. A silicon nitride oxide film preferably contains nitrogen, oxygen, silicon, and hydrogen in the ranges of 55 atomic % to 65 atomic % inclusive, 1 atomic % to 20 atomic % inclusive, 25 atomic % to 35 atomic % inclusive, and 0.1 atomic % to 10 atomic % inclusive, respectively.

In this specification and the like, the terms “film” and “layer” can be interchanged with each other. For example, the term “conductive layer” can be changed into the term “conductive film” in some cases. Also, the term “insulating film” can be changed into the term “insulating layer” in some cases.

In addition, in this specification and the like, the term “insulator” can be replaced with the term “insulating film” or “insulating layer.” Moreover, the term “conductor” can be replaced with the term “conductive film” or “conductive layer.” Furthermore, the term “semiconductor” can be replaced with the term “semiconductor film” or “semiconductor layer.”

Furthermore, unless otherwise specified, transistors described in this specification and the like are field effect transistors. Unless otherwise specified, transistors described in this specification and the like are n-channel transistors. Thus, unless otherwise specified, the threshold voltage (also referred to as “Vₜₕ”) is higher than 0 V.

In this specification and the like, the term “parallel” indicates that the angle formed between two straight lines is greater than or equal to −10° and less than or equal to 10°, and accordingly also includes the case where the angle is greater than or equal to −5° and less than or equal to 5°. In addition, the term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly also includes the case where the angle is greater than or equal to 85° and less than or equal to 95°. In addition, the term “substantially perpendicular” indicates that the angle formed between two straight lines is greater than or equal to 60° and less than or equal to 120°.

In this specification, trigonal and rhombohedral crystal systems are included in a hexagonal crystal system.

Note that in this specification, a barrier film refers to a film having a function of inhibiting the penetration of oxygen and impurities such as hydrogen. The barrier film that has conductivity may be referred to as a conductive barrier film.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. In other words, an OS FET is a transistor including an oxide or an oxide semiconductor.

### Embodiment 1

An example of a semiconductor device including a transistor 200 of one embodiment of the present invention will be described below.

### <Structure Example 1 of Semiconductor Device>

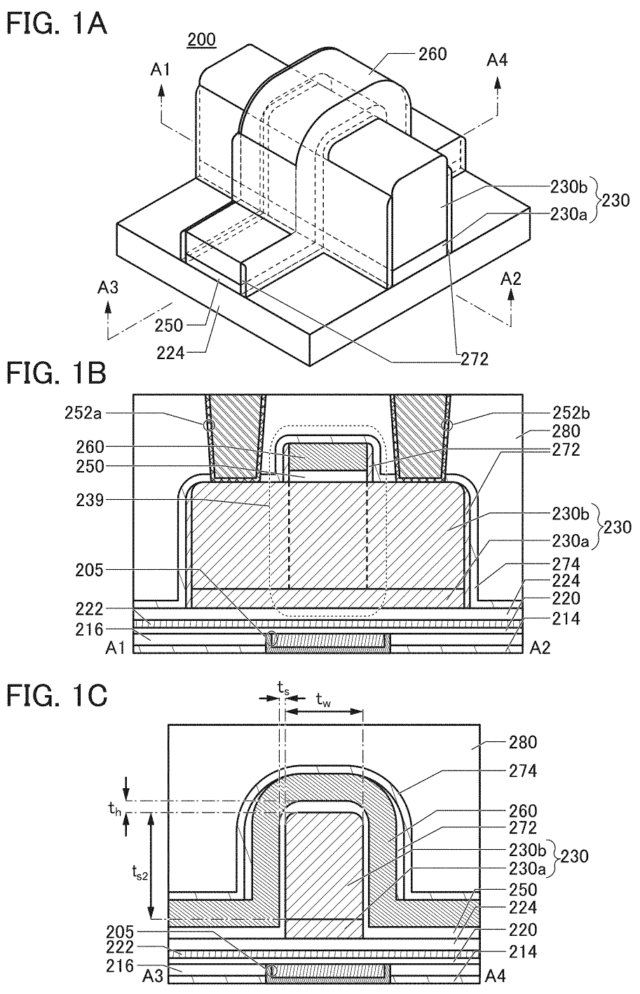

FIGS. 1A to 1C are a perspective view and cross-sectional views illustrating the transistor 200 of one embodiment of the present invention and the periphery thereof.

FIG. 1A is a perspective view of the semiconductor device including the transistor 200. FIGS. 1B and 1C are cross-sectional views illustrating the semiconductor device. FIG. 1B is a cross-sectional view taken along dashed-dotted line A1-A2 in FIG. 1A, which corresponds to a cross-sectional view in the channel length direction of the transistor 200. FIG. 1C is a cross-sectional view taken along dashed-dotted line A3-A4 in FIG. 1A, which corresponds to a cross-sectional view in the channel width direction of the transistor 200. For simplification of the drawing, some components are not illustrated in the perspective view in FIG. 1A.

The semiconductor device of one embodiment of the present invention includes the transistor 200, an insulator 280 functioning as an interlayer film, and conductors 252 (a conductor 252a and a conductor 252b) functioning as plugs that are electrically connected to the transistor 200.

The conductors 252 are in contact with inner walls of openings in the insulator 280.

Here, the top surfaces of the conductors 252 can be substantially level with the top surface of the insulator 280. Note that although the conductors 252 in the transistor 200 each have a single-layer structure, one embodiment of the present invention is not limited thereto. For example, the conductors 252 may each have a stacked-layer structure of two or more layers.

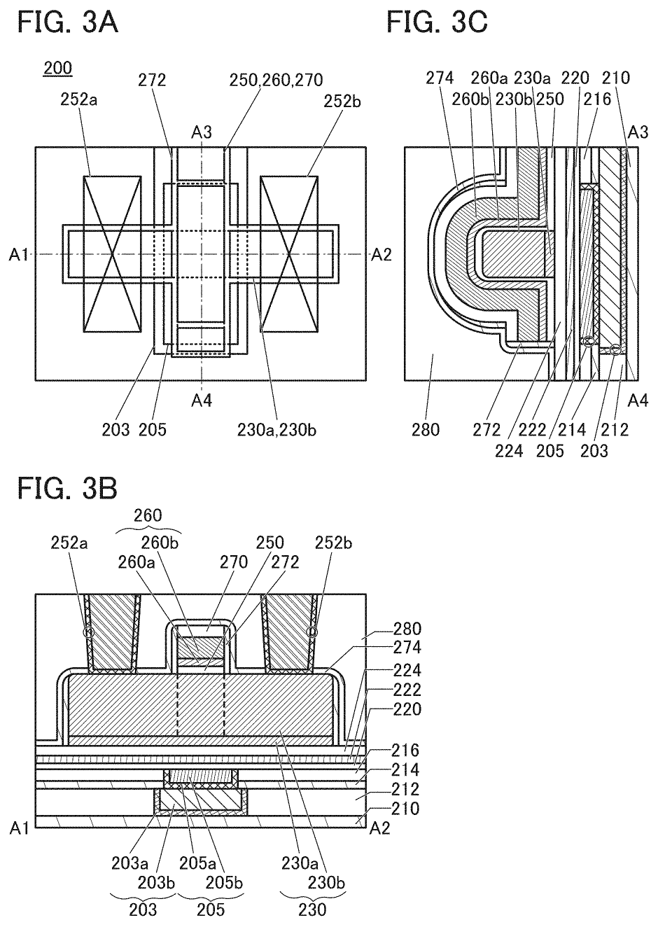

FIGS. 3A to 3C illustrate a structure of the semiconductor device illustrated in FIGS. 1A to 1C, which further includes a wiring and the like. FIG. 3A is a top view of the semiconductor device including the transistor 200. FIGS. 3B and 3C are cross-sectional views illustrating the semiconductor device. FIG. 3B is a cross-sectional view taken along dashed-dotted line A1-A2 in FIG. 3A, which corresponds to a cross-sectional view in the channel length direction of the transistor 200. FIG. 3C is a cross-sectional view taken along dashed-dotted line A3-A4 in FIG. 3A, which corresponds to a cross-sectional view in the channel width direction of the transistor 200. For simplification of the drawing, some components are not illustrated in the top view in FIG. 3A.

The semiconductor device of one embodiment of the present invention may include the transistor 200 and an insulator 210 and an insulator 212 functioning as interlayer films, as illustrated in FIGS. 3A to 3C. Furthermore, a conductor 203 (including a conductor 203a and a conductor 203b) functioning as a wiring that is electrically connected to the transistor 200 may be included.

The conductor 203 includes the conductor 203a that is in contact with an inner wall of an opening of the insulator 212 and the conductor 203b positioned on an inner side than the conductor 203a. Here, the top surface of the conductor 203 can be substantially level with the top surface of the insulator 212. Although the conductors 203a and 203b are stacked in the transistor 200, one embodiment of the present invention is not limited to this structure. For example, a structure in which only the conductor 203b may be employed.

### [Transistor 200]

As illustrated in FIGS. 1A to 1C, the transistor 200 includes a conductor 205 over a substrate (not illustrated); an insulator 220, an insulator 222, and an insulator 224 over the conductor 205; an oxide 230a over the insulator 224; an oxide 230b over the oxide 230a; an insulator 250 in contact with the top surface and a side surface of the oxide 230b; a conductor 260 over the insulator 250; and an insulator 272 in contact with a side surface of the insulator 250 and a side surface of the conductor 260. As illustrated in FIGS. 1A and 1C, the conductor 260 has a region that faces the top and side surfaces of the oxide 230b with the insulator 250 positioned therebetween. Hereinafter, the oxide 230a and the oxide 230b are collectively expressed as an oxide 230, in some cases.

As illustrated in FIG. 1C, a thickness tₛ₂ of the oxide 230b is greater than or equal to a length tw of the oxide 230b in the channel width direction. In addition, a thickness is of the insulator 250 around the side surface of the oxide 230b is smaller than a thickness to of the insulator 250 around the top surface of the oxide 230b.

Furthermore, the oxide 230b has a curved surface between its side surface and top surface. The curved surface preferably has a radius of curvature greater than or equal to 3 nm and less than or equal to 10 nm.

The conductor 205 is preferably embedded in an insulator 214 and an insulator 216 provided over the substrate, as illustrated in FIGS. 1A to 1C. The insulator 220 is preferably provided over the insulator 216 and the conductor 205, the insulator 222 is preferably provided over the insulator 220, and the insulator 224 is preferably provided over the insulator 222. As illustrated in FIGS. 3A to 3C, an insulator 270 may be provided over the conductor 260. It is preferable to provide an insulator 274 in contact with the oxide 230 and the insulator 272.

Although the transistor 200 has a structure in which the oxide 230a and the oxide 230b are stacked, one embodiment of the present invention is not limited thereto. For example, a stacked-layer structure of three or more layers, or a single-layer structure of the oxide 230b may be employed. As illustrated in FIGS. 3A to 3C, the conductor 260 may have a stacked-layer structure of a conductor 260a and a conductor 260b or a single-layer structure of the conductor 260b. Furthermore, as illustrated in FIGS. 3A to 3C, the conductor 205 may have a stacked-layer structure of a conductor 205a and a conductor 205b or a single-layer structure of the conductor 205b.

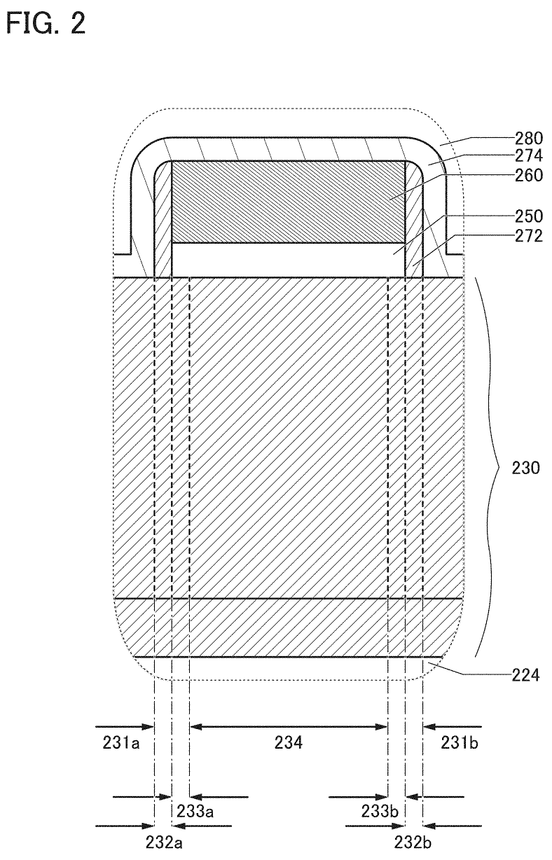

FIG. 2 is an enlarged view illustrating a region 239 including a channel and the vicinity thereof, which is surrounded by a dashed line in FIG. 1B. As illustrated in FIG. 2, the oxide 230 has regions 231 (a region 231a and a region 231b), regions 232 (a region 232a and a region 232b), regions 233 (a region 233a and a region 233b), and a region 234.

The regions 231, 232, and 233 each have a high carrier density and reduced resistance. In particular, in the case where the regions 231 each have a higher carrier density than the other regions, the regions 231 function as source and drain regions. Furthermore, since the region 234 has a lower carrier density than the other regions, at least part of the region 234 functions as a channel formation region in some cases.

The regions 232 and 233 are regions provided between the channel formation region and the source and drain regions. The regions 233 have a higher carrier density than the region 234 and a lower carrier density than the regions 232 and 231. The regions 232 have a higher carrier density than the regions 234 and 233 and a lower carrier density than the regions 231.

When the regions 232 and 233 are provided, a high-resistance region is not formed between the region 234 where a channel is formed and each of the regions 231 functioning as the source and drain regions; thus, the on-state current of the transistor can be increased.

The regions 233 function as overlap regions (also referred to as Lov regions) which overlap with the conductor 260 that functions as a gate electrode, in some cases.

The transistor 200 described in this embodiment is what is called a fin transistor in which a cross section of a structure including the insulator 224 serving as a base insulating film and the oxide 230 is a protrusion shape and the gate is provided to cover the top and side surfaces of the oxide 230, as mentioned above. Note that a fin transistor including an oxide semiconductor is also called OS-FIN.

In such a fin transistor, not only the top surface of the oxide 230 but also the side surface of the oxide 230 can function as a channel. Since channels are formed in the side surfaces on the A3 side and the A4 side and in the top surface of the oxide 230, an effective channel width is at least three or more times greater than the length tw of the oxide 230 in the channel width direction. Note that a channel formed in the side surface of the oxide 230 can be referred to as a side channel, and channels formed in the side surfaces of the oxide 230 on the A3 and A4 sides can be collectively referred to as a dual side channel. In addition, a channel formed in the top surface of the oxide 230 can be referred to as a top channel.

Furthermore, since the thickness tₛ of the insulator 250 around the side surface of the oxide 230b is smaller than the thickness tₕ of the insulator 250 around the top surface of the oxide 230b, the carrier density of the side surface of the oxide 230b is higher than the carrier density of the top surface of the oxide 230b. This means that the dual side channel contributes to the on-state current of the transistor 200 more than the top channel does.

Note that the oxide 230, in particular, the oxide 230b, preferably has a layered crystal structure. It is further preferable to have, for example, a crystal structure that has c-axis alignment and an a-b plane and is formed of a plurality of nanocrystals, such as a CAAC-OS described later. The a-b plane of the oxide 230 is substantially parallel to a substrate surface.

Voltage V_{g} is applied to the oxide 230 having such a structure via the gate that faces the side surfaces of the oxide 230 (such a gate can be referred to as a dual gate). At this time, the voltage V_{g} is applied along the a-b plane, and current flows in the dual side channel along the a-b plane of the oxide 230.

Here, electric fields are applied from two opposing directions along the a-b plane. Furthermore, an electric field is also applied to the bulk of the oxide 230 because of the electric fields, and bulk current flows between a source and a drain. This bulk current can be referred to as bulk flow.

Note that layered crystals parallel to the a-b plane of the oxide 230 is formed of a metal element M (e.g., an indium atom) and an oxygen atom. In the above structure, even when a layered crystal parallel to the a-b plane has defects, carriers (electrons) can flow in another layered crystal parallel to the a-b plane having no defects. Accordingly, the transistor 200 can have favorable on-state characteristics.

When the on-state current of the transistor 200 is increased in the above manner, the on-state current of the transistor 200 can be five times to ten times higher than that of a transistor in which only a top channel is formed. In this manner, the transistor 200 can have a high on-state current.

Furthermore, the on-state current can be increased without increasing the area occupied by the transistor 200 when seen from the top; thus, the semiconductor device can be miniaturized or highly integrated.

The structure of the semiconductor device including the transistor 200 of one embodiment of the present invention will be described in detail below.

The conductor 205 functioning as a second gate electrode is provided to overlap with the oxide 230 and the conductor 260. The conductor 205 is preferably provided on and in contact with the conductor 203.

The conductor 205 is preferably larger than the region 234 in the oxide 230. It is particularly preferable that, in the channel width direction, the conductor 205 extend in a region outward from the side surface of the oxide 230. In other words, it is preferable that the conductor 205 and the conductor 260 overlap with each other with an insulator provided therebetween in the region outward from the side surface of the oxide 230 in the channel width direction.

Here, the conductor 260 functions as a first gate (also referred to as a top gate) electrode and the conductor 205 functions as the second gate (also referred to a back gate) electrode, in some cases. In that case, a potential applied to the conductor 205 can be changed independently of a potential applied to the conductor 260 to control the threshold voltage of the transistor 200. In particular, a negative potential is applied to the conductor 205, so that the threshold voltage of the transistor 200 can be higher than 0 V and the transistor 200 can be a normally-off transistor. Accordingly, a drain current I_{cut} when 0 V is applied to the conductor 260 can be reduced. Note that in this specification and the like, I_{cut} is a drain current when a voltage of a gate electrode that controls switching operation of the transistor 200 is 0 V.

The conductor 205 preferably includes, as illustrated in FIGS. 3A to 3C, the conductor 205a that is in contact with an inner wall of an opening of the insulators 214 and 216 and the conductor 205b positioned on an inner side than the conductor 205a. Here, the top surfaces of the conductors 205a and 205b can be substantially level with the top surface of the insulator 216. Although the conductor 205a and the conductor 205b are stacked in the transistor 200, one embodiment of the present invention is not limited to this structure. For example, a structure in which only the conductor 205b is provided may be employed.

The conductor 203 extends in the channel width direction in a manner similar to that of the conductor 260, and functions as a wiring through which a potential is applied to the conductor 205, that is, the second gate electrode. Here, the conductor 205 is provided to be stacked over the conductor 203 functioning as a wiring for the second gate electrode and to be embedded in the insulators 214 and 216. When the conductor 205 is provided over the conductor 203, a distance between the conductor 203 functioning as the wiring for the second gate electrode and the conductor 260 functioning as the first gate electrode and a wiring can be set as appropriate. That is, the insulators 214 and 216 and the like are provided between the conductors 203 and 260, whereby a parasitic capacitance between the conductors 203 and 260 can be reduced, and the withstand voltage can be increased.

The reduction in the parasitic capacitance between the conductor 203 and the conductor 260 can improve the switching speed of the transistor, so that the transistor can have high frequency characteristics. The increase in the withstand voltage between the conductor 203 and the conductor 260 can improve the reliability of the transistor 200. Therefore, the thicknesses of the insulator 214 and the insulator 216 are preferably large. Note that the extending direction of the conductor 203 is not limited to this example; for example, the conductor 203 may extend in the channel length direction of the transistor 200.

The conductors 205a and 203a are preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (or a conductive material through which the impurities are less likely to pass). Alternatively, the conductors 205a and 203a are preferably formed using a conductive material having a function of inhibiting diffusion of oxygen (e.g., oxygen atoms or oxygen molecules), that is, a conductive material through which the oxygen is less likely to pass. Note that in this specification, a function of inhibiting diffusion of impurities or oxygen means a function of inhibiting diffusion of any one or all of the above impurities or the above oxygen.

When the conductors 205a and 203a have a function of inhibiting diffusion of oxygen, the conductivity of the conductors 205b and 203b can be prevented from being lowered because of oxidation. As the conductive material having a function of inhibiting diffusion of oxygen, for example, tantalum, tantalum nitride, ruthenium, or ruthenium oxide is preferably used. Thus, the conductors 205a and 203a may be a single layer or a stacked layer of the above conductive materials. Accordingly, impurities such as hydrogen and water can be prevented from being diffused to the transistor 200 side of the insulator 210 through the conductors 203 and 205 from the substrate side of the insulator 210.

Furthermore, the conductor 205b is preferably formed using a conductive material containing tungsten, copper, or aluminum as its main component. Note that although the conductor 205b is illustrated as a single layer, the conductor 205b may have a stacked-layer structure. For example, a stacked layer of any of the above conductive materials and titanium or titanium nitride may be used.

The conductor 203b functions as the wiring and thus is preferably formed using a conductor having higher conductivity than the conductor 205b. For example, a conductive material containing copper or aluminum as its main component can be used. The conductor 203b may have a stacked-layer structure, and for example, a stacked layer of any of the above conductive materials and titanium or titanium nitride may be used.

Each of the insulators 210 and 214 preferably functions as a barrier insulating film for preventing impurities such as water and hydrogen from entering the transistor from the substrate side. Accordingly, each of the insulators 210 and 214 is preferably formed using an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (or a conductive material through which the impurities are less likely to pass). Alternatively, each of the insulators 210 and 214 is preferably formed using an insulating material having a function of inhibiting diffusion of oxygen (e.g., oxygen atoms or oxygen molecules), that is, a conductive material through which the impurities are less likely to pass.

It is preferable that aluminum oxide be used for the insulator 210 and that silicon nitride be used for the insulator 214, for example. Thus, impurities such as hydrogen and water can be prevented from being diffused to the transistor side of the insulators 210 and 214. Alternatively, oxygen contained in the insulator 224 or the like can be prevented from being diffused to the substrate side of the insulators 210 and 214.

Furthermore, with the structure in which the conductor 205 is stacked over the conductor 203, the insulator 214 can be provided between the conductor 203 and the conductor 205. Here, even when a metal that is easily diffused, such as copper, is used for the conductor 203b, the use of silicon nitride, aluminum oxide, hafnium oxide, or the like having low copper permeability for the insulator 214 can prevent diffusion of the metal to a layer over the insulator 214.

The permittivity of each of the insulators 212, 216, and 280 functioning as interlayer films is preferably lower than that of the insulator 210 or 214. In the case where a material with a low permittivity is used for the interlayer films, the parasitic capacitance between wirings can be reduced.

For example, each of the insulators 212, 216, and 280 can have single-layer structure or a stacked-layer structure using one or more of insulators such as silicon oxide, silicon oxynitride, silicon nitride oxide, aluminum oxide, hafnium oxide, tantalum oxide, zirconium oxide, lead zirconate titanate (PZT), strontium titanate (SrTiO₃), and (Ba,Sr)TiO₃ (BST). Aluminum oxide, bismuth oxide, germanium oxide, niobium oxide, silicon oxide, titanium oxide, tungsten oxide, yttrium oxide, or zirconium oxide may be added to the insulator, for example. The insulator may be subjected to nitriding treatment. A layer of silicon oxide, silicon oxynitride, or silicon nitride may be stacked over the insulator.

The insulators 220, 222, and 224 collectively function as a gate insulator of the second gate.

Here, as the insulator 224 in contact with the oxide 230, an oxide insulator that contains more oxygen than that in the stoichiometric composition is preferably used. That is, an excess-oxygen region is preferably formed in the insulator 224. When such an insulator containing excess oxygen is provided in contact with the oxide 230, oxygen vacancies in the oxide 230 can be reduced, leading to an improvement in reliability.

As the insulator having an excess-oxygen region, specifically, an oxide that releases part of oxygen by heating is preferably used. The oxide that releases part of oxygen by heating is an oxide film in which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy (TDS) analysis. In the TDS analysis, the film surface temperature is preferably higher than or equal to 100° C. and lower than or equal to 700° C., or higher than or equal to 100° C. and lower than or equal to 400° C.

In the case where the insulator 224 has an excess-oxygen region, the insulator 222 preferably has a function of inhibiting diffusion of oxygen (e.g., oxygen atoms or oxygen molecules), that is, a conductive material through which the impurities are less likely to pass.

When the insulator 222 has a function of inhibiting diffusion of oxygen, oxygen in the excess-oxygen region is not diffused to the insulator 220 side and thus can be supplied to the oxide 230 efficiently. The conductor 205 can be inhibited from reacting with oxygen in the excess-oxygen region of the insulator 224.

The insulator 222 preferably has a single-layer structure or a stacked-layer structure using an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST). When a high-k material is used for the insulator functioning as a gate insulator, miniaturization and high integration of the transistor becomes possible. It is particularly preferable to use an insulating material having a function of inhibiting diffusion of impurities such as aluminum oxide and hafnium oxide, oxygen, and the like (or an insulating material through which oxygen is less likely to pass). The insulator 222 formed using such a material functions as a layer that prevents release of oxygen from the oxide 230 and entry of impurities such as hydrogen from the periphery of the transistor 200.

Alternatively, aluminum oxide, bismuth oxide, germanium oxide, niobium oxide, silicon oxide, titanium oxide, tungsten oxide, yttrium oxide, or zirconium oxide may be added to these insulators, for example. These insulators may be subjected to nitriding treatment. A layer of silicon oxide, silicon oxynitride, or silicon nitride may be stacked over the insulator.

It is preferable that the insulator 220 be thermally stable. Because silicon oxide and silicon oxynitride have thermal stability, the combination of silicon oxide or silicon oxynitride with the insulator formed using a high-k material can provide a stacked-layer structure with thermal stability and a high relative permittivity, for example.

Note that the insulators 220, 222, and 224 each may have a stacked-layer structure of two or more layers. In this case, the stacked layers are not necessarily formed of the same material but may be formed of different materials. A structure in which any one selected from the insulators 220, 222, and 224 is used or a structure in which any two selected from the insulators 220, 222, and 224 are used may be employed.

The oxide 230 includes the oxide 230a and the oxide 230b over the oxide 230a. The oxide 230 preferably has the regions 231, 232, 233, and 234. Note that it is preferable that at least part of the regions 231 be in contact with the insulator 274 and that at least one of the concentration of a metal element such as indium and the concentration of hydrogen and nitrogen be higher in the regions 231 than that in the region 234.

The thickness tₛ₂ of the oxide 230b is greater than or equal to the length tw of the oxide 230b in the channel width direction. For example, the thickness tₛ₂ can be 1 to 10 times, preferably 1 to 3 times greater than the length tw in the channel width direction. Accordingly, the transistor 200 is what is called a fin transistor in which a cross section of a structure including the insulator 224 serving as the base insulating film and the oxide 230 is a protrusion shape.

When the length of the conductor 260 in the channel length direction is 60 nm and the length of the oxide 230b in the channel width direction is 60 nm, for example, the thickness tₛ₂ of the oxide 230b can be approximately 60 nm to 100 nm.

In such a fin transistor, not only the top surface of the oxide 230 but also the side surface of the oxide 230 can function as a channel. Since channels are formed in the side surfaces on the A3 side and the A4 side and in the top surface of the oxide 230, an effective channel width is at least three or more times greater than the length tw in the channel width direction. In this manner, the transistor 200 can have a high on-state current.

In the above structure, an increase in the thickness of the oxide 230b can increase the on-state current without increasing the area occupied by the transistor 200 when seen from the top. Thus, the semiconductor device can be miniaturized or highly integrated.

In the case of a fin transistor containing silicon, a depletion layer due to an electric field of a gate is not completely extended because of a thick channel formation region; thus, it might be difficult to turn off the transistor completely. Meanwhile, in the case of the fin transistor 200 whose channel formation region is in the oxide 230, which is described in one embodiment of the present invention, a depletion layer due to the electric field of the gate can be sufficiently extended even when the channel formation region is thick; thus, the transistor 200 can be turned off

The curved surface is provided between the side surface and the top surface of the oxide 230. That is, an end portion of the side surface and an end portion of the top surface are preferably curved (such end portions are also referred to as rounded end portions). The radius of curvature of the curved surface at the end portion of the side surface of the oxide 230b is preferably greater than or equal to 3 nm and less than or equal to 10 nm, and further preferably greater than or equal to 5 nm and less than or equal to 6 nm.

Since the oxide 230b has the curved surface between its side surface and top surface, the insulator 250 can be formed over the oxide 230 with good coverage. Thus, short circuit between the oxide 230 and the conductor 260, which is caused when part of the insulator 250 is not formed, can be prevented. In addition, electrostatic discharge due to electric field concentration in part of the insulator 250 can be prevented.

The oxide 230 is preferably formed using a metal oxide functioning as an oxide semiconductor (hereinafter, the metal oxide is also referred to as an oxide semiconductor). For example, a metal oxide used for the region 234 preferably has an energy gap higher than or equal to 2 eV, further preferably higher than or equal to 2.5 eV. With the use of a metal oxide having such a wide energy gap, the off-state current of the transistor can be reduced.

Note that in this specification and the like, a metal oxide including nitrogen is also called a metal oxide in some cases. Moreover, a metal oxide including nitrogen may be called a metal oxynitride.

A transistor formed using an oxide semiconductor has an extremely low leakage current in an off state; thus, a semiconductor device with low power consumption can be provided. An oxide semiconductor can be formed by a sputtering method or the like and thus can be used in a transistor included in a highly integrated semiconductor device.

For the oxide 230, for example, a metal oxide such as an In-M-Zn oxide (M is one or more of aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like) is used. Alternatively, an In-Ga oxide or an In-Zn oxide may be used for the oxide 230.

The conduction band minimum of the oxide 230a is preferably higher than that of the oxide 230b. In other words, the electron affinity of the oxide 230a is preferably smaller than that of the oxide 230b.

Here, the conduction band minimum is gradually varied in the oxides 230a and 230b. In other words, the conduction band minimum is continuously varied or continuously connected. To vary the conduction band minimum gradually, the density of defect states in a mixed layer formed at the interface between the oxides 230a and 230b is decreased.

Specifically, when the oxides 230a and 230b contain the same element (as a main component) in addition to oxygen, a mixed layer with a low density of defect states can be formed. For example, in the case where the oxide 230b is an In-Ga-Zn oxide, it is preferable to use an In-Ga-Zn oxide, a Ga-Zn oxide, gallium oxide, or the like for the oxide 230a.

At this time, a narrow-gap portion formed in the oxide 230b serves as a main carrier path. Since the density of defect states at the interface between the oxides 230a and 230b can be decreased, the influence of interface scattering on carrier conduction is small, and a high on-state current can be obtained.

Since the oxide 230b is provided over the oxide 230a, impurities can be prevented from being diffused into the oxide 230b from the components formed below the oxide 230a.

When the transistor 200 is turned on, the region 231a or the region 231b functions as the source region or the drain region. At least part of the region 234 functions as the channel formation region.

As illustrated in FIG. 2, the oxide 230 preferably includes the regions 233 and 234. With this structure, the transistor 200 can have a high on-state current and a low leakage current in an off state (off-state current).

Here, the region 234 in the oxide 230 will be described.

The region 234 overlaps with the conductor 260. It is preferable that the region 234 be provided between the region 233a and the region 233b and that at least one of the concentration of a metal element such as indium and the concentration of an impurity element such as hydrogen and nitrogen be lower in the region 234 than that in the regions 231, 232, and 233.

The region 234 preferably has a stacked-layer structure of oxides which differ in the atomic ratio of metal elements. Specifically, in the case where the region 234 has the stacked-layer structure of the oxides 230a and 230b, the atomic ratio of the element M to constituent elements in a metal oxide used for the oxide 230a is preferably greater than that in a metal oxide used for the oxide 230b. Furthermore, the atomic ratio of the element M to In in the metal oxide used for the oxide 230a is preferably greater than that in the metal oxide used for the oxide 230b. Moreover, the atomic ratio of the element In to M in the metal oxide used for the oxide 230b is preferably greater than that in the metal oxide used for the oxide 230a.

The oxide 230b preferably has a layered crystal structure at least in the region 234. It is further preferable to have, for example, a crystal structure that has c-axis alignment and an a-b plane and is formed of a plurality of nanocrystals, such as a CAAC-OS described later. The a-b plane of the oxide 230 is substantially parallel to a substrate surface.

Next, the regions 231, the regions 232, and the regions 233 of the oxide 230 will be described.

The regions 231 are preferably in contact with the insulator 274. At least one of the concentration of a metal element such as indium and the concentration of an impurity element such as hydrogen and nitrogen is preferably higher in the regions 231 than in the regions 232, 233, and 234.

The regions 232 each have a region overlapping with the insulator 272. The regions 232 are preferably positioned between the regions 231 and 233. At least one of the concentration of a metal element such as indium and the concentration of an impurity element such as hydrogen and nitrogen is preferably higher in the regions 232 than in the regions 233 and 234. In addition, at least one of the concentration of a metal element such as indium and the concentration of an impurity element such as hydrogen and nitrogen is preferably lower in the regions 232 than in the regions 231.

The regions 233 each have a region overlapping with the conductor 260. The regions 233 are preferably positioned between the regions 234 and 232. At least one of the concentration of a metal element such as indium and the concentration of an impurity element such as hydrogen and nitrogen is preferably higher in the regions 232 than in the region 234. In addition, at least one of the concentration of a metal element such as indium and the concentration of an impurity element such as hydrogen and nitrogen is preferably lower in the regions 233 that in the regions 231 and 232.

As described above, each of the regions 231, 232, and 233 is a region whose resistance is reduced by addition of a metal atom such as an indium atom or impurities to the metal oxide used for the oxide 230. Each of the regions has higher conductivity than at least the oxide 230b in the region 234. In the addition of impurities to the regions 231, 232, and 233, for example, a dopant which is at least one of the metal element such as indium and the impurities can be added by plasma treatment, an ion implantation method by which an ionized source gas is subjected to mass separation and then added, an ion doping method by which an ionized source gas is added without mass separation, a plasma immersion ion implantation method, or the like.

That is, when the content of a metal element such as indium in the regions 231, 232, and 233 of the oxide 230 is increased, the electron mobility can be increased and the resistance can be decreased.

When the insulator 274 containing an impurity element is formed in contact with the oxide 230, an impurity can be added to the regions 231, 232, and 233.

That is, when an element that forms an oxygen vacancy or an element trapped by an oxygen vacancy is added to the regions 231, 232, and 233, the resistance of the regions 231, 232, and 233 is reduced. Typical examples of the element are hydrogen, boron, carbon, nitrogen, fluorine, phosphorus, sulfur, chlorine, titanium, and a rare gas element. Typical examples of the rare gas element are helium, neon, argon, krypton, and xenon. Accordingly, the regions 231, 232, and 233 are made to contain one or more of the above elements.

The regions 234, 231, 232, and 233 are formed in the oxides 230a and 230b in FIGS. 1A to 1C and FIG. 2. Without limitation to the structure illustrated in FIGS. 1A to 1C and FIG. 2, the regions may be formed at least in the oxide 230b, for example. Although the boundaries between the regions are indicated substantially perpendicularly to the top surface of the oxide 230 in FIGS. 1A to 1C and FIG. 2, this embodiment is not limited thereto. For example, the region 233a is shaped such that it recedes to the A1 (in FIG. 1B) side near the bottom surface of the oxide 230a and the region 233b is shaped such that it recedes to the A2 (in FIG. 1B) side near the bottom surface of the oxide 230a, in some cases.

In the oxide 230, the boundaries between the regions 231, 232, 233, and 234 cannot be detected accurately in some cases. The concentration of a detected metal element such as indium and the concentration of a detected impurity element such as hydrogen and nitrogen may be gradually changed (also referred to as gradation) not only between the regions but also in each region. It is acceptable as long as a region closer to the region 234 (the regions 233, the regions 232, and the regions 231 are close to the region 234 in this order) has a lower concentration of a detected metal element such as indium and a lower concentration of a detected impurity element such as hydrogen and nitrogen.

When the regions 233 and 232 are provided in the transistor 200, a high-resistance region is not formed between the region 234 where a channel is formed and each of the regions 231 functioning as the source and drain regions; thus, the on-state current and the carrier mobility of the transistor can be increased. Moreover, when the transistor 200 includes the regions 233, the gate does not overlap with the source region and the drain region in the channel length direction, so that the formation of unnecessary capacitance can be inhibited, and the leakage current in an off state can be reduced.

Thus, by appropriately selecting the areas of the regions 231, 232, and 233, a transistor having electrical characteristics necessary for the circuit design can be easily provided.

The insulator 250 functions as a gate insulating film of the first gate. The insulator 250 is preferably in contact with the top and side surfaces of the oxide 230b. In addition, the thickness is of the insulator 250 around the side surface of the oxide 230b is preferably smaller than the thickness to of the insulator 250 around the top surface of the oxide 230b.

Owing to the use of the insulator 250 having such a structure as the gate insulating film of the first gate, not only the top surface of the oxide 230 but also the side surface of the oxide 230 can function as a channel. The thickness tₛ₂ of the oxide 230b is greater than or equal to the length tw of the oxide 230b in the channel width direction. Since a channel is formed in the side surfaces on the A3 side and the A4 side in addition to a channel formed in the top surface of the oxide 230, an effective channel width is at least three or more times greater than the length tw of the oxide 230 in the channel width direction.

Furthermore, since the thickness is of the insulator 250 around the side surface of the oxide 230b is smaller than the thickness to of the insulator 250 around the top surface of the oxide 230b, the carrier density of the side surface of the oxide 230b is higher than the carrier density of the top surface of the oxide 230b. Thus, when the transistor 200 is turned on, current flows more in the channel in the top surface of the oxide 230b than in the channel in the side surface of the oxide 230b. Since the thickness of the insulator 250 around the side surface of the oxide 230b is small, the carrier density of the insulator 250 around the side surface of the oxide 230b is increased; thus, the transistor 200 can have high frequency characteristics.

It is preferable that the insulator 250 cover the oxide 230 and be in contact with the insulator 224 on the A3 and A4 sides of the oxide 230 in the channel width direction. When the insulator 250 is provided in such a manner, the entire side surface of the region 234 on the A3 side and the entire side surface of the region 234 on the A4 side can function as channel formation regions.

Since the oxide 230b has the curved surface between its side surface and top surface, the insulator 250 can be formed over the oxide 230 with good coverage. Thus, short circuit between the oxide 230 and the conductor 260, which is caused when part of the insulator 250 is not formed, can be prevented. In addition, electrostatic discharge due to electric field concentration in part of the insulator 250 can be prevented.

A transistor formed using an oxide semiconductor is likely to have its electrical characteristics changed by impurities and oxygen vacancies in the oxide semiconductor; as a result, the reliability is reduced, in some cases. Hydrogen contained in an oxide semiconductor reacts with oxygen bonded to a metal atom to be water, and thus causes an oxygen vacancy, in some cases. Entry of hydrogen into the oxygen vacancy generates an electron serving as a carrier in some cases. Accordingly, a transistor including an oxide semiconductor containing oxygen vacancies is likely to have normally-on characteristics. Thus, it is preferable that oxygen vacancies in the oxide semiconductor be reduced as much as possible.

Thus, the insulator 250 in contact with the region 234 of the oxide 230 preferably contains oxygen at a higher proportion than oxygen in the stoichiometric composition (also referred to as an “excess oxygen”). The excess oxygen contained in the insulator 250 is diffused into the region 234, whereby oxygen vacancies in the region 234 can be reduced.

When as the insulator 250, an insulator from which oxygen is released by heating is provided in contact with the top surface of the oxide 230b, oxygen can be efficiently supplied to the region 234 of the oxide 230b. The insulator 250 is an oxide film of which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy (TDS) analysis, for example. In the TDS analysis, the film surface temperature is preferably higher than or equal to 100° C. and lower than or equal to 700° C., or higher than or equal to 100° C. and lower than or equal to 500° C.

Furthermore, as in the case of the insulator 224, the concentration of impurities such as water and hydrogen in the insulator 250 is preferably lowered.

The conductor 260 has the region that faces the top and side surfaces of the oxide 230b with the insulator 250 positioned therebetween. In other words, the conductor 260 is positioned along the fin oxide 230b whose thickness tₛ₂ is greater than or equal to the length tw in the channel width direction. Owing to the use of the conductor 260 having such a structure as the first gate, not only the top surface of the oxide 230 but also the side surface of the oxide 230 can function as a channel. Since a channel is formed in the side surfaces on the A3 side and the A4 side in addition to a channel in the top surface of the oxide 230, an effective channel width is at least three or more times greater than the length tw of the oxide 230 in the channel width direction.

As illustrated in FIG. 1C, the bottom surface of the conductor 260 in a region not overlapping with the oxide 230 is preferably below the bottom surface of the oxide 230b. When the conductor 260 is provided in such a manner, the entire side surface of the region 234 in the oxide 230b on the A3 side and the entire side surface of the region 234 in the oxide 230b on the A4 side can function as channel formation regions.

The conductor 260 functioning as the first gate electrode includes the conductor 260a and the conductor 260b over the conductor 260a, as illustrated in FIGS. 3A to 3C. The conductor 260a is preferably formed using a conductive oxide. For example, the metal oxide that can be used for the oxide 230a or 230b can be used. It is particularly preferable to use an In-Ga-Zn-based oxide with an atomic ratio of In:Ga:Zn =4:2:3 to 4:2:4.1 or in the neighborhood thereof, which has high conductivity. When the conductor 260a is formed using such a material, oxygen can be prevented from entering the conductor 260b, and an increase in electric resistance value of the conductor 260b due to oxidation can be prevented.

When such a conductive oxide is formed by a sputtering method, oxygen can be added to the insulator 250, so that oxygen can be supplied to the metal oxide 230b. Thus, oxygen vacancies in the region 234 of the oxide 230 can be reduced.

The conductor 260b can be formed using a metal such as tungsten, for example. As the conductor 260b, a conductor that can add impurities such as nitrogen to the conductor 260a to improve the conductivity of the conductor 260a may be used. For example, titanium nitride or the like is preferably used for the conductor 260b. Alternatively, the conductor 260b may be a stack including a metal nitride such as titanium nitride and a metal such as tungsten thereover.

As illustrated in FIGS. 3A to 3C, the insulator 270 functioning as a hard mask may be provided over the conductor 260b. Owing to the insulator 270, in processing the conductor 260, the side surface of the conductor 260 can be substantially perpendicular to the substrate surface, specifically, an angle formed by the side surface of the conductor 260 and the substrate surface can be greater than or equal to 75° and less than or equal to 100°, preferably greater than or equal to 80° and less than or equal to 95°. When the conductor 260 is processed into such a shape, the insulator 272 that is subsequently formed can be formed into a desired shape. The insulator 270 may have a stacked-layer structure; for example, a stacked-layer structure of a layer functioning as a barrier film, like the insulator 272, and a layer functioning as a hard mask provided over the layer functioning as a barrier film may be used.

The insulator 272 functioning as the barrier film is provided in contact with the side surface of the insulator 250, the side surface of the conductor 260, and a side surface of the insulator 270.

Here, the insulator 272 is preferably formed using an insulating material that has a function of inhibiting the penetration of oxygen and impurities such as water and hydrogen. For example, aluminum oxide or hafnium oxide is preferably used. In this manner, oxygen in the insulator 250 can be prevented from diffusing outward. In addition, impurities such as hydrogen and water can be prevented from entering the oxide 230 through the side of the insulator 250 or the like.

When the insulator 272 has a function of inhibiting diffusion of oxygen, oxygen contained in the insulator 250 is not diffused to the insulator 274 side and thus is supplied to the region 234 efficiently. Thus, the formation of oxygen vacancies at the interface between the oxide 230 and the insulator 250 can be inhibited, leading to an improvement in the reliability of the transistor 200.

Owing to the insulator 272, the top and side surfaces of the conductor 260 and the side surface of the insulator 250 can be covered with an insulator having a function of inhibiting the passage of oxygen and impurities such as water or hydrogen. This can prevent entry of impurities such as water or hydrogen into the oxide 230 through the conductor 260 and the insulator 250. Thus, the insulator 272 functions as a side barrier for protecting the side surfaces of the gate electrode and the gate insulating film.

In the case where the transistor is miniaturized and has a channel length of approximately greater than or equal to 10 nm and less than or equal to 30 nm, impurity elements contained in the components provided in the vicinity of the transistor 200 might be diffused, and the regions 231a and 231b might be electrically connected to each other.

In view of the above, when the insulator 272 is formed as described in this embodiment, impurities such as hydrogen and water can be prevented from entering the insulator 250 and the conductor 260, and oxygen in the insulator 250 can be prevented from being diffused to the outside. Accordingly, the source region and the drain region when the voltage of the first gate is 0 V, can be prevented from being electrically connected to each other.

When the insulator 272 is formed in contact with the side surfaces of the conductor 260 and the insulator 250, the insulator 272 is formed on a side surface of the oxide 230 as illustrated in FIGS. 1A and 1B, in some cases. Similarly, as illustrated in FIGS. 1A and 1C, the insulator 272 is formed on a side surface of a projecting portion of the conductor 260 formed due to the oxide 230 in some cases.

The insulator 274 is provided to cover the insulator 270, the insulator 272, the oxide 230, and the insulator 224. Here, the insulator 274 is provided in contact with the top surfaces of the insulators 270 and 272 and a side surface of the insulator 272.

Moreover, the insulator 274 is preferably formed using an insulating material having a function of inhibiting the passage of oxygen and impurities such as water or hydrogen. For the insulator 274, for example, silicon nitride, silicon nitride oxide, silicon oxynitride, aluminum nitride, or aluminum nitride oxide, is preferably used. When the insulator 274 is formed using such a material, entry of oxygen through the insulator 274 to be supplied to oxygen vacancies in the regions 231a and 231b, which decreases the carrier density, can be prevented. Furthermore, impurities such as water or hydrogen can be prevented from passing through the insulator 274 and excessively enlarging the region 231a and the region 231b to the region 234 side.

Note that in the case where the regions 231, 232, and 233 are formed when the insulator 274 is formed, the insulator 274 preferably contains at least one of hydrogen and nitrogen. When an insulator containing impurities such as hydrogen or nitrogen is used as the insulator 274, impurities such as hydrogen or nitrogen can be added to the oxide 230 to form the regions 231, 232, and 233 in the oxide 230.

The insulator 280 functioning as the interlayer film is preferably provided over the insulator 274. As with the insulator 224 or the like, the concentration of impurities such as water or hydrogen in the insulator 280 is preferably lowered. Note that an insulator similar to the insulator 210 may be provided over the insulator 280.

The conductors 252a and 252b are provided in openings formed in the insulators 280 and 274. The conductors 252a and 252b are provided to face each other with the conductor 260 positioned therebetween. Note that the top surfaces of the conductors 252a and 252b may be at the same level as the top surface of the insulator 280.

Here, the conductor 252a is in contact with the region 231a functioning as one of a source region and a drain region of the transistor 200, and the conductor 252b is in contact with the region 231b functioning as the other of the source region and the drain region of the transistor 200. Therefore, the conductor 252a can function as one of a source electrode and a drain electrode, and the conductor 252b can function as the other of the source electrode and the drain electrode. Because the region 231a and the region 231b are reduced in resistance, the contact resistance between the conductor 252a and the region 231a and the contact resistance between the conductor 252b and the region 231b are reduced, leading to a high on-state current of the transistor 200.

Note that the conductor 252a is formed in contact with an inner wall of the opening in the insulators 280 and 274. The region 231a of the oxide 230 is positioned on at least part of a bottom portion of the opening, and thus the conductor 252a is in contact with the region 231a. Similarly, the conductor 252b is formed in contact with an inner wall of the opening in the insulators 280 and 274. The region 231b of the oxide 230 is positioned on at least part of a bottom portion of the opening, and thus the conductor 252b is in contact with the region 231b.

It is preferable that the conductor 252a (the conductor 252b) be in contact with at least the top surface of the oxide 230 and a side surface of the oxide 230. It is preferable that the insulator 272 be not formed on the side surface of the oxide 230 in the opening in which the conductor 252a (the conductor 252b) is provided and the contact between the conductor 252a (the conductor 252b) and the oxide 230 be not prevented. It is particularly preferable that the conductor 252a (the conductor 252b) be in contact with one or both of the side surfaces of the oxide 230 in the channel width direction on the A3 and A4 sides. The conductor 252a (the conductor 252b) may be in contact with the side surface of the oxide 230 on the A1 side (the A2 side) in the channel length direction. When the conductor 252a (the conductor 252b) is in contact with not only the top surface of the oxide 230 but also the side surface of the oxide 230, a contact area of the contact portion of the conductor 252a (the conductor 252b) and the oxide 230 can be increased and the contact resistance between the conductor 252a (the conductor 252b) and the oxide 230 can be reduced without increasing the area of the top surface of the contact portion.

Accordingly, miniaturization of the source electrode and the drain electrode of the transistor can be achieved, and the on-state current can be increased.

The conductor 252a and the conductor 252b are preferably formed using a conductive material including tungsten, copper, or aluminum as its main component. Although not shown, the conductor 252a and the conductor 252b may have a stacked-layer structure, and for example, a stacked layer of titanium, titanium nitride, and any of the above conductive materials may be used.

In the case where the conductors 252 each have a stacked-layer structure, a conductive material having a function of inhibiting the passage of impurities such as water or hydrogen is preferably used for a conductor in contact with the insulators 274 and 280, as in the conductor 205a or the like. For example, tantalum, tantalum nitride, titanium, titanium nitride, ruthenium, or ruthenium oxide is preferably used. The conductive material having a function of inhibiting the passage of impurities such as water or hydrogen may be formed to have a single-layer structure or a stacked-layer structure. With the use of the conductive material, impurities such as hydrogen or water can be prevented from entering the oxide 230 through the conductors 252a and 252b from a layer above the insulator 280.

Although not illustrated, conductors functioning as wirings may be provided in contact with the top surfaces of the conductors 252a and 252b. A conductive material containing tungsten, copper, or aluminum as its main component is preferably used for the conductors functioning as the wirings. Each of the conductors may have a stacked-layer structure; for example, a stacked layer of any of the above conductive materials and titanium or titanium nitride may be used. Note that the conductor may be formed to be embedded in an opening provided in an insulator, like the conductor 203 or the like.

### <Material for Semiconductor Device>

Materials that can be used for a semiconductor device will be described below.

### <<Substrate>>

As a substrate over which the transistor 200 is formed, for example, an insulator substrate, a semiconductor substrate, or a conductor substrate may be used. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a semiconductor substrate of silicon, germanium, or the like, or a compound semiconductor substrate of silicon carbide, silicon germanium, gallium arsenide, indium phosphide, zinc oxide, or gallium oxide can be used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate. As a method for providing a transistor over a flexible substrate, there is a method in which the transistor is formed over a non-flexible substrate and then the transistor is separated and transferred to the substrate which is a flexible substrate. In that case, a separation layer is preferably provided between the non-flexible substrate and the transistor. The substrate may have elasticity. The substrate may have a property of returning to its original shape when bending or pulling is stopped. Alternatively, the substrate may have a property of not returning to its original shape. The substrate has a region with a thickness of, for example, greater than or equal to 5 μm and less than or equal to 700 μm, preferably greater than or equal to 10 μm and less than or equal to 500 μm, further preferably greater than or equal to 15 μm and less than or equal to 300 μm. When the substrate has a small thickness, the weight of the semiconductor device including the transistor can be reduced. When the substrate has a small thickness, even in the case of using glass or the like, the substrate may have elasticity or a property of returning to its original shape when bending or pulling is stopped. Therefore, an impact applied to the semiconductor device over the substrate due to dropping or the like can be reduced. That is, a durable semiconductor device can be provided.

For the substrate which is a flexible substrate, metal, an alloy, resin, glass, or fiber thereof can be used, for example. As the substrate, a sheet, a film, or a foil containing a fiber may be used. The flexible substrate preferably has a lower coefficient of linear expansion because deformation due to an environment is suppressed. The flexible substrate is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate because of its low coefficient of linear expansion.

### <<Insulator>>

Examples of an insulator include an insulating oxide, an insulating nitride, an insulating oxynitride, an insulating nitride oxide, an insulating metal oxide, an insulating metal oxynitride, and an insulating metal nitride oxide.

When a high-k material having a high relative permittivity is used for the insulator functioning as the gate insulator, miniaturization and high integration of the transistor can be achieved. By contrast, when a material having a low relative permittivity is used for the insulator functioning as an interlayer film, the parasitic capacitance between wirings can be reduced. In this manner, a material is preferably selected depending on the function of an insulator.

As the insulator having a high relative permittivity, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, or the like can be given.

As the insulator having a low relative permittivity, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like can be given.

In particular, silicon oxide and silicon oxynitride are thermally stable. Accordingly, a stacked-layer structure which is thermally stable and has a low relative permittivity can be obtained by combination with a resin, for example. Examples of the resin include polyester, polyolefin, polyamide (e.g., nylon or aramid), polyimide, polycarbonate, and acrylic. Furthermore, combination of silicon oxide or silicon oxynitride with an insulator with a high relative permittivity allows the stacked-layer structure to be thermally stable and have a high relative permittivity, for example.

Note that when the transistor including an oxide semiconductor is surrounded by an insulator that has a function of inhibiting the penetration of oxygen and impurities such as hydrogen, the electrical characteristics of the transistor can be stabilized.

The insulator that has a function of inhibiting the penetration of oxygen and impurities such as hydrogen can have, for example, a single-layer structure or a stacked-layer structure of an insulator including boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the penetration of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide, silicon nitride oxide, silicon nitride, or the like can be used.

For example, an insulator that has a function of inhibiting the penetration of oxygen and impurities such as hydrogen may be used as each of the insulators 222, 214, and 210. Note that the insulators 222, 214, and 210 preferably contain aluminum oxide, hafnium oxide, or the like.

For example, the insulators 212, 216, 220, 224, and 250 may be formed using a single layer or a stacked layer of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, the insulators 212, 216, 220, 224, and 250 preferably contain silicon oxide, silicon oxynitride, or silicon nitride.

For example, when aluminum oxide, gallium oxide, or hafnium oxide in each of the insulators 224 and 250 functioning as a gate insulator is in contact with the oxide 230, entry of silicon included in silicon oxide or silicon oxynitride into the oxide 230 can be suppressed. When silicon oxide or silicon oxynitride in each of the insulators 224 and 250 is in contact with the oxide 230, for example, trap centers might be formed at the interface between aluminum oxide, gallium oxide, or hafnium oxide and silicon oxide or silicon oxynitride. The trap centers can shift the threshold voltage of the transistor in the positive direction by trapping electrons in some cases.

The insulator 212, the insulator 216, and the insulator 280 preferably include an insulator with a low relative permittivity. For example, the insulator 212, the insulator 216, and the insulator 280 preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, each of the insulator 212, the insulator 216, and the insulator 280 preferably has a stacked-layer structure of a resin and one of the following materials: silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide. When silicon oxide or silicon oxynitride, which is thermally stable, is combined with resin, the stacked-layer structure can have thermal stability and low relative permittivity. Examples of the resin include polyester, polyolefin, polyamide (e.g., nylon or aramid), polyimide, polycarbonate, and acrylic.

As the insulators 270 and 272, an insulator having a function of inhibiting the penetration of impurities such as hydrogen and oxygen may be used. For the insulator 270 and the insulator 272, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example.

<<Conductor>>

The conductors can be formed using a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like. Alternatively, a semiconductor having a high electric conductivity typified by polycrystalline silicon including an impurity element such as phosphorus, or silicide such as nickel silicide may be used.

A stack of a plurality of conductive layers formed with the above materials may be used. For example, a stacked-layer structure formed using a combination of a material including any of the metal elements listed above and a conductive material including oxygen may be used. Alternatively, a stacked-layer structure formed using a combination of a material including any of the metal elements listed above and a conductive material including nitrogen may be used. Alternatively, a stacked-layer structure formed using a combination of a material including any of the metal elements listed above, a conductive material including oxygen, and a conductive material including nitrogen may be used.

When oxide is used for the channel formation region of the transistor, a stacked-layer structure formed using a material containing the above-described metal element and a conductive material containing oxygen is preferably used for the conductor functioning as the gate electrode. In this case, the conductive material containing oxygen is preferably formed on the channel formation region side. In that case, the conductive material including oxygen is preferably provided on the channel formation region side so that oxygen released from the conductive material is easily supplied to the channel formation region.

It is particularly preferable to use, for the conductor functioning as the gate electrode, a conductive material containing oxygen and a metal element contained in a metal oxide in which a channel is formed. A conductive material containing the above metal element and nitrogen may be used. For example, a conductive material containing nitrogen such as titanium nitride or tantalum nitride may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide in which a channel is formed can be captured in some cases. Alternatively, hydrogen entering from an external insulator or the like can be captured in some cases.

The conductors 260a, 260b, 203a, 203b, 205a, 205b, 252a, and 252b can be each formed using a material containing one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like. Alternatively, a semiconductor having a high electric conductivity typified by polycrystalline silicon including an impurity element such as phosphorus, or silicide such as nickel silicide may be used.

<<Metal Oxide>>

The oxide 230 is preferably formed using a metal oxide functioning as an oxide semiconductor (hereinafter, the metal oxide is also referred to as an oxide semiconductor). A metal oxide that can be used for the oxide 230 of one embodiment of the present invention will be described below.

An oxide semiconductor preferably contains at least indium or zinc. In particular, indium and zinc are preferably contained. In addition, aluminum, gallium, yttrium, tin, or the like is preferably contained. Furthermore, one or more elements selected from boron, silicon, titanium, iron, nickel, germanium, zirconium, molybdenum, lanthanum, cerium, neodymium, hafnium, tantalum, tungsten, magnesium, or the like may be contained.

Here, the case where the oxide semiconductor is an In-M-Zn oxide that contains indium, an element M, and zinc is considered. The element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, and magnesium. Note that two or more of the above elements may be used in combination as the element M

Note that in this specification and the like, a metal oxide including nitrogen is also called a metal oxide in some cases. Moreover, a metal oxide including nitrogen may be called a metal oxynitride.

Here, the case where a metal oxide contains indium, the element M, and zinc is considered.

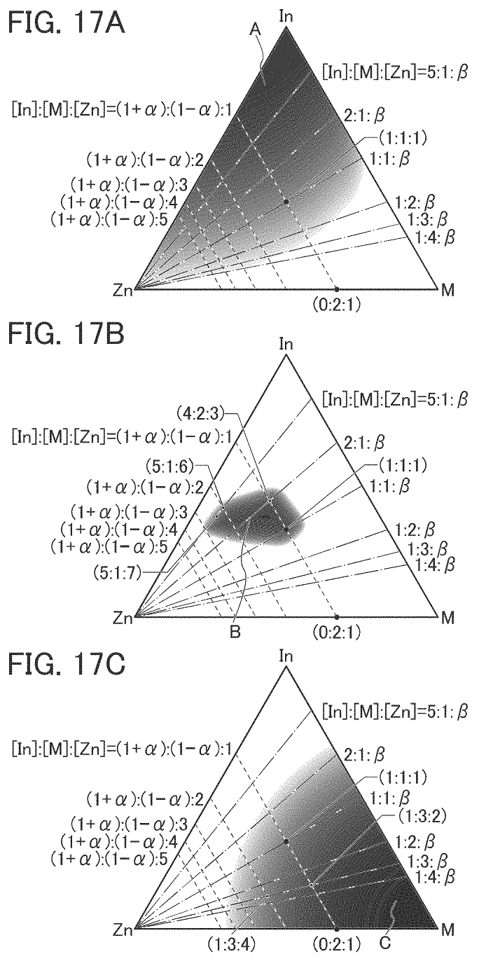

Preferred ranges of the atomic ratio of indium, the element M, and zinc contained in a metal oxide that can be used for the oxides 230a and 230b will be described with reference to FIGS. 17A to 17C. Note that the proportion of oxygen atoms is not shown in FIGS. 17A to 17C. The terms of the atomic ratio of indium, the element M, and zinc contained in the metal oxide are denoted by [In], [M], and [Zn], respectively.

In FIGS. 17A to 17C, broken lines indicate a line where the atomic ratio [In]:[M]:[Zn] is (1+α):(1−α):1 (−1≤α≤1), a line where the atomic ratio [In]:[M]:[Zn] is (1+α):(1−α):2, a line where the atomic ratio [In]:[M]:[Zn] is (1+α): (1−α):3, a line where the atomic ratio [In]:[M]:[Zn] is (1+α):(1−α):4, and a line where the atomic ratio [In]:[M]:[Zn] is (1+α):(1−α):5.

Furthermore, dashed-dotted lines indicate a line where the atomic ratio [In]:[M]:[Zn] is 5:1:β(β≥0), a line where the atomic ratio [In]:[M]:[Zn] is 2:1:β, a line where the atomic ratio [In]:[M]:[Zn] is 1:1:β, a line where the atomic ratio [In]:[M]:[Zn] is 1:2:β, a line where the atomic ratio [In]:[M]:[Zn] is 1:313, and a line where the atomic ratio [In]:[M]:[Zn] is 1:4:₁6.

Furthermore, a metal oxide with the atomic ratio of [In]:[M]:[Zn]=0:2:1 or a neighborhood thereof in FIGS. 17A to 17C tends to have a spinel crystal structure.

A plurality of phases (e.g., two phases or three phases) exist in the metal oxide in some cases. For example, with an atomic ratio [In]:[M]:[Zn] that is close to 0:2:1, two phases of a spinel crystal structure and a layered crystal structure are likely to exist. In addition, with an atomic ratio [In]:[M]:[Zn] that is close to 1:0:0, two phases of a bixbyite crystal structure and a layered crystal structure are likely to exist. In the case where a plurality of phases exist in the metal oxide, a grain boundary might be formed between different crystal structures.

A region A in FIG. 17A represents an example of the preferred range of the atomic ratio of indium, the element M, and zinc contained in the metal oxide.

In addition, the metal oxide having a higher content of indium can have higher carrier mobility (electron mobility). Thus, a metal oxide having a high content of indium has higher carrier mobility than a metal oxide having a low content of indium.

By contrast, when the indium content and the zinc content in a metal oxide become lower, carrier mobility becomes lower. Thus, with an atomic ratio of [In]:[M]:[Zn]=0:1:0 and the vicinity thereof (e.g., a region C in FIG. 17C), insulation performance becomes better.

For example, the metal oxide used for the oxide 230b preferably has an atomic ratio represented by the region A in FIG. 17A. The metal oxide with the atomic ratio has high carrier mobility. The atomic ratio of In to Ga and Zn of the metal oxide used for the oxide 230b may be 4:2:3 to 4:2:4.1 or in the neighborhood thereof, for example. By contrast, the metal oxide used for the oxide 230a preferably has an atomic ratio represented by the region C in FIG. 17C. The metal oxide with the atomic ratio has relatively high insulating properties. The atomic ratio of In to Ga and Zn of the metal oxide used for the oxide 230a may be approximately 1:3:4.

A metal oxide having an atomic ratio in the region A, particularly in a region B in FIG. 17B, has high carrier mobility and high reliability and is excellent.

Note that the region B includes an atomic ratio of [In]:[M]:[Zn]=4:2:3 to 4:2:4.1 and the vicinity thereof. The vicinity includes an atomic ratio of [In]:[M]:[Zn]=5:3:4. Note that the region B includes an atomic ratio of [In]:[M]:[Zn]=5:1:6 and the vicinity thereof and an atomic ratio of [In]:[M]:[Zn]=5:1:7 and the vicinity thereof.

In the case where the metal oxide is formed of an In-M-Zn oxide, it is preferable to use a target including a polycrystalline In-M-Zn oxide as the sputtering target. Note that the atomic ratio of the formed metal oxide varies from the above atomic ratios of metal elements of the sputtering targets in a range of ±40%. For example, when a sputtering target containing In, Ga, and Zn at an atomic ratio of 4:2:4.1 is used for forming the metal oxide, the atomic ratio of In to Ga and Zn in the formed metal oxide may be 4:2:3 or in the neighborhood of 4:2:3. When a sputtering target containing In, Ga, and Zn at an atomic ratio of 5:1:7 is used for forming the metal oxide, the atomic ratio of In to Ga and Zn in the formed metal oxide may be 5:1:6 or in the neighborhood of 5:1:6.

Note that the property of a metal oxide is not uniquely determined by an atomic ratio. Even with the same atomic ratio, the property of a metal oxide might be different depending on a formation condition. For example, in the case where the metal oxide is deposited with a sputtering apparatus, a film having an atomic ratio deviated from the atomic ratio of the target is formed. In particular, [Zn] in the film might be smaller than [Zn] in the target depending on the substrate temperature in deposition. Thus, the illustrated regions each represent an atomic ratio with which a metal oxide tends to have specific characteristics, and boundaries of the regions A to C are not clear.

### [Composition of Metal Oxide]

Described below is the composition of a cloud-aligned composite oxide semiconductor (CAC-OS) applicable to a transistor disclosed in one embodiment of the present invention.

In this specification and the like, “c-axis aligned crystal (CAAC)” or “cloud-aligned composite (CAC)” might be stated. Note that CAAC refers to an example of a crystal structure, and CAC refers to an example of a function or a material composition.

A CAC-OS or a CAC metal oxide has a conducting function in a part of the material and has an insulating function in another part of the material; as a whole, the CAC-OS or the CAC metal oxide has a function of a semiconductor. In the case where the CAC-OS or the CAC metal oxide is used in an active layer of a transistor, the conducting function is to allow electrons (or holes) serving as carriers to flow, and the insulating function is to not allow electrons serving as carriers to flow. By the complementary action of the conducting function and the insulating function, the CAC-OS or the CAC metal oxide can have a switching function (on/off function). In the CAC-OS or the CAC metal oxide, separation of the functions can maximize each function.

The CAC-OS or the CAC metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

Furthermore, in the CAC-OS or the CAC metal oxide, the conductive regions and the insulating regions each have a size greater than or equal to 0.5 nm and less than or equal to 10 nm, preferably greater than or equal to 0.5 nm and less than or equal to 3 nm and are dispersed in the material, in some cases.

The CAC-OS or the CAC metal oxide includes components having different bandgaps. For example, the CAC-OS or the CAC metal oxide contains a component having a wide gap due to the insulating region and a component having a narrow gap due to the conductive region. In the case of such a composition, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS or the CAC metal oxide is used in a channel formation region of a transistor, high current drive capability in the on state of the transistor, that is, a high on-state current and high field-effect mobility, can be obtained.

In other words, the CAC-OS or the CAC metal oxide can be called a matrix composite or a metal matrix composite.

### [Structure of Metal Oxide]

An oxide semiconductor is classified into a single crystal oxide semiconductor and a non-single-crystal oxide semiconductor. Examples of a non-single-crystal oxide semiconductor include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

The CAAC-OS has c-axis alignment, its nanocrystals are connected in the a-b plane direction, and its crystal structure has distortion. Note that distortion refers to a portion where the direction of a lattice arrangement changes between a region with a uniform lattice arrangement and another region with a uniform lattice arrangement in a region where the nanocrystals are connected.

The shape of the nanocrystal is basically a hexagon but is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of distortion in the CAAC-OS. That is, a lattice arrangement is distorted and thus formation of a grain boundary is inhibited. This is probably because the CAAC-OS can tolerate distortion owing to a low density of oxygen atom arrangement in the a-b plane direction, a change in interatomic bond distance by substitution of a metal element, and the like.

The CAAC-OS tends to have a layered crystal structure (also referred to as a stacked-layer structure) in which a layer containing indium and oxygen (hereinafter, In layer) and a layer containing the element M, zinc, and oxygen (hereinafter, (M, Zn) layer) are stacked. Note that indium and the element M can be replaced with each other, and when the element M of the (M, Zn) layer is replaced by indium, the layer can also be referred to as an (In, M, Zn) layer. When indium of the In layer is replaced by the element M, the layer can also be referred to as an (In, M) layer.

The CAAC-OS is an oxide semiconductor with high crystallinity. By contrast, in the CAAC-OS, a reduction in electron mobility due to the grain boundary is less likely to occur because a clear grain boundary cannot be observed. Entry of impurities, formation of defects, or the like might decrease the crystallinity of an oxide semiconductor. This means that the CAAC-OS has small amounts of impurities and defects (e.g., oxygen vacancies). Thus, an oxide semiconductor including a CAAC-OS is physically stable. Therefore, the oxide semiconductor including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different nanocrystals in the nc-OS. Thus, the orientation of the whole film is not observed. Accordingly, in some cases, the nc-OS cannot be distinguished from an a-like OS or an amorphous oxide semiconductor, depending on an analysis method.

The a-like OS has a structure intermediate between those of the nc-OS and the amorphous oxide semiconductor. The a-like OS has a void or a low-density region. That is, the a-like OS has low crystallinity as compared with the nc-OS and the CAAC-OS.

An oxide semiconductor can have any of various structures which show various different properties. Two or more of the amorphous oxide semiconductor, the polycrystalline oxide semiconductor, the a-like OS, the nc-OS, and the CAAC-OS may be included in an oxide semiconductor of one embodiment of the present invention.

### [Transistor Containing Oxide Semiconductor]

Next, the case where the oxide semiconductor is used for a transistor will be described.

When the oxide semiconductor is used in a transistor, the transistor can have high field-effect mobility. In addition, the transistor can have high reliability.

Moreover, an oxide semiconductor with low carrier density is preferably used for the transistor. In order to reduce the carrier density of the oxide semiconductor film, the concentration of impurities in the oxide semiconductor film is reduced so that the density of defect states can be reduced. In this specification and the like, a state with a low impurity concentration and a low density of defect states is referred to as a highly purified intrinsic or substantially highly purified intrinsic state. The oxide semiconductor has, for example, a carrier density lower than 8×10¹¹/cm³, preferably lower than 1×10¹¹/cm³, and further preferably lower than 1×10¹°/cm³, and higher than or equal to 1×10⁻⁹/cm³.

A highly purified intrinsic or substantially highly purified intrinsic oxide semiconductor film has a low density of defect states and accordingly has a low density of trap states in some cases.

Charges trapped by the trap states in the oxide semiconductor take a long time to be released and may behave like fixed charges. Thus, a transistor whose channel formation region is formed in the oxide semiconductor having a high density of trap states has unstable electrical characteristics in some cases.

In order to obtain stable electrical characteristics of the transistor, it is effective to reduce the concentration of impurities in the oxide semiconductor. In addition, in order to reduce the concentration of impurities in the oxide semiconductor, the concentration of impurities in a film that is adjacent to the oxide semiconductor is preferably reduced. As examples of the impurities, hydrogen, nitrogen, alkali metal, alkaline earth metal, iron, nickel, silicon, and the like are given.

### [Impurity]

Here, the influence of impurities in the oxide semiconductor is described.

When silicon or carbon that is one of Group 14 elements is contained in the oxide, defect states are formed. Thus, the concentration of silicon or carbon (the concentration is measured by SIMS) in the oxide semiconductor and the concentration of silicon or carbon in the vicinity of an interface with the oxide semiconductor (the concentration is measured by secondary ion mass spectrometry, SIMS) is set to be lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated, in some cases. Thus, a transistor including an oxide semiconductor that contains an alkali metal or an alkaline earth metal is likely to be a normally-on transistor. Therefore, it is preferable to reduce the concentration of an alkali metal or an alkaline earth metal in the oxide semiconductor. Specifically, the concentration of alkali metal or alkaline earth metal in the oxide semiconductor, which is measured by SIMS, is lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase of carrier density.

Thus, a transistor whose semiconductor includes an oxide semiconductor that contains nitrogen is likely to be a normally-on transistor. For this reason, nitrogen in the oxide semiconductor is preferably reduced as much as possible; for example, the concentration of nitrogen in the oxide semiconductor measured by SIMS is set to lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Hydrogen contained in an oxide semiconductor reacts with oxygen bonded to a metal atom to be water, and thus causes an oxygen vacancy, in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor including an oxide semiconductor that contains hydrogen is likely to be normally-on. For this reason, hydrogen in the oxide semiconductor is preferably reduced as much as possible. Specifically, the hydrogen concentration of the oxide semiconductor measured by SIMS is lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurity concentration is used for a channel formation region in a transistor, the transistor can have stable electrical characteristics.

### <Method for Manufacturing Semiconductor Device>

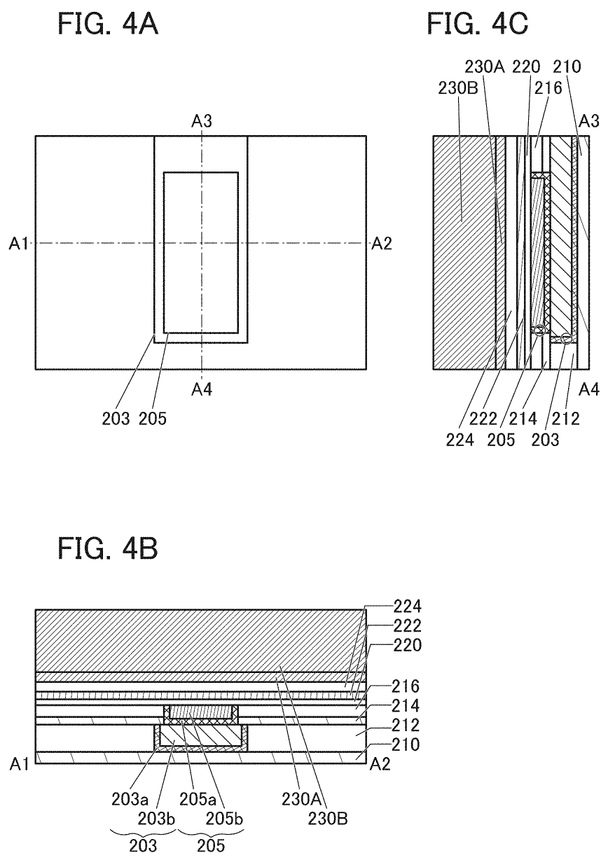

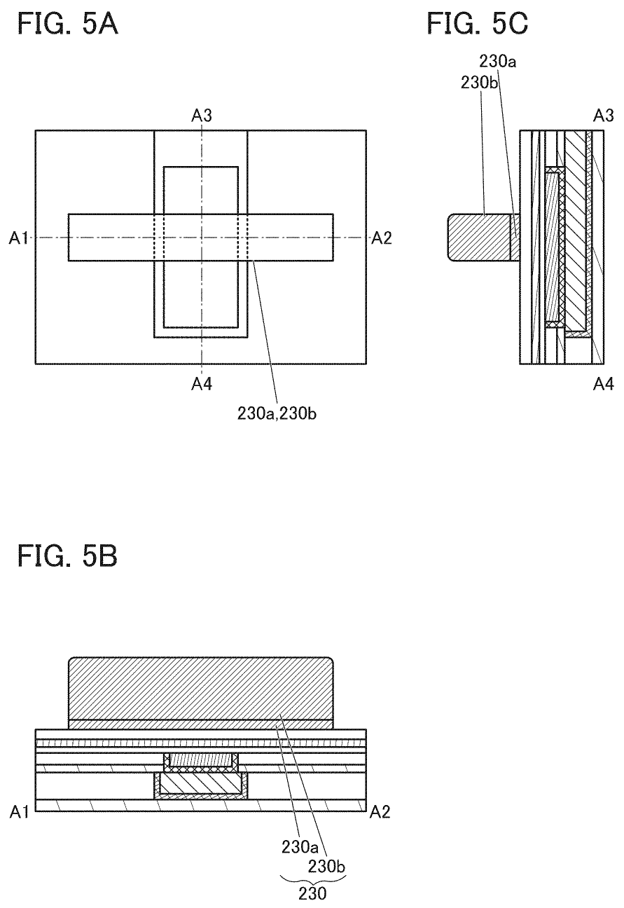

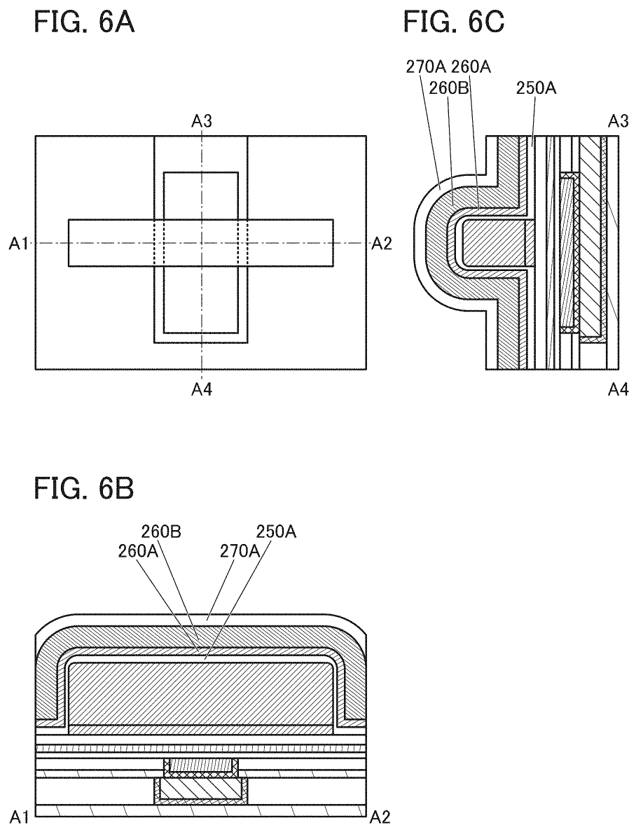

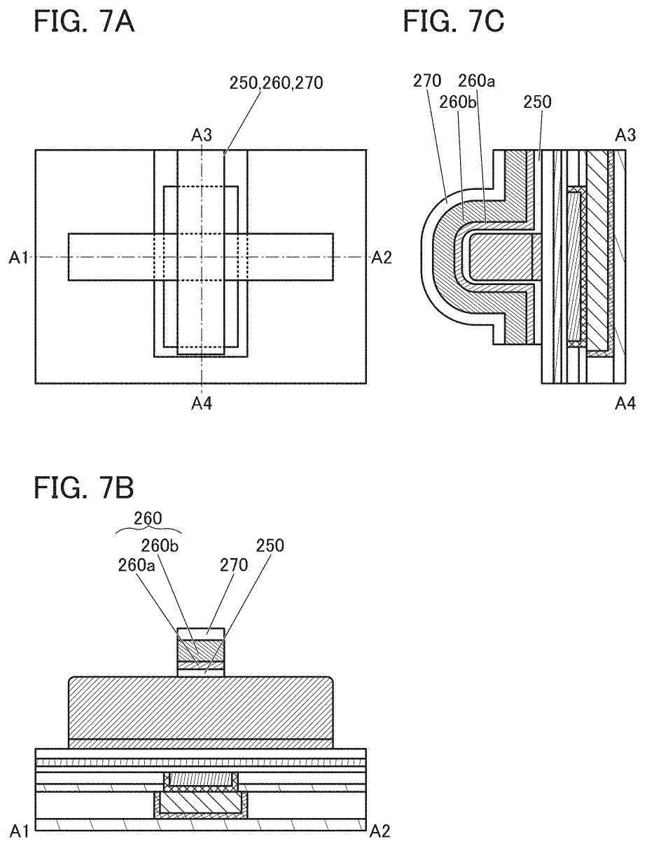

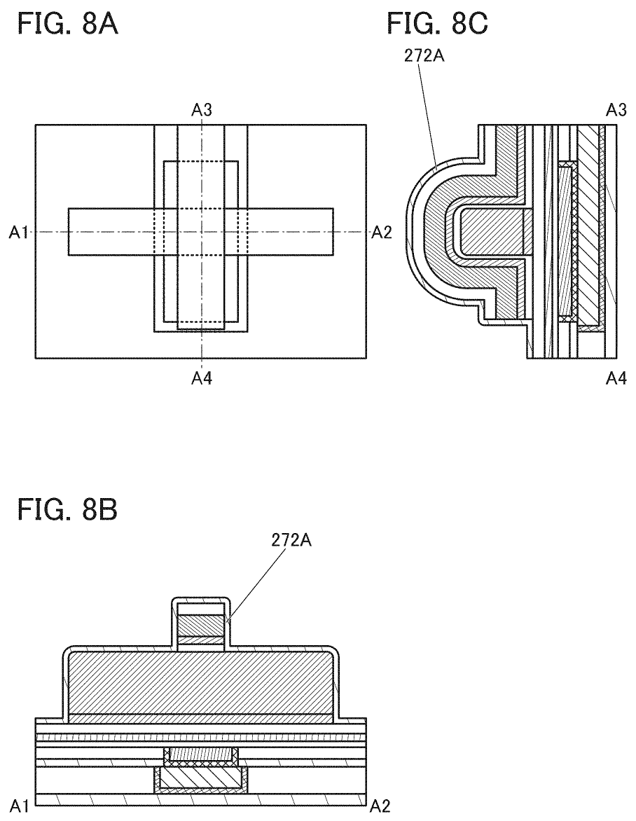

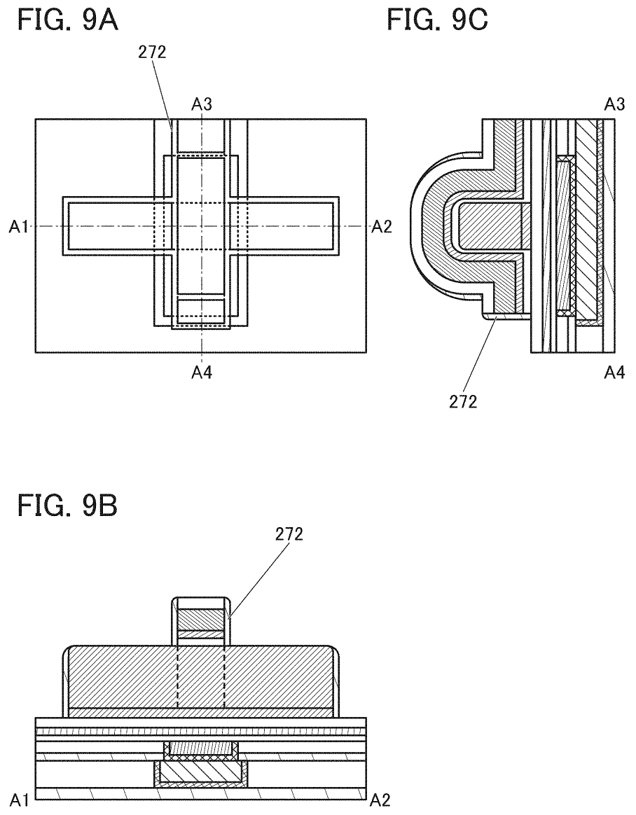

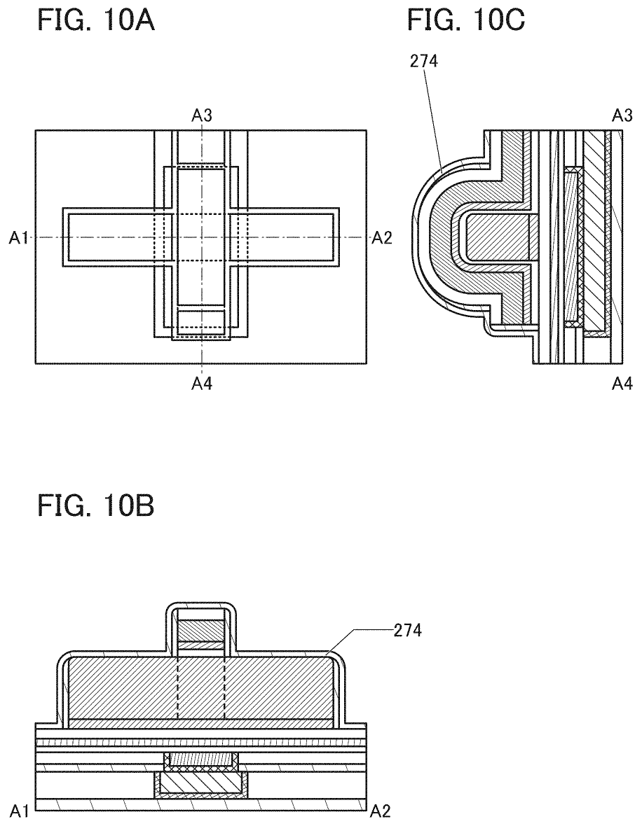

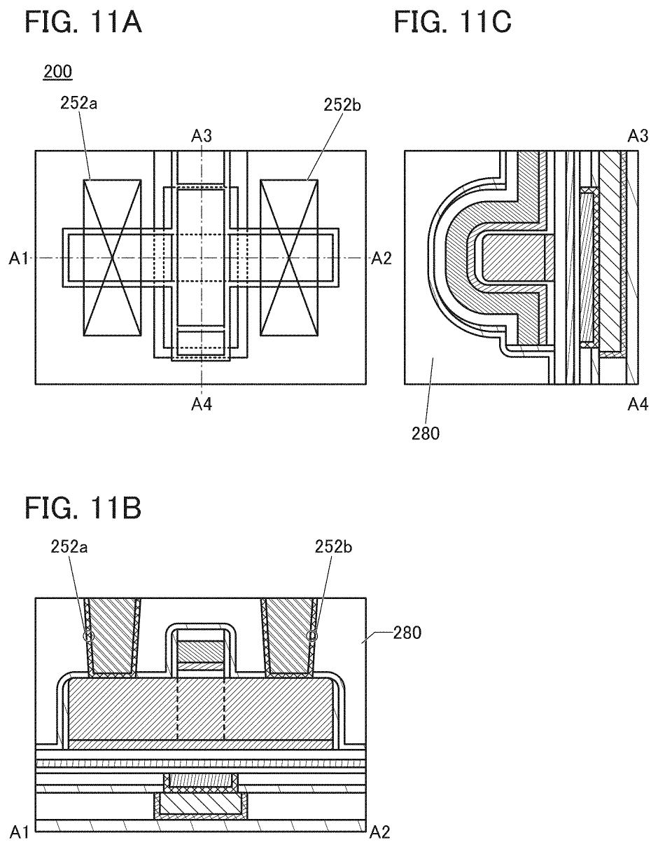

Next, a method for manufacturing a semiconductor device including the transistor 200 illustrated in FIGS. 3A to 3C will be described with reference to FIGS. 4A to 4C to FIGS. 11A to 11C. FIG. 4A, FIG. 5A, FIG. 6A, FIG. 7A, FIG. 8A, FIG. 9A, FIG. 10A, and FIG. 11A are top views. FIG. 4B, FIG. 5B, FIG. 6B, FIG. 7B, FIG. 8B, FIG. 9B, FIG. 10B, and FIG. 11B are cross-sectional views taken along dashed-dotted lines A1-A2 in FIG. 4A, FIG. 5A, FIG. 6A, FIG. 7A, FIG. 8A, FIG. 9A, FIG. 10A, and FIG. 11A. FIG. 4C, FIG. 5C, FIG. 6C, FIG. 7C, FIG. 8C, FIG. 9C, FIG. 10C, and FIG. 11C are cross-sectional views taken along dashed-dotted lines A3-A4 in FIG. 4A, FIG. 5A, FIG. 6A, FIG. 7A, FIG. 8A, FIG. 9A, FIG. 10A, and FIG. 11A.

First, a substrate (not illustrated) is prepared, and the insulator 210 is formed over the substrate. The insulator 210 can be formed by a sputtering method, a chemical vapor deposition (CVD) method, a molecular beam epitaxy (MBE) method, a pulsed laser deposition (PLD) method, an ALD method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

The use of a PECVD method can provide a high-quality film at a relatively low temperature. Furthermore, a thermal CVD method does not use plasma and thus causes less plasma damage to an object. For example, a wiring, an electrode, an element (e.g., transistor or capacitor), or the like included in a semiconductor device might be charged up by receiving charges from plasma. In that case, accumulated charges might break the wiring, electrode, element, or the like included in the semiconductor device. By contrast, when a thermal CVD method not using plasma is employed, such plasma damage is not caused and the yield of the semiconductor device can be increased. A thermal CVD method does not cause plasma damage during deposition, so that a film with few defects can be obtained.

An ALD method also causes less plasma damage to an object. An ALD method does not cause plasma damage during deposition, so that a film with few defects can be obtained.

Unlike in a deposition method in which particles ejected from a target or the like are deposited, in a CVD method and an ALD method, a film is formed by reaction at a surface of an object. Thus, a CVD method and an ALD method enable favorable step coverage almost regardless of the shape of an object. In particular, an ALD method enables excellent step coverage and excellent thickness uniformity and can be favorably used for covering a surface of an opening with a high aspect ratio, for example. On the other hand, an ALD method has a relatively low deposition rate; thus, it is sometimes preferable to combine an ALD method with another deposition method with a high deposition rate such as a CVD method.

When a CVD method or an ALD method is used, composition of a film to be formed can be controlled with a flow rate ratio of the source gases. For example, by a CVD method or an ALD method, a film with a certain composition can be formed depending on a flow rate ratio of the source gases. Moreover, with a CVD method or an ALD method, by changing the flow rate ratio of the source gases while forming the film, a film whose composition is continuously changed can be formed. In the case where the film is formed while changing the flow rate ratio of the source gases, as compared to the case where the film is formed using a plurality of deposition chambers, time taken for the film formation can be reduced because time taken for transfer and pressure adjustment is omitted. Thus, semiconductor devices can be manufactured with improved productivity in some cases.

In this embodiment, aluminum oxide is formed as the insulator 210 by a sputtering method. The insulator 210 may have a multilayer structure. For example, the multilayer structure may be formed in such a manner that an aluminum oxide is formed by a sputtering method and an aluminum oxide is formed over the aluminum oxide by an ALD method. Alternatively, the multilayer structure may be formed in such a manner that an aluminum oxide is formed by an ALD method and an aluminum oxide is formed over the aluminum oxide by a sputtering method.

Then, the insulator 212 is formed over the insulator 210. The insulator 212 can be formed by a sputtering method, a CVD method, an MBE method, a PLD method, an ALD method, or the like. In this embodiment, as the insulator 212, silicon oxide is formed by a CVD method.

Then, openings are formed in the insulator 212 to reach the insulator 210. Examples of the openings include grooves and slits. A region where the opening is formed may be referred to as an opening portion. The opening can be formed by wet etching; however, dry etching is suitable for microfabrication. The insulator 210 is preferably an insulator that serves as an etching stopper film used in forming the groove by etching the insulator 212. For example, in the case where a silicon oxide film is used for the insulator 212 in which the groove is to be formed, the insulator 210 is preferably formed using a silicon nitride film, an aluminum oxide film, or a hafnium oxide film.

After formation of the openings, a conductive film to be the conductor 203a is formed. The conductive film preferably includes a conductor that has a function of inhibiting the penetration of oxygen. For example, tantalum nitride, tungsten nitride, or titanium nitride can be used. Alternatively, a stacked-layer film formed using the conductor and tantalum, tungsten, titanium, molybdenum, aluminum, copper, or a molybdenum-tungsten alloy can be used. The conductive film to be the conductor 203a can be formed by a sputtering method, a CVD method, an MBE method, a PLD method, an ALD method, or the like.

In this embodiment, as the conductive film to be the conductor 203a, tantalum nitride or a stacked film of tantalum nitride and titanium nitride formed over the tantalum nitride is formed by a sputtering method. Even when a metal that is easily diffused, such as copper, is used for the conductor 203b to be described later, the use of such a metal nitride as the conductor 203a can prevent the metal from being diffused to the outside of the conductor 203a.

Next, a conductive film to be the conductor 203b is formed over the conductive film to be the conductor 203a. The conductive film can be formed by a sputtering method, a CVD method, an MBE method, a PLD method, an ALD method, or the like. In this embodiment, as the conductive film to be the conductor 203b, a low-resistant conductive material such as copper is formed.

Next, by CMP treatment, the conductive film to be the conductor 203a and the conductive film to be the conductor 203b are partly removed to expose the insulator 212. As a result, the conductive film to be the conductor 203a and the conductive film to be the conductor 203b remain only in the openings. Thus, the conductor 203 including the conductors 203a and 203b, which has a flat top surface, can be formed (see FIGS. 4A to 4C). Note that the insulator 212 is partly removed by the CMP treatment in some cases.

Next, the insulator 214 is formed over the conductor 203. The insulator 214 can be formed by a sputtering method, a CVD method, an MBE method, a PLD method, an ALD method, or the like. In this embodiment, as the insulator 214, silicon nitride is formed by a CVD method. Even when metal that is likely to be diffused, such as copper, is used for the conductor 203b, the use of an insulator through which copper is less likely to pass, such as silicon nitride, as the insulator 214 can prevent the metal from being diffused into the layers above the insulator 214.

Next, the insulator 216 is formed over the insulator 214. The insulator 216 can be formed by a sputtering method, a CVD method, an MBE method, a PLD method, an ALD method, or the like. In this embodiment, silicon oxide is formed as the insulator 216 by a CVD method.

Next, an opening reaching the conductor 203 is formed in the insulators 214 and 216. The opening can be formed by wet etching; however, dry etching is suitable for microfabrication.

After formation of the opening, a conductive film to be the conductor 205a is formed. The conductive film to be the conductor 205a preferably includes a conductive material that has a function of inhibiting the penetration of oxygen. For example, tantalum nitride, tungsten nitride, or titanium nitride can be used. Alternatively, a stacked-layer film of the conductor and tantalum, tungsten, titanium, molybdenum, aluminum, copper, or a molybdenum-tungsten alloy can be used. The conductive film to be the conductor 205a can be formed by a sputtering method, a CVD method, an MBE method, a PLD method, an ALD method, or the like.

In this embodiment, tantalum nitride is formed as a conductive film to be the conductor 205a by a sputtering method.

Next, a conductive film to be the conductor 205b is formed over the conductive film to be the conductor 205a. The conductive film can be formed by a sputtering method, a CVD method, an MBE method, a PLD method, an ALD method, or the like.

In this embodiment, as the conductive film to be the conductor 205b, titanium nitride is formed by a CVD method and tungsten is formed by a CVD method over the titanium nitride.

Next, by CMP treatment, the conductive film to be the conductor 205a and the conductive film to be the conductor 205b are partly removed to expose the insulator 216. As a result, the conductive film to be the conductor 205a and the conductive film to be the conductor 205b remain only in the opening. Thus, the conductor 205 including the conductors 205a and 205b, which has a flat top surface, can be formed (see FIGS. 4A to 4C). Note that the insulator 216 is partly removed by the CMP treatment in some cases.

Next, the insulator 220 is formed over the insulator 216 and the conductor 205. The insulator 220 can be formed by a sputtering method, a CVD method, an MBE method, a PLD method, an ALD method, or the like.

Then, the insulator 222 is formed over the insulator 220. The insulator 222 can be formed by a sputtering method, a CVD method, an MBE method, a PLD method, an ALD method, or the like.

It is particularly preferable that hafnium oxide be formed as the insulator 222 by an ALD method. Hafnium oxide formed by an ALD method has a barrier property against oxygen, hydrogen, and water. When the insulator 222 has a barrier property against hydrogen and water, hydrogen and water contained in components provided around the transistor 200 are not diffused into the transistor 200, and generation of oxygen vacancies in the oxide 230 can be inhibited.

Then, the insulator 224 is formed over the insulator 222. The insulator 224 can be formed by a sputtering method, a CVD method, an MBE method, a PLD method, an ALD method, or the like (see FIGS. 4A to 4C).

Subsequently, heat treatment is preferably performed. The heat treatment can be performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The heat treatment is performed in a nitrogen atmosphere, an inert gas atmosphere, or an atmosphere containing an oxidizing gas at 10 ppm or more, 1% or more, or 10% or more. The heat treatment may be performed under a reduced pressure. Alternatively, the heat treatment may be performed in such a manner that heat treatment is performed in a nitrogen atmosphere or an inert gas atmosphere, and then another heat treatment is performed in an atmosphere containing an oxidizing gas at 10 ppm or more, 1% or more, or 10% or more in order to compensate for released oxygen.

By the above heat treatment, impurities such as hydrogen and water included in the insulator 224 can be removed, for example.

Alternatively, in the heat treatment, plasma treatment using oxygen may be performed under a reduced pressure. The plasma treatment using oxygen is preferably performed using an apparatus including a power source for generating high-density plasma using microwaves, for example. Alternatively, a power source for applying a radio frequency (RF) to a substrate side may be provided. The use of high-density plasma enables high-density oxygen radicals to be produced, and application of the RF to the substrate side allows oxygen radicals generated by the high-density plasma to be efficiently introduced into the insulator 224. Alternatively, after plasma treatment using an inert gas with the apparatus, plasma treatment using oxygen in order to compensate for released oxygen may be performed. Note that the heat treatment is not necessarily performed in some cases.

This heat treatment can also be performed after the formation of the insulator 220 and after the formation of the insulator 222. Although the heat treatment can be performed under the conditions for the heat treatment, heat treatment after the formation of the insulator 220 is preferably performed in an atmosphere containing nitrogen.

In this embodiment, the heat treatment is performed in a nitrogen atmosphere at 400° C. for one hour after formation of the insulator 224.

Next, an oxide film 230A to be the oxide 230a and an oxide film 230B to be the oxide 230b are sequentially formed over the insulator 224 (see FIGS. 4A to 4C). Note that the oxide films are preferably formed successively without exposure to the air. When the oxide films are formed without exposure to the air, impurities or moisture from the air can be prevented from being attached to the oxide films 230A and 230B, so that the interface between the oxide films 230A and 230B and the vicinity of the interface can be kept clean.

The oxide films 230A and 230B can be formed by a sputtering method, a CVD method, an MBE method, a PLD method, an ALD method, or the like. It is suitable to use a sputtering method because the oxide films 230A and 230B can have higher density. As a sputtering gas, a rare gas (typified by argon), oxygen, or a mixed gas of a rare gas and oxygen can be used. Deposition may be performed in the state where the substrate is heated. Here, the oxide film 230B is preferably formed thicker than at least the oxide film 230A.

In the case where the oxide films 230A and 230B are formed by a sputtering method, for example, oxygen or a mixed gas of oxygen and a rare gas is used as a sputtering gas. By increasing the proportion of oxygen in the sputtering gas, the amount of excess oxygen in the oxide films to be formed can be increased. In the case where the above oxide films are formed by a sputtering method, the above In-M-Zn oxide target can be used.

In particular, when the oxide film 230A is formed, part of oxygen contained in the sputtering gas is supplied to the insulator 224, in some cases. Note that the proportion of oxygen in the sputtering gas used for the oxide film 230A is preferably higher than or equal to 70%, further preferably higher than or equal to 80%, and still further preferably 100%.

In the case where the oxide film 230B is formed by a sputtering method, the proportion of oxygen in the sputtering gas is set higher than or equal to 0% and lower than or equal to 30%, preferably higher than or equal to 5% and lower than or equal to 20%, so that an oxygen-deficient oxide semiconductor is formed. A transistor including an oxygen-deficient oxide semiconductor can have relatively high field-effect mobility.

In the case where the oxide film 230A and the oxide film 230B are formed by a sputtering method, water and the like serving as impurities for the oxide film 230A and the oxide film 230B are preferably removed from the substrate and a chamber in a sputtering apparatus as much as possible. To remove the impurities, the chamber is preferably evacuated to a high vacuum region at approximately 1×10⁻⁴ Pa to 5×10⁻⁷ Pa with an adsorption vacuum evacuation pump such as a cryopump. In addition, the ultimate pressure of the chamber is preferably reduced to an ultra-high vacuum region (also referred to as a UHV region) at approximately 1×10⁻⁵ Pa to 1×10⁻⁸ Pa.

In this embodiment, the oxide film 230A is formed by a sputtering method using a target containing In, Ga, and Zn at an atomic ratio of 1:3:4, and the oxide film 230B is formed by a sputtering method using a target containing In, Ga, and Zn at an atomic ratio of 4:2:4.1. Note that each of the oxide films is formed using appropriate deposition conditions and an atomic ratio to have required characteristics of the oxide 230.

Next, heat treatment may be performed. For the heat treatment, the conditions for the heat treatment can be used. By the heat treatment, impurities such as hydrogen and water contained in the oxide films 230A and 230B can be removed, for example. In this embodiment, treatment is performed in a nitrogen atmosphere at 400° C. for one hour, and successively another treatment is performed in an oxygen atmosphere at 400° C. for one hour.

Then, the oxide films 230A and 230B are processed into island shapes to form the oxides 230a and 230b (see FIGS. 5A to 5C). At this time, the insulator 224 may also be processed into an island shape. In that case, the insulator 222 functions as an etching stopper.

The oxide 230 is formed so that at least part thereof overlaps with the conductor 205. It is preferable that the side surface of the oxide 230 be substantially perpendicular to the insulator 222, in which case a plurality of the transistors 200 can be provided at high density in a small area. Note that an angle formed by the side surface of the oxide 230 and the top surface of the insulator 222 may be an acute angle. In that case, the angle formed by the side surface of the oxide 230 and the top surface of the insulator 222 is preferably as large as possible.

The oxide 230 has a curved surface between the side surface and the top surface. That is, an end portion of the side surface and an end portion of the top surface are preferably curved (hereinafter such a curved shape is also referred to as a rounded shape). A radius of curvature of the curved surface at the end portion of the side surface of the oxide 230b is greater than or equal to 3 nm and less than or equal to 10 nm, preferably greater than or equal to 5 nm and less than or equal to 6 nm.

Note that when the end portions are curved, the coverage with films formed later in the manufacturing process can be improved.

Note that the oxide films may be processed by a lithography method. The processing can be performed by a dry etching method or a wet etching method. A dry etching method is suitable for microfabrication.

In the lithography method, first, a resist is exposed to light through a mask. Next, a region exposed to light is removed or left using a developing solution, so that a resist mask is formed. Then, etching through the resist mask is conducted. As a result, a conductor, a semiconductor, an insulator, or the like can be processed in to a desired shape. The resist mask is formed by, for example, exposure of the resist to light using KrF excimer laser light, ArF excimer laser light, extreme ultraviolet (EUV) light, or the like. Alternatively, a liquid immersion technique may be employed in which a portion between a substrate and a projection lens is filled with liquid (e.g., water) to perform light exposure. An electron beam or an ion beam may be used instead of the above-mentioned light. Note that a mask is not necessary in the case of using an electron beam or an ion beam. To remove the resist mask, dry etching treatment such as ashing or wet etching treatment can be used. Alternatively, wet etching treatment can be performed after dry etching treatment. Further alternatively, dry etching treatment can be performed after wet etching treatment.

A hard mask formed of an insulator or a conductor may be used instead of the resist mask. In the case where a hard mask is used, a hard mask with a desired shape can be formed in the following manner: an insulating film or a conductive film that is the material of the hard mask is formed over the oxide film 230B, a resist mask is formed thereover, and then the material of the hard mask is etched. The etching of the oxide films 230A and 230B may be performed after or without removal of the resist mask. In the latter case, the resist mask may be removed during the etching. The hard mask may be removed by etching after the etching of the oxide films. The hard mask does not need to be removed in the case where the material of the hard mask does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, the capacitively coupled plasma etching apparatus may have a structure in which different high-frequency power sources are applied to one of the parallel plate type electrodes. Alternatively, the capacitively coupled plasma etching apparatus may have a structure in which high-frequency power sources with the same frequency are applied to the parallel plate type electrodes. Alternatively, the capacitively coupled plasma etching apparatus may have a structure in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In some cases, the treatment such as dry etching causes the attachment or diffusion of impurities due to an etching gas or the like to a surface or an inside of the oxide 230a, the oxide 230b, or the like. Examples of the impurities include fluorine and chlorine.

In order to remove the impurities, cleaning is performed. As the cleaning, any of wet cleaning using a cleaning solution or the like, plasma treatment using plasma, cleaning by heat treatment, and the like can be performed by itself or in appropriate combination.

The wet cleaning may be performed using an aqueous solution in which oxalic acid, phosphoric acid, hydrofluoric acid, or the like is diluted with carbonated water or pure water. Alternatively, ultrasonic cleaning using pure water or carbonated water may be performed. In this embodiment, ultrasonic cleaning using pure water or carbonated water is performed.

Next, heat treatment may be performed. For the heat treatment, the conditions for the above heat treatment can be used.

Next, an insulating film 250A, a conductive film 260A, a conductive film 260B, and an insulating film 270A are formed in this order over the insulator 222 and the oxide 230 (see FIGS. 6A to 6C).

The insulating film 250A can be formed by a sputtering method, a CVD method, an MBE method, a PLD method, an ALD method, or the like. The insulating film 250A formed by such a deposition method can have a smaller thickness in a region around the side surface of the oxide 230 than in a region around the top surface of the oxide 230.

Note that oxygen is excited by microwaves to generate high-density oxygen plasma, and the insulating film 250A is exposed to the oxygen plasma, whereby oxygen can be supplied to the insulating film 250A and the oxide 230.

Furthermore, heat treatment may be performed. For the heat treatment, the conditions for the above heat treatment can be used. The heat treatment can reduce the moisture concentration and the hydrogen concentration in the insulating film 250A.

The conductive film 260A can be formed by a sputtering method, a CVD method, an MBE method, a PLD method, an ALD method, or the like. Here, when an oxide semiconductor that can be used for the oxide 230 is subjected to treatment for reducing resistance, for example, the oxide semiconductor becomes a conductive oxide. Accordingly, the oxide that can be used for the oxide 230 may be formed as the conductive film 260A and the resistance of the oxide may be reduced in a later step. Note that when the oxide that can be used for the oxide 230 is formed as the conductive film 260A in an atmosphere containing oxygen by a sputtering method, oxygen can be added to the insulator 250. When oxygen is added to the insulator 250, the added oxygen can be supplied to the oxide 230 through the insulator 250.

The conductive film 260B can be formed by a sputtering method, a CVD method, an MBE method, a PLD method, an ALD method, or the like. In the case where the oxide semiconductor that can be used for the oxide 230 is used for the conductive film 260A, the electric resistance of the conductive film 260A can be reduced when the conductive film 260B is formed by a sputtering method, so that the conductive film 260A can be a conductor. Such a conductor can be called an oxide conductor (OC) electrode. Another conductor may be formed over the conductor over the OC electrode by a sputtering method or the like.

Subsequently, heat treatment can be performed. For the heat treatment, the conditions for the above heat treatment can be used. Note that the heat treatment is not necessarily performed in some cases. In this embodiment, the heat treatment is performed at 400° C. in a nitrogen atmosphere for one hour.

The insulating film 270A can be formed by a sputtering method, a CVD method, an MBE method, a PLD method, an ALD method, or the like. Here, the thickness of the insulating film 270A is preferably larger than that of an insulating film 272A to be formed in a later step. In that case, the insulator 270 can easily remain over the conductor 260 when the insulator 272 is formed in a later step.

Next, the insulating film 270A is etched to form the insulator 270. Subsequently, the insulating film 250A, the conductive film 260A, and the conductive film 260B are etched using the insulator 270 as a hard mask to form the insulator 250 and the conductor 260 (the conductors 260a and 260b) (see FIGS. 7A to 7C). The insulator 250, the conductor 260a, the conductor 260b, and the insulator 270 are formed to at least partly overlap with the conductor 205 and the oxide 230. As illustrated in FIG. 7C, the conductor 260 is formed to have the region that faces the top and side surfaces of the oxide 230 in the channel width direction with the insulator 250 positioned therebetween.

The side surface of the insulator 250, a side surface of the conductor 260a, a side surface of the conductor 260b, and the side surface of the insulator 270 are preferably on the same surface.

It is preferable that the surface shared by the side surfaces of the insulator 250, the conductor 260a, the conductor 260b, and the insulator 270 be substantially perpendicular to the substrate. Note that in the cross section, the angle formed by the top surface of the oxide 230 and the side surfaces of the insulator 250, the conductor 260a, the conductor 260b, and the insulator 270 may be an acute angle. In that case, the angle formed by the top surface of the oxide 230 and the side surfaces of the insulator 250, the conductor 260a, the conductor 260b, and the insulator 270 is preferably as large as possible.

Note that an upper portion of the oxide 230 in a region not overlapping with the insulator 250 may be etched by the above etching. In that case, the oxide 230 may be thicker in the region overlapping with the insulator 250 than in the region not overlapping with the insulator 250.

Next, the insulating film 272A is formed to cover the insulator 222, the insulator 224, the oxide 230, the insulator 250, the conductor 260, and the insulator 270 (see FIGS. 8A to 8C). The insulating film 272A can be formed by a sputtering method, a CVD method, an MBE method, a PLD method, an ALD method, or the like. The insulating film 272A is preferably formed with a sputtering apparatus. When the sputtering apparatus is used, an excess-oxygen region can be easily formed in each of the insulator 250 in contact with the insulating film 272A and the insulator 224.

Here, during deposition by a sputtering method, ions and sputtered particles exist between a target and a substrate. For example, a potential E₀ is supplied to the target, to which a power source is connected. A potential E₁ such as a ground potential is supplied to the substrate. Note that the substrate may be electrically floating. In addition, there is a region at a potential E2 between the target and the substrate. The potential relationship is E₂>E₁>E₀.

The ions in plasma are accelerated by a potential difference (E₂−E₀) and collide with the target; accordingly, the sputtered particles are ejected from the target. These sputtered particles are attached to a deposition surface and deposited thereover; as a result, a film is formed. Some ions recoil by the target and might pass through the formed film as recoil ions, and be taken into the insulator 224 and the insulator 250 in contact with a formation surface. The ions in the plasma are accelerated by a potential difference (E₂−E₁) and collide with the deposition surface. At this time, some ions reach the inside of the insulators 250 and 224. When the ions are taken into the insulators 250 and 224, a region into which the ions are taken is formed in the insulators 250 and 224. That is, an excess-oxygen region is formed in the insulators 250 and 224 in the case where the ions include oxygen.

Introduction of excess oxygen to the insulators 250 and 224 can form an excess-oxygen region. The excess oxygen in the insulators 250 and 224 is supplied to the oxide 230 and can fill oxygen vacancies in the oxide 230.

Accordingly, when the insulating film 272A is formed in an oxygen gas atmosphere with a sputtering apparatus, oxygen can be introduced into the insulators 250 and 224 while the insulating film 272A is formed. When aluminum oxide having a barrier property is used for the insulating film 272A, for example, excess oxygen introduced into the insulator 250 can be effectively sealed.

Next, in the oxide 230, the regions 231, 232, 233, and 234 are formed. Each of the regions 231, 232, and 233 is a region whose resistance is reduced by addition of a metal atom such as indium or impurities to the metal oxide used for the oxide 230. Note that each of the regions has higher conductivity than at least the oxide 230b in the region 234.

In order to add impurities to the regions 231, 232, and 233, a dopant which is at least one of the metal element such as indium and the impurities is added through the insulating film 272A, for example.

For the addition of the dopant, an ion implantation method by which an ionized source gas is subjected to mass separation and then added, an ion doping method by which an ionized source gas is added without mass separation, a plasma immersion ion implantation method, or the like can be used. In the case of performing mass separation, ion species to be added and its concentration can be controlled properly. On the other hand, in the case of not performing mass separation, ions at a high concentration can be added in a short time. Alternatively, an ion doping method in which atomic or molecular clusters are generated and ionized may be employed. Instead of the term “dopant,” the term “ion,” “donor,” “acceptor,” “impurity,” “element,” or the like may be used.

In the case where the dopant is added substantially perpendicularly to the substrate surface by any of the above methods, in particular, an ion implantation method or an ion doping method, the dopant is added only to an upper portion of the oxide 230; thus, the concentration of the dopant might vary in the regions 231, 232, and 233. To prevent this, the dopant is preferably added to the oxide 230 at an angle with respect to the substrate surface, in this embodiment.

When an angle θ perpendicular to the substrate surface is 0° and an angle θ parallel to the substrate surface is 90°, the dopant is added at an angle θ greater than 0° and less than 90°, preferably at an angle θ greater than 10° and less than 85°, and further preferably at an angle θ greater than 20° and less than 80°. For example, the dopant is added at an angle θ of 45°.

Note that the dopant is preferably added in a direction parallel to the line A3-A4, that is, a direction parallel to the channel width direction. In that case, the conductor 260 or the like functions as a mask for the region 234 of the oxide 230 where a channel is formed; thus, the dopant can be prevented from being added unintentionally to the region 234.

The dopant is preferably added separately two or more times: from the A3 side and from the A4 side in the channel width direction. In that case, the concentration of the dopant added to the oxide 230 on one of the A3 and A4 sides can be inhibited.

Note that the addition of the dopant is not limited to the above. For example, the dopant may be added while the substrate is rotated around an axis perpendicular to the substrate surface.

Here, when the indium content in the oxide 230 is increased, the carrier density can be increased and the resistance can be decreased. Accordingly, a metal element that improves the carrier density of the oxide 230, such as indium, can be used as the dopant.

That is, when the content of a metal atom such as indium in the regions 231, 232, and 233 in the oxide 230 is increased, the electron mobility can be increased and the resistance can be decreased.

Accordingly, the atomic ratio of indium to the element M at least in the region 231 is greater than the atomic ratio of indium to the element M in the region 234.

As the dopant, the element forming an oxygen vacancy, the element trapped by an oxygen vacancy, or the like may be used. Typical examples of the element are hydrogen, boron, carbon, nitrogen, fluorine, phosphorus, sulfur, chlorine, titanium, and a rare gas. Typical examples of the rare gas element are helium, neon, argon, krypton, and xenon.

Here, the insulating film 272A is provided to cover the oxide 230, the insulator 250, the conductor 260, and the insulator 270. Accordingly, on the top surface of the oxide 230, the thickness of the insulating film 272A in a direction perpendicular to the top surface of the oxide 230 is different between a peripheral portion of the side surfaces of the insulator 250, the conductor 260, and the insulator 270 and a region other than the peripheral portion. That is, the thickness of the insulating film 272A in the peripheral portion of the side surfaces of the insulator 250, the conductor 260, and the insulator 270 is larger than that in the region other than the peripheral portion. Accordingly, when the dopant is added through the insulating film 272A, the regions 231, 232, and 233 can be formed in a self-aligned manner even in a minute transistor whose channel length is approximately 10 nm to 30 nm. The regions 233 may be formed in such a manner that the dopants in the regions 231 and 232 are diffused by heat treatment to be performed in a later step, for example.

When the regions 233 and 232 are provided in the transistor 200, high-resistance regions are not formed between the region 231 functioning as the source region and the drain region and the region 234 where a channel is formed, so that the on-state current and the carrier mobility of the transistor can be increased. Moreover, when the transistor 200 includes the regions 233, the gate does not overlap with the source region and the drain region in the channel length direction, so that formation of unnecessary capacitance can be suppressed, and the leakage current in an off state can be reduced.

Thus, by appropriately selecting the areas of the region 231a and the region 231b, a transistor having electrical characteristics necessary for the circuit design can be easily provided.

Next, the insulating film 272A is subjected to anisotropic etching to form the insulator 272 in contact with the side surfaces of the insulator 250, the conductor 260, and the insulator 270 (see FIGS. 9A to 9C). Dry etching is preferably performed as the anisotropic etching. In this manner, the insulating film 272A in a region on a plane substantially parallel to the substrate surface can be removed, so that the insulator 272 can be formed in a self-aligned manner. When the insulator 270 is made thicker than the insulating film 272A, the insulator 270 and the insulator 272 can remain even when the insulating film 272A over the insulator 270 is removed.

The insulating film 272A may remain also on the side surface of the oxide 230. In that case, coverage with an interlayer film or the like to be formed in a later step can be improved. When the insulator remains on the side surface of the oxide 230, entry of impurities such as water or hydrogen into the oxide 230 and outward diffusion of oxygen from the oxide 230 can be prevented, in some cases.

Since a structure body in which part of the insulating film 272A remains is provided in contact with the side surface of the oxide 230, in the case of forming the insulator 274 containing an element serving as an impurity to form the regions 231a and 231b in the oxide 230 in a later step, the resistance of an interface region between the insulator 224 and the oxide 230 is not lowered, so that generation of leakage current can be inhibited. In the case where a dopant is added such that the concentration of indium has a peak in the oxide 230a when indium is added to the oxide 230, generation of leakage current through the oxide 230a can be inhibited.

As illustrated in FIGS. 9A and 9C, the structure body in which part of the insulating film 272A remains is formed on a side surface of a projecting portion of the insulator 270 and the conductor 260 formed due to the oxide 230, in some cases.

Subsequently, heat treatment can be performed. For the heat treatment, the conditions for the above heat treatment can be used. The heat treatment allows diffusion of the added dopant into the regions 233 in the oxide 230, resulting in an increase in on-state current.

Next, the insulator 274 is formed to cover the insulator 224, the oxide 230, the insulator 272, and the insulator 270 (see FIGS. 10A to 10C).

As the insulator 274, for example, aluminum oxide is preferably formed by an ALD method. The aluminum oxide formed by an ALD method is a dense film having good coverage. In addition, the insulator 274 preferably has a barrier property against oxygen, hydrogen, and water. When the insulator 274 has a barrier property against hydrogen and water, hydrogen and water contained in components around the transistor 200 are not diffused into the transistor 200, and generation of oxygen vacancies in the oxide 230 can be inhibited.

The insulator 274 is preferably in contact with the insulator 222 at an outer edge of the transistor 200. With this structure, the transistor 200 can be surrounded by the insulators each having a barrier property. Furthermore, impurities such as hydrogen or water can be prevented from entering the transistor 200. In addition, oxygen contained in the insulators 224 and 250 can be prevented from diffusing into the interlayer film from the transistor 200.

When such an insulator 274 is provided over the regions 231a and 231b, the carrier density can be prevented from being changed by entry of oxygen or impurities such as excess water or hydrogen into the regions 231a and 231b.

When the insulator 274 containing an element serving as an impurity is formed in contact with the oxide 230, impurities can be added to the regions 231, 232, and 233.

In the case where the insulator 274 containing an element serving as an impurity is formed in contact with the oxide 230, impurity elements such as hydrogen and nitrogen, which are contained in a deposition atmosphere of the insulator 274, are added to the regions 231a and 231b. Oxygen vacancies are formed because of the added impurity elements, and the impurity elements enter the oxygen vacancies mainly in a region of the oxide 230 which is in contact with the insulator 274, thereby increasing the carrier density and reducing the resistance. The impurities are diffused also into the regions 232 and 233 that are not in contact with the insulator 274 at this time, whereby the resistance of the regions 232 and 233 is reduced.

Therefore, the region 231a and the region 231b preferably have a higher concentration of at least one of hydrogen and nitrogen than the region 234. The concentration of hydrogen or nitrogen can be measured by secondary ion mass spectrometry (SIMS) or the like. Here, the concentration of hydrogen or nitrogen in the middle of the region of the oxide 230b that overlaps with the insulator 250 (e.g., a portion in the metal oxide 230b which is located equidistant from both side surfaces in the channel length direction of the insulator 250) is measured as the concentration of hydrogen or nitrogen in the region 234.

The regions 231, 232, and 233 are reduced in resistance when an element forming an oxygen vacancy or an element trapped by an oxygen vacancy is added thereto. Typical examples of the element are hydrogen, boron, carbon, nitrogen, fluorine, phosphorus, sulfur, chlorine, titanium, and a rare gas. Typical examples of the rare gas element are helium, neon, argon, krypton, and xenon. Accordingly, the regions 231, 232, and 233 are made to include one or more of the above elements.

To form the insulator 274 containing an element serving as an impurity, a sputtering method, a CVD method, an MBE method, a PLD method, an ALD method, or the like can be used.

The insulator 274 containing elements serving as impurities is preferably formed in an atmosphere containing at least one of nitrogen and hydrogen. In that case, oxygen vacancies are formed mainly in the region of the oxides 230a and 230b not overlapping with the insulator 250 and the oxygen vacancies and impurity elements such as nitrogen and hydrogen are bonded to each other, leading to an increase in carrier density. In this manner, the regions 231a and 231b with reduced resistance can be formed. For the insulator 274, for example, silicon nitride, silicon nitride oxide, or silicon oxynitride can be formed by a CVD method. In this embodiment, silicon nitride oxide is used for the insulator 274.

Accordingly, in the method for manufacturing a semiconductor device described in this embodiment, a source region and a drain region can be formed in a self-aligned manner owing to the formation of the insulator 274, even in a minute transistor whose channel length is approximately 10 nm to 30 nm. Thus, minute or highly integrated semiconductor devices can be manufactured with high yield.

Here, when the top and side surfaces of the insulator 270 and the conductor 260 and the insulator 250 are covered with the insulator 272, impurity elements such as nitrogen and hydrogen can be prevented from entering the conductor 260 and the insulator 250. Thus, impurity elements such as nitrogen and hydrogen can be prevented from entering the region 234 functioning as the channel formation region of the transistor 200 through the conductor 260 and the insulator 250. Accordingly, the transistor 200 having favorable electrical characteristics can be provided.

The addition of a dopant may be performed after the formation of the insulator 274.

Note that although the regions 231, 232, 233, and 234 are formed through the addition of a dopant or the reduction in the resistance by the formation of the insulator 274 in the above description, this embodiment is not limited thereto. For example, the regions may be formed through both the addition of a dopant and the reduction in the resistance by the formation of the insulator 274. Plasma treatment may be performed.

For example, plasma treatment may be performed on the oxide 230 using the insulator 250, the conductor 260, the insulator 272, and the insulator 270 as a mask. The plasma treatment is performed in an atmosphere containing the above-described element forming oxygen vacancies or an element trapped by oxygen vacancies, for example. The plasma treatment may be performed using an argon gas and a nitrogen gas, for example.

Then, an insulating film to be the insulator 280 is formed over the insulator 274. The insulating film to be the insulator 280 can be formed by a sputtering method, a CVD method, an MBE method, a PLD method, an ALD method, or the like. Alternatively, the insulating film to be the insulator 280 can be formed by a spin coating method, a dipping method, a droplet discharging method (such as an ink-jet method), a printing method (such as screen printing or offset printing), a doctor knife method, a roll coater method, a curtain coater method, or the like. In this embodiment, silicon oxynitride is used for the insulating film.

Next, the insulating film to be the insulator 280 is partly removed to form the insulator 280 (see FIGS. 11A to 11C). The insulator 280 is preferably formed to have a flat top surface. For example, the insulator 280 may have had a flat top surface since the insulating film to be the insulator 280 was formed. Alternatively, for example, the insulator 280 may be planarized by removing the insulator or the like from the top surface after the deposition so that the top surface becomes parallel to a reference surface such as a rear surface of the substrate. Such treatment is referred to as planarization treatment. As the planarization treatment, chemical mechanical polishing (CMP) treatment, dry etching treatment, or the like can be performed. In this embodiment, CMP treatment is used as the planarization treatment. Note that the top surface of the insulator 280 does not necessarily have planarity.

Next, openings reaching the regions 231a and 231b of the oxide 230 are formed in the insulator 280 and the insulator 274. The openings may be formed by a lithography method. Note that in order that the conductors 252a and 252b are provided in contact with a side surface of the oxide 230, the openings are formed such that a side surface of the oxide 230 is exposed in the openings reaching the oxide 230. In the case where the insulator 272 is formed on the side surface of the oxide 230 in regions overlapping with the openings, the insulator 272 is preferably removed at the time of the formation of the openings.

Next, a conductive film to be the conductors 252a and 252b is formed. The conductive film can be formed by a sputtering method, a CVD method, an MBE method, a PLD method, an ALD method, or the like.

Next, the conductive film to be the conductors 252a and 252b is partly removed by CMP treatment to expose the insulator 280. As a result, the conductive film remains only in the openings, so that the conductors 252a and 252b having flat top surfaces can be formed (see FIGS. 11A to 11C).

Through the above process, the semiconductor device including the transistor 200 can be manufactured. By the method for manufacturing a semiconductor device which is described in this embodiment and illustrated in FIGS. 4A to 4C to FIGS. 11A to 11C, the transistor 200 can be formed.

### <Modification Example of Semiconductor Device>

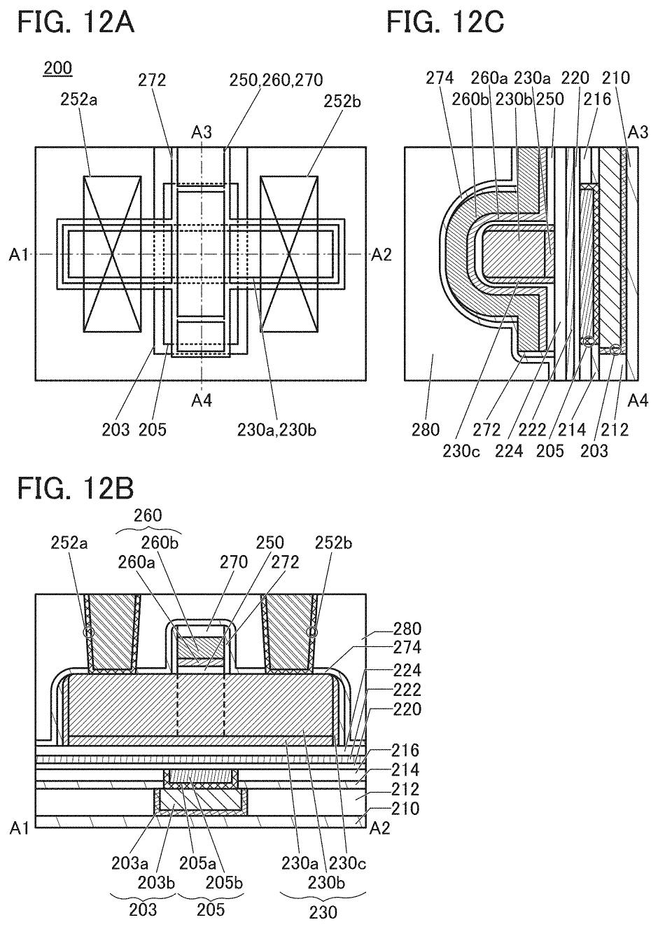

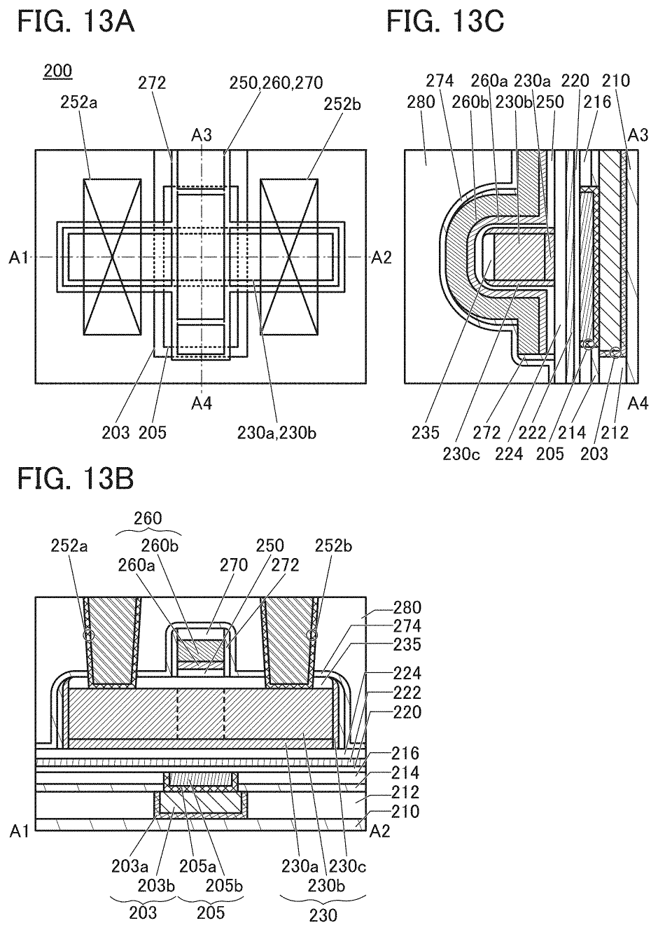

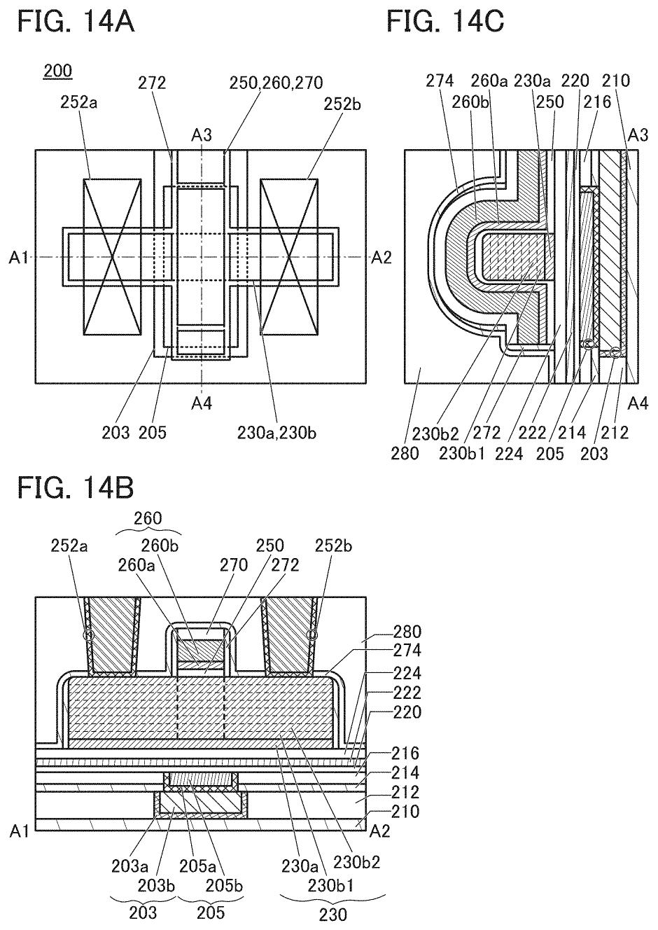

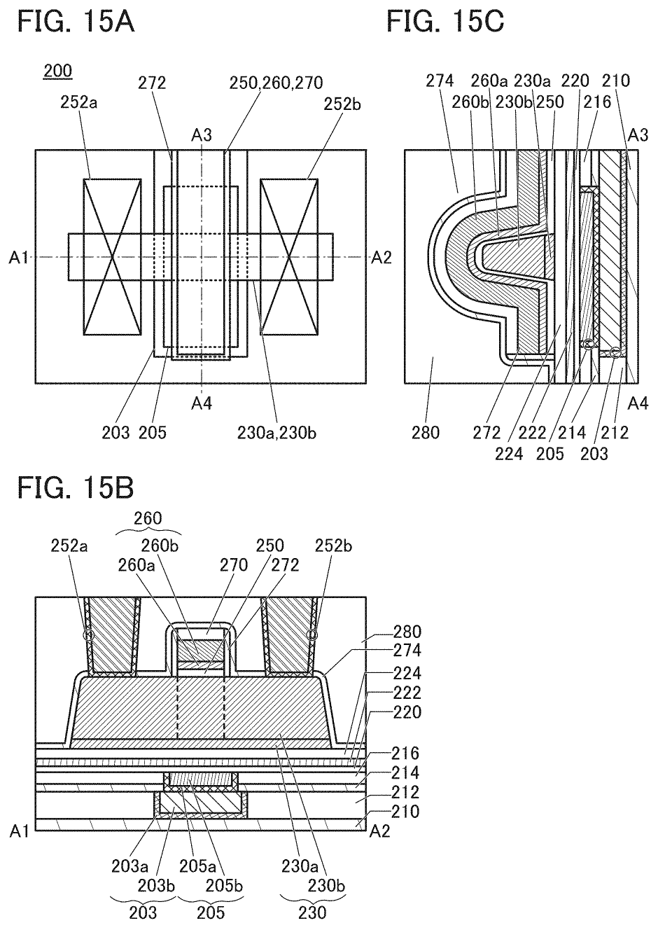

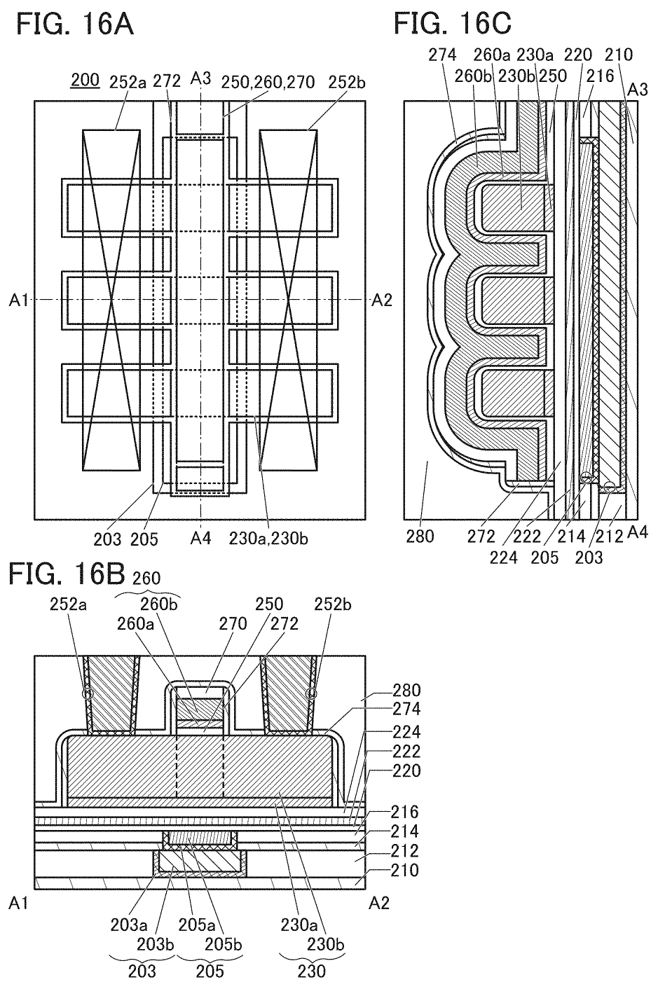

The structure of the semiconductor device described in this embodiment is not limited to the above-described structure. Modification examples of the transistor described in this embodiment will be described below with reference to FIGS. 12A to 12C to FIGS. 16A to 16C. FIG. 12A, FIG. 13A, FIG. 14A, FIG. 15A, and FIG. 16A are each a top view of a semiconductor device including the transistor 200. FIG. 12B, FIG. 13B, FIG. 14B, FIG. 15B, and FIG. 16B are cross-sectional views taken along dashed-dotted lines A1-A2 in FIG. 12A, FIG. 13A, FIG. 14A, FIG. 15A, and FIG. 16A, each of which corresponds to a cross-sectional view in the channel length direction of the transistor 200. FIG. 12C, FIG. 13C, FIG. 14C, FIG. 15C, and FIG. 16C are cross-sectional views taken along dashed-dotted lines A3-A4 in FIG. 12A, FIG. 13A, FIG. 14A, FIG. 15A, and FIG. 16A, each of which corresponds to a cross-sectional view in the channel width direction of the transistor 200. For simplification of the drawing, some components are not illustrated in the top view in FIG. 12A, FIG. 13A, FIG. 14A, FIG. 15A, and FIG. 16A.

The transistor 200 illustrated in FIGS. 12A to 12C is different from the transistor 200 illustrated in FIGS. 1A to 1C in that an oxide 230c is provided in contact with side surfaces of the oxides 230a and 230b. The description of the components of the transistor 200 illustrated in FIGS. 1A to 1C can be referred to for other components.

Since the oxide 230c is in contact with the side surfaces of the oxides 230a and 230b in the transistor 200 illustrated in FIGS. 12A to 12C, diffusion of impurities from a component on an outer side than the oxide 230c into the oxide 230b can be inhibited. The oxide 230c can function as a channel formation region in some cases.

Since the oxide 230c is not formed on the top surface of the oxide 230b, the oxide 230b can be directly in contact with each of the conductors 252a and 252b; accordingly, a high on-state current can be obtained without increasing the contact resistance.

The oxide 230c is preferably formed in a self-aligned manner by anisotropic etching, as with the formation of the insulator 272 illustrated in FIGS. 9A to 9C. Specifically, to form the oxide 230c in contact with the side surfaces of the oxides 230a and 230b, an oxide film to be the oxide 230c is formed after the oxides 230a and 230b are formed in the step illustrated in FIGS. 5A to 5C, and the oxide film is subjected to anisotropic etching. As a result, the insulator 250 is provided in contact with the top surface of the oxide 230b and a side surface of the oxide 230c.

The oxide 230c can be formed using a metal oxide which can be used for the oxide 230a or 230b. The oxide film to be the oxide 230c may be formed under conditions similar to those of an oxide film to be the oxide 230a or 230b. Alternatively, these conditions may be combined for the formation of the oxide film to be the oxide 230c.

In this embodiment, the oxide film to be the oxide 230c is formed by a sputtering method using a target containing In, Ga, and Zn at an atomic ratio of 4:2:4.1. The oxide film may be formed at a proportion of oxygen of 70% or higher, preferably 80% or higher, further preferably 100%.

Note that the above oxide film is formed using appropriate deposition conditions and an atomic ratio to have required characteristics of the oxide 230.

In the case where the oxides 230a and 230c are provided, the conduction band minimum of each of the oxides 230a and 230c is preferably higher than that of the oxide 230b. In other words, the electron affinity of each of the oxides 230a and 230c is preferably smaller than that of the oxide 230b.

Here, the conduction band minimum is gradually varied in the oxides 230a, 230b, and 230c. In other words, the conduction band minimum is continuously varied or continuously connected. To vary the conduction band minimum gradually, the density of defect states in a mixed layer formed at the interface between the oxides 230a and 230b and the interface between the oxides 230b and 230c is decreased.

Specifically, when the oxides 230a and 230b or the oxides 230b and 230c contain the same element (as a main component) in addition to oxygen, a mixed layer with a low density of defect states can be formed. For example, in the case where the oxide 230b is an In-Ga-Zn oxide, it is preferable to use an In-Ga-Zn oxide, a Ga-Zn oxide, gallium oxide, or the like as each of the oxides 230a and 230c.

At this time, a narrow-gap portion formed in the oxide 230b serves as a main carrier path. Since the density of defect states at the interface between the oxides 230a and 230b and the interface between the oxides 230b and 230c can be made low, the influence of interface scattering on carrier conduction is small, and a high on-state current can be obtained.

The transistor 200 illustrated in FIGS. 13A to 13C is different from the transistor 200 illustrated in FIGS. 12A to 12C in that an insulator 235 is provided in contact with the top surface of the oxide 230b. The description of the components of the transistor 200 illustrated in FIGS. 12A to 12C can be referred to for other components.

The insulator 235 can function as a hard mask when the oxides 230a and 230b are processed into island shapes. Furthermore, the insulator 235 can prevent the top surface of the oxide 230b from being etched at the time of the formation of the oxide 230c by anisotropic etching.

The insulator 235 also functions as a gate insulating film of a first gate. Thus, the gate insulating film has a relatively larger thickness on the top surface of the oxide 230 than on a side surface of the oxide 230. Accordingly, when the transistor 200 is turned on, current flows more in a channel in the top surface of the oxide 230b than in a channel in the side surface of the oxide 230b.

The transistor 200 illustrated in FIGS. 14A to 14C is different from the transistor 200 illustrated in FIGS. 1A to 1C in that the oxide 230b has a structure in which a plurality of layers 230b1 and a plurality of layers 230b2 are alternately stacked. The description of the components of the transistor 200 illustrated in FIGS. 1A to 1C can be referred to for other components. When the length of the conductor 260 in the channel length direction is 60 nm and the length of the oxide 230b in the channel width direction is 60 nm, for example, each of the layers 230b1 and 230b2 can have a thickness of approximately 5 nm to 20 nm.

The band gap of each of the layers 230b1 is larger than the band gap of each of the layers 230b2. The above-described CAAC-OS is used for the layers 230b1 and the above-described CAC-OS is used for the layers 230b2, for example.

It is preferable that the layers 230b1 and the layers 230b2 be alternately stacked without exposure to the air. The layers 230b1 and the layers 230b2 are formed by a sputtering method using a target containing In, Ga, and Zn at an atomic ratio of 4:2:4.1, for example. Note that the layers 230b1 and 230b2 can be formed as different layers by adjusting the proportion of oxygen contained in a sputtering gas. To form the layers 230b1, the proportion of oxygen contained in a sputtering gas is set to 70% or higher, preferably to 80% or higher, and further preferably set to 100%. To form the layers 230b2, the proportion of oxygen contained in a sputtering gas is set to 0% or higher and 30% or lower, and preferably to 5% or higher and 20% or lower.

In alternately stacking the layers 230b1 and 230b2, the proportion of oxygen contained in a sputtering gas, which is used for forming the layers 230b1, is set to 70% or higher, preferably to 80% or higher, and further preferably set to 100%, in which case oxygen can be added to a layer (layer 230b2) serving as a base to reduce oxygen vacancies in the layer (layer 230b2) serving as a base. When the layers 230b1 and the layers 230b2 are alternately stacked as described here, the oxide 230b including the layers 230b2 that have few shallow defect states (also referred to as sDOS) can be formed.

It is preferable that the insulator 250 be in contact with a side surface of the oxide 230b in the channel width direction, in other words, side surfaces of the layers 230b1 and 230b2 in the channel width direction, and the conductor 260 be provided to face the oxide 230b with the insulator 250 positioned therebetween, as illustrated in FIG. 14C. Such a structure can prevent the formation of a parasitic channel on the side surface of the oxide 230b.

The transistor 200 illustrated in FIGS. 15A to 15C is different from the transistor 200 illustrated in FIGS. 1A to 1C in that the oxides 230a and 230b have tapered cross sections. The description of the components of the transistor 200 illustrated in FIGS. 1A to 1C can be referred to for other components.

The taper angle to a plane parallel to a substrate surface is approximately greater than or equal to 30° and less than 75°, for example. With the oxides 230a and 230b having such tapered cross sections, a dopant can be added to the oxides 230a and 230b even when the dopant is added substantially perpendicular to the substrate surface. In addition, the insulator 272 can be prevented from remaining on side surfaces of the oxides 230a and 230b, in some cases.

The transistor 200 illustrated in FIGS. 16A to 16C is different from the transistor 200 illustrated in FIGS. 1A to 1C in that there are a plurality of channel formation regions for one gate electrode. The transistor 200 illustrated in FIGS. 16A to 16C can have a high on-state current owing to the plurality of channel formation regions. Furthermore, top and side surfaces of the oxide 230 are covered with the gate electrode in each of the channel formation regions; thus, a high on-state current can be obtained in each of the channel formation regions. Although FIGS. 16A to 16C illustrate an example of a structure including three channel formation regions, the number of channel formation regions is not limited to three. The description of the components of the transistor 200 illustrated in FIGS. 1A to 1C can be referred to for other components.

One embodiment of the present invention can provide a semiconductor device with a high on-state current. One embodiment of the present invention can provide a semiconductor device that can be miniaturized or highly integrated. One embodiment of the present invention can provide a semiconductor device with high frequency characteristics. One embodiment of the present invention can provide a semiconductor device with normally-off electrical characteristics. One embodiment of the present invention can provide a semiconductor device with favorable electrical characteristics. One embodiment of the present invention can provide a semiconductor device that can be manufactured with high productivity.

As described above, the structures, methods, and the like described in this embodiment can be combined with any of the structures, methods, and the like described in the other embodiments as appropriate.

### Embodiment 2

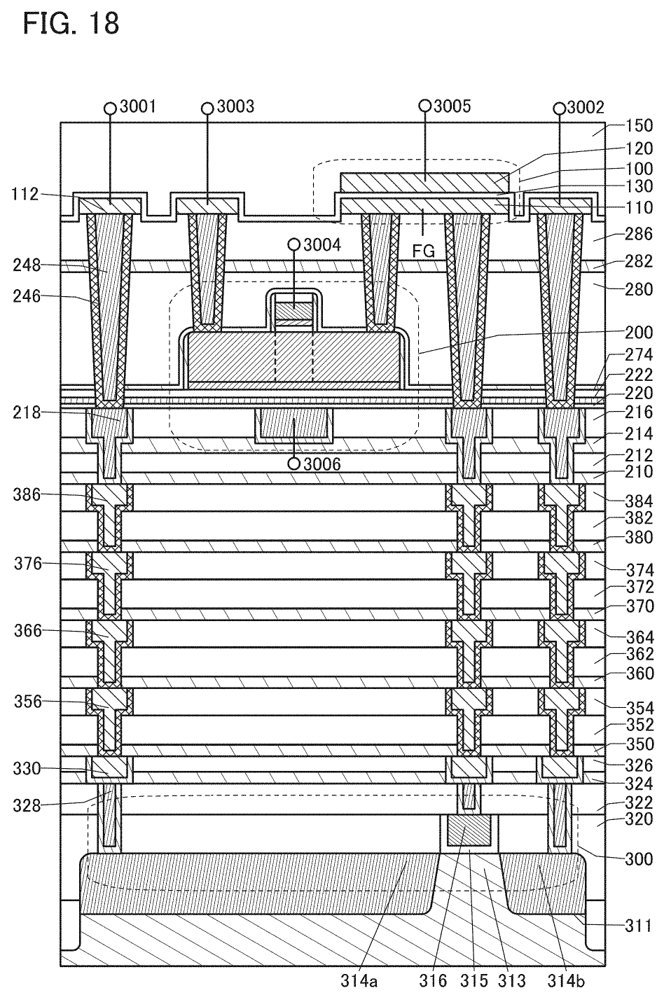

In this embodiment, one embodiment of a semiconductor device will be described with reference to FIG. 18.

### [Memory Device 1]

A semiconductor device illustrated in FIG. 18 includes a transistor 300, a transistor 200, and a capacitor 100.

The transistor 200 is a transistor in which a channel is formed in a semiconductor layer containing an oxide semiconductor. Since the off-state current of the transistor 200 is low, a memory device including the transistor can retain stored data for a long time. In other words, such a memory device does not require refresh operation or has an extremely low frequency of the refresh operation, which leads to a sufficient reduction in power consumption of the memory device.

In FIG. 18, a wiring 3001 is electrically connected to a source of the transistor 300. A wiring 3002 is electrically connected to a drain of the transistor 300. A wiring 3003 is electrically connected to one of a source and a drain of the transistor 200. A wiring 3004 is electrically connected to a first gate of the transistor 200. A wiring 3006 is electrically connected to a second gate of the transistor 200. A gate of the transistor 300 and the other of the source and the drain of the transistor 200 are electrically connected to one electrode of the capacitor 100. A wiring 3005 is electrically connected to the other electrode of the capacitor 100.

The semiconductor device illustrated in FIG. 18 has a feature that the potential of the gate of the transistor 300 can be retained and thus enables writing, retaining, and reading of data as follows.

Writing and retaining of data are described. First, the potential of the wiring 3004 is set to a potential at which the transistor 200 is turned on, so that the transistor 200 is turned on. Accordingly, the potential of the wiring 3003 is supplied to a node FG where the gate of the transistor 300 and the one electrode of the capacitor 100 are electrically connected to each other. That is, a predetermined charge is supplied to the gate of the transistor 300 (writing). Here, one of two kinds of charges providing different potential levels (hereinafter referred to as a low-level charge and a high-level charge) is supplied. After that, the potential of the wiring 3004 is set to a potential at which the transistor 200 is turned off, so that the transistor 200 is turned off. Thus, the charge is retained in the node FG (retaining).

In the case where the off-state current of the transistor 200 is low, the charge of the node FG is retained for a long time.

Next, reading of data is described. An appropriate potential (reading potential) is supplied to the wiring 3005 while a predetermined potential (constant potential) is supplied to the wiring 3001, whereby the potential of the wiring 3002 varies depending on the amount of charge retained in the node FG. This is because in the case of using an n-channel transistor as the transistor 300, an apparent threshold voltage V_{th-H} at the time when a high-level charge is given to the gate of the transistor 300 is lower than an apparent threshold voltage V_{th-L} at the time when a low-level charge is given to the gate of the transistor 300. Here, an apparent threshold voltage refers to the potential of the wiring 3005 which is needed to turn on the transistor 300. Thus, the potential of the wiring 3005 is set to a potential V₀ which is between Vₜₕ₋ₚ and V_{th-L}, whereby the charge supplied to the node FG can be determined. For example, in the case where a high-level charge is supplied to the node FG in writing and the potential of the wiring 3005 is V₀ (>Vₜₕ₋ₚ), the transistor 300 is turned on. Meanwhile, in the case where a low-level charge is supplied to the node FG in writing, even when the potential of the wiring 3005 is V₀ (<V_{th-L}), the transistor 300 remains off. Thus, the data retained in the node FG can be read by determining the potential of the wiring 3002.

### <Structure of Memory Device 1>

The semiconductor device of one embodiment of the present invention includes the transistor 300, the transistor 200, and the capacitor 100 as illustrated in FIG. 18. The transistor 200 is provided above the transistor 300, and the capacitor 100 is provided above the transistor 300 and the transistor 200.

The transistor 300 is provided in and on a substrate 311 and includes a conductor 316, an insulator 315, a semiconductor region 313 that is a part of the substrate 311, and a low-resistance region 314a and a low-resistance region 314b functioning as a source region and a drain region.

The transistor 300 is either a p-channel transistor or an n-channel transistor.

It is preferable that a region of the semiconductor region 313 where a channel is formed, a region in the vicinity thereof, the low-resistance regions 314a and 314b functioning as the source and drain regions, and the like contain a semiconductor such as a silicon-based semiconductor, further preferably single crystal silicon. Alternatively, a material including germanium (Ge), silicon germanium (SiGe), gallium arsenide (GaAs), gallium aluminum arsenide (GaAlAs), or the like may be contained. Silicon whose effective mass is adjusted by applying stress to the crystal lattice and thereby changing the lattice spacing may be contained. Alternatively, the transistor 300 may be a high-electron-mobility transistor (HEMT) with GaAs and GaAlAs, or the like.

The low-resistance regions 314a and 314b contain an element which imparts n-type conductivity, such as arsenic or phosphorus, or an element which imparts p-type conductivity, such as boron, in addition to a semiconductor material used for the semiconductor region 313.

The conductor 316 functioning as a gate electrode can be formed using a semiconductor material such as silicon containing the element which imparts n-type conductivity, such as arsenic or phosphorus, or the element which imparts p-type conductivity, such as boron, or using a conductive material such as a metal material, an alloy material, or a metal oxide material.

Note that the work function of a conductor is determined by a material of the conductor, whereby the threshold voltage can be adjusted. Specifically, it is preferable to use titanium nitride, tantalum nitride, or the like for the conductor. Furthermore, in order to ensure the conductivity and embeddability, it is preferable to use a stacked layer of metal materials such as tungsten and aluminum for the conductor. It is particularly preferable to use tungsten in terms of heat resistance.

Note that the transistor 300 illustrated in FIG. 18 is only an example and the structure of the transistor 300 is not limited to that illustrated in FIG. 18; a transistor appropriate for a circuit configuration or a driving method can be used.

An insulator 320, an insulator 322, an insulator 324, and an insulator 326 are stacked sequentially so as to cover the transistor 300.

The insulator 320, the insulator 322, the insulator 324, and the insulator 326 can be formed using, for example, silicon oxide, silicon oxynitride, silicon nitride oxide, silicon nitride, aluminum oxide, aluminum oxynitride, aluminum nitride oxide, or aluminum nitride.

The insulator 322 may function as a planarization film for eliminating a level difference caused by the transistor 300 or the like underlying the insulator 322. For example, the top surface of the insulator 322 may be planarized by planarization treatment using a chemical mechanical polishing (CMP) method or the like to increase the level of planarity.

The insulator 324 is preferably formed using a film having a barrier property that prevents hydrogen or impurities from the substrate 311, the transistor 300, or the like from diffusing to a region where the transistor 200 is formed.

As an example of the film having a barrier property against hydrogen, a silicon nitride film formed by a CVD method can be given. The diffusion of hydrogen to a semiconductor element including an oxide semiconductor, such as the transistor 200, degrades the characteristics of the semiconductor element in some cases. Therefore, a film that prevents hydrogen diffusion is preferably provided between the transistor 200 and the transistor 300. The film that prevents hydrogen diffusion is specifically a film from which hydrogen is less likely to be released.

The amount of released hydrogen can be measured by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm² in the TDS analysis in the range from 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 times or less that of the insulator 324, further preferably 0.6 times or less that of the insulator 324. In the case where a material with a low permittivity is used for an interlayer film, the parasitic capacitance between wirings can be reduced. A conductor 328, a conductor 330, and the like that are electrically connected to the capacitor 100 or the transistor 200 are provided in the insulator 320, the insulator 322, the insulator 324, and the insulator 326. Note that the conductor 328 and the conductor 330 each function as a plug or a wiring. A plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor serves as a wiring and part of a conductor serves as a plug.

As a material for each of plugs and wirings (e.g., the conductor 328 and the conductor 330), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 18, an insulator 350, an insulator 352, and an insulator 354 are stacked sequentially. Furthermore, a conductor 356 is formed in the insulator 350, the insulator 352, and the insulator 354. The conductor 356 functions as a plug or a wiring. Note that the conductor 356 can be formed using a material similar to those used for forming the conductor 328 and the conductor 330.

Note that the insulator 350 is preferably formed using an insulator having a barrier property against hydrogen, as with the insulator 324, for example. Furthermore, the conductor 356 preferably contains a conductor having a barrier property against hydrogen. In particular, the conductor having a barrier property against hydrogen is formed in an opening of the insulator 350 having a barrier property against hydrogen. In such a structure, the transistor 300 and the transistor 200 can be separated by a barrier layer, so that the diffusion of hydrogen from the transistor 300 to the transistor 200 can be prevented.

Note that as the conductor having a barrier property against hydrogen, tantalum nitride is preferably used, for example. The use of a stack including tantalum nitride and tungsten having high conductivity can inhibit the diffusion of hydrogen from the transistor 300 while the conductivity of a wiring is ensured. In this case, a tantalum nitride layer having a barrier property against hydrogen is preferably in contact with the insulator 350 having a barrier property against hydrogen.

A wiring layer may be provided over the insulator 354 and the conductor 356. For example, in FIG. 18, an insulator 360, an insulator 362, and an insulator 364 are stacked sequentially. Furthermore, a conductor 366 is formed in the insulator 360, the insulator 362, and the insulator 364. The conductor 366 functions as a plug or a wiring. Note that the conductor 366 can be formed using a material similar to those used for forming the conductor 328 and the conductor 330.

Note that the insulator 360 is preferably formed using an insulator having a barrier property against hydrogen, as with the insulator 324, for example. Furthermore, the conductor 366 preferably contains a conductor having a barrier property against hydrogen. In particular, the conductor having a barrier property against hydrogen is formed in an opening of the insulator 360 having a barrier property against hydrogen. In such a structure, the transistor 300 and the transistor 200 can be separated by a barrier layer, so that the diffusion of hydrogen from the transistor 300 to the transistor 200 can be prevented.

A wiring layer may be provided over the insulator 364 and the conductor 366. For example, in FIG. 18, an insulator 370, an insulator 372, and an insulator 374 are stacked sequentially. Furthermore, a conductor 376 is formed in the insulator 370, the insulator 372, and the insulator 374. The conductor 376 functions as a plug or a wiring. Note that the conductor 376 can be formed using a material similar to those used for forming the conductor 328 and the conductor 330.

Note that the insulator 370 is preferably formed using an insulator having a barrier property against hydrogen, as with the insulator 324, for example. Furthermore, the conductor 376 preferably contains a conductor having a barrier property against hydrogen. In particular, the conductor having a barrier property against hydrogen is formed in an opening of the insulator 370 having a barrier property against hydrogen. In such a structure, the transistor 300 and the transistor 200 can be separated by a barrier layer, so that the diffusion of hydrogen from the transistor 300 to the transistor 200 can be prevented.

A wiring layer may be provided over the insulator 374 and the conductor 376. For example, in FIG. 18, an insulator 380, an insulator 382, and an insulator 384 are stacked sequentially. Furthermore, a conductor 386 is formed in the insulator 380, the insulator 382, and the insulator 384. The conductor 386 functions as a plug or a wiring. Note that the conductor 386 can be formed using a material similar to those used for forming the conductor 328 and the conductor 330.

Note that the insulator 380 is preferably formed using an insulator having a barrier property against hydrogen, as with the insulator 324, for example. Furthermore, the conductor 386 preferably contains a conductor having a barrier property against hydrogen. In particular, the conductor having a barrier property against hydrogen is formed in an opening of the insulator 380 having a barrier property against hydrogen. In such a structure, the transistor 300 and the transistor 200 can be separated by a barrier layer, so that the diffusion of hydrogen from the transistor 300 to the transistor 200 can be prevented.

The insulator 210, the insulator 212, the insulator 214, and the insulator 216 are stacked sequentially over the insulator 384. A material having a barrier property against oxygen or hydrogen is preferably used for any of the insulator 210, the insulator 212, the insulator 214, and the insulator 216.

Each of the insulators 210 and 214 is preferably formed using, for example, a film having a barrier property that prevents hydrogen or impurities from the substrate 311, a region where the transistor 300 is formed, or the like from diffusing to a region where the transistor 200 is formed. Therefore, each of the insulators 210 and 214 can be formed using a material similar to that used for forming the insulator 324.

As an example of the film having a barrier property against hydrogen, a silicon nitride film formed by a CVD method can be given. The diffusion of hydrogen to a semiconductor element including an oxide semiconductor, such as the transistor 200, degrades the characteristics of the semiconductor element in some cases. Therefore, a film that prevents hydrogen diffusion is preferably provided between the transistor 200 and the transistor 300. The film that prevents hydrogen diffusion is specifically a film from which hydrogen is less likely to be released.

For the film having a barrier property against hydrogen used for each of the insulators 210 and 214, for example, a metal oxide such as aluminum oxide, hafnium oxide, or tantalum oxide is preferably used.

In particular, aluminum oxide has an excellent blocking effect that prevents permeation of oxygen and impurities such as hydrogen and moisture which cause a change in electrical characteristics of the transistor. Accordingly, the use of aluminum oxide can prevent the entry of impurities such as hydrogen and moisture into the transistor 200 in and after a manufacturing process of the transistor. In addition, release of oxygen from the oxide contained in the transistor 200 can be prevented. Therefore, aluminum oxide is suitably used for a protective film of the transistor 200.

The insulators 212 and 216 can be formed using a material similar to that used for forming the insulator 320, for example. In the case where a material with a relatively low permittivity is used for an interlayer film, the parasitic capacitance between wirings can be reduced. For example, a silicon oxide film, a silicon oxynitride film, or the like can be used for the insulators 212 and 216.

A conductor 218, a conductor (the conductor 205) included in the transistor 200, and the like are provided in the insulators 210, 212, 214, and 216. Note that the conductor 218 functions as a plug or a wiring that is electrically connected to the capacitor 100 or the transistor 300. The conductor 218 can be formed using a material similar to those used for forming the conductors 328 and 330.

In particular, part of the conductor 218 that is in contact with the insulators 210 and 214 is preferably a conductor having a barrier property against oxygen, hydrogen, and water. In such a structure, the transistors 300 and 200 can be completely separated by the layer having a barrier property against oxygen, hydrogen, and water. As a result, the diffusion of hydrogen from the transistor 300 to the transistor 200 can be prevented.

The transistor 200 is provided over the insulator 216. Note that the structure of any of the transistors included in the semiconductor devices described in the above embodiment can be used as the structure of the transistor 200. Note that the transistor 200 in FIG. 18 is only an example of the structure of the transistor 200 is not limited to that illustrated in FIG. 18; a transistor appropriate for a circuit configuration or a driving method can be used.

The insulator 280 is provided over the transistor 200. An insulator 282 is provided over the insulator 280. A material having a barrier property against oxygen or hydrogen is preferably used for the insulator 282. Thus, the insulator 282 can be formed using a material similar to that used for forming the insulator 214. For the insulator 282, a metal oxide such as aluminum oxide, hafnium oxide, or tantalum oxide is preferably used, for example.

In particular, aluminum oxide has an excellent blocking effect that prevents permeation of oxygen and impurities such as hydrogen and moisture which cause a change in electrical characteristics of the transistor. Accordingly, the use of aluminum oxide can prevent the entry of impurities such as hydrogen and moisture into the transistor 200 in and after a manufacturing process of the transistor. In addition, release of oxygen from the oxide contained in the transistor 200 can be prevented. Therefore, aluminum oxide is suitably used for a protective film of the transistor 200.

An insulator 286 is provided over the insulator 282. The insulator 286 can be formed using a material similar to that used for forming the insulator 320. In the case where a material with a relatively low permittivity is used for an interlayer film, the parasitic capacitance between wirings can be reduced. For example, a silicon oxide film, a silicon oxynitride film, or the like can be used for the insulator 286.

A conductor 246, a conductor 248, and the like are provided in the insulators 220, 222, 280, 282, and 286.

The conductors 246 and 248 function as plugs or wirings that are electrically connected to the capacitor 100, the transistor 200, or the transistor 300. The conductors 246 and 248 can be formed using a material similar to those used for forming the conductors 328 and 330.

The capacitor 100 is provided above the transistor 200. The capacitor 100 includes a conductor 110, a conductor 120, and an insulator 130.

A conductor 112 may be provided over the conductors 246 and 248. The conductor 112 functions as a plug or a wiring that is electrically connected to the capacitor 100, the transistor 200, or the transistor 300. The conductor 110 functions as the electrode of the capacitor 100. The conductor 112 and the conductor 110 can be formed at the same time.

The conductor 112 and the conductor 110 can be formed using a metal film containing an element selected from molybdenum, titanium, tantalum, tungsten, aluminum, copper, chromium, neodymium, and scandium; a metal nitride film containing any of the above elements as its component (a tantalum nitride film, a titanium nitride film, a molybdenum nitride film, or a tungsten nitride film); or the like. Alternatively, it is possible to use a conductive material such as an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon oxide is added.

The conductor 112 and the conductor 110 each have a single-layer structure in FIG. 18; however, one embodiment of the present invention is not limited thereto, and a stacked-layer structure of two or more layers may be used. For example, between a conductor having a barrier property and a conductor having high conductivity, a conductor which is highly adhesive to the conductor having a barrier property and the conductor having high conductivity may be formed.

As a dielectric of the capacitor 100, the insulator 130 is provided over the conductors 112 and 110. The insulator 130 can be formed to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like.

A material with high dielectric strength, such as silicon oxynitride, is preferably used for the insulator 130, for example. In the capacitor 100 having such a structure, the dielectric strength can be increased and the electrostatic breakdown of the capacitor 100 can be prevented because of the insulator 130.

Over the insulator 130, the conductor 120 is provided so as to overlap with the conductor 110. Note that the conductor 120 can be formed using a conductive material such as a metal material, an alloy material, or a metal oxide material. It is preferable to use a high-melting-point material which has both heat resistance and conductivity, such as tungsten or molybdenum, and it is particularly preferable to use tungsten. In the case where the conductor 120 is formed concurrently with another component such as a conductor, copper (Cu), aluminum (Al), or the like which is a low-resistance metal material can be used.

An insulator 150 is provided over the conductor 120 and the insulator 130. The insulator 150 can be formed using a material similar to that used for forming the insulator 320. The insulator 150 may function as a planarization film that covers a roughness thereunder.

The above is the description of the structure example. With the use of the structure, a change in electrical characteristics can be prevented and reliability can be improved in a semiconductor device including a transistor including an oxide semiconductor. A transistor including an oxide semiconductor with a high on-state current can be provided. A transistor including an oxide semiconductor with a low off-state current can be provided. A semiconductor device with low power consumption can be provided.

The structures, the methods, and the like described in this embodiment can be combined as appropriate with any of the structures, the methods, and the like described in the other embodiments.

### Embodiment 3

In this embodiment, a frame memory including a semiconductor device of one embodiment of the present invention, which can be used in a display controller IC, a source driver IC, or the like, will be described.

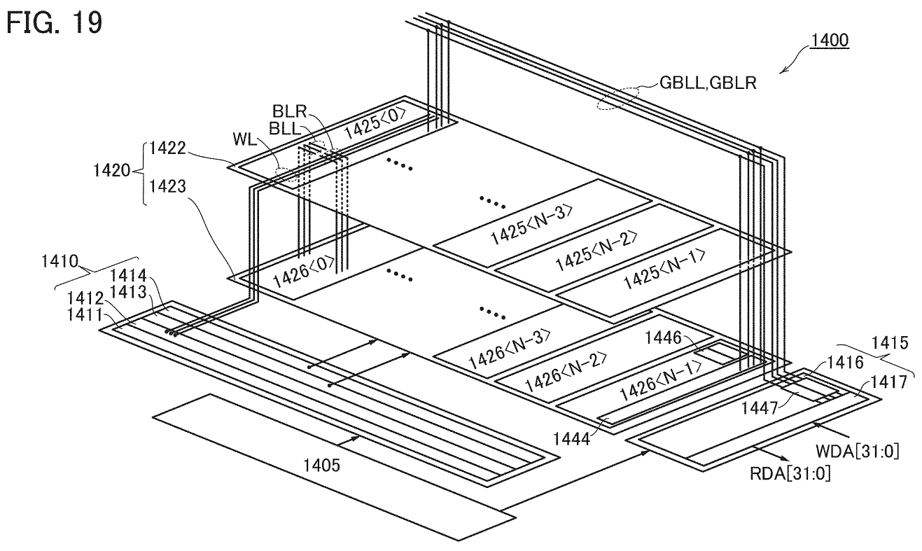

A dynamic random access memory (DRAM) including memory cells of 1T1C (one transistor, one capacitor) type can be used as the frame memory, for example. A memory device in which OS transistors are used in memory cells (the memory device is hereinafter referred to as an OS memory) can also be used. Here, a RAM including memory cells of 1T1C type is described as an example of the OS memory. Such a RAM is herein referred to as a dynamic oxide semiconductor RAM (DOSRAM). FIG. 19 illustrates a configuration example of a DOSRAM.

### <<DOSRAM 1400>>

The DOSRAM 1400 includes a controller 1405, a row circuit 1410, a column circuit 1415, and a memory cell and sense amplifier array 1420 (hereinafter referred to as MC-SA array 1420).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR. (MC-SA array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts a hierarchical bit line structure, where the bit lines are layered into local and global bit lines.

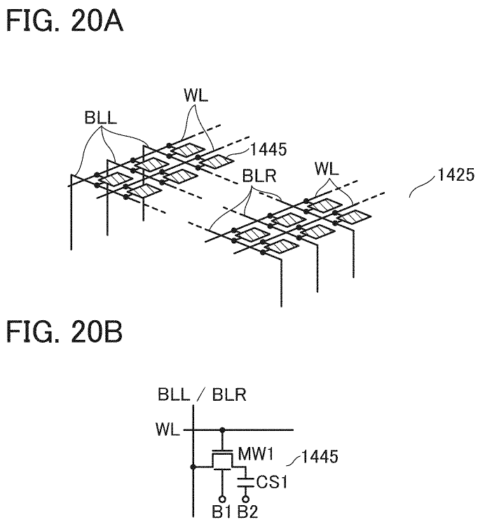

The memory cell array 1422 includes Nlocal memory cell arrays 1425<0> to 1425<N−1>, where N is an integer greater than or equal to 2. FIG. 20A illustrates a configuration example of the local memory cell array 1425. The local memory cell array 1425 includes a plurality of memory cells 1445, a plurality of word lines WL, and a plurality of bit lines BLL and BLR. In the example in FIG. 20A, the local memory cell array 1425 has an open bit-line architecture but may have a folded bit-line architecture.

FIG. 20B illustrates a circuit configuration example of the memory cell 1445. The memory cell 1445 includes a transistor MW1, a capacitor CS1, and terminals B1 and B2. The transistor MW1 has a function of controlling the charging and discharging of the capacitor CS1. A gate of the transistor MW1 is electrically connected to the word line, a first terminal of the transistor MW1 is electrically connected to the bit line, and a second terminal of the transistor MW1 is electrically connected to a first terminal of the capacitor CS1. A second terminal of the capacitor CS1 is electrically connected to the terminal B2. A constant voltage (e.g., low power supply voltage) is applied to the terminal B2.

The transistor MW1 includes a back gate, and the back gate is electrically connected to the terminal B1. This makes it possible to change the threshold voltage of the transistor MW1 with a voltage applied to the terminal B1. For example, a fixed voltage (e.g., negative constant voltage) may be applied to the terminal Bl; alternatively, the voltage applied to the terminal B1 may be changed in response to the operation of the DOSRAM 1400.

The back gate of the transistor MW1 may be electrically connected to the gate, the source, or the drain of the transistor MW1. Alternatively, the transistor MW1 does not necessarily include the back gate.

The sense amplifier array 1423 includes N local sense amplifier arrays 1426<0> to 1426<N−1>. The local sense amplifier array 1426 includes one switch array 1444 and a plurality of sense amplifiers 1446. A bit line pair is electrically connected to the sense amplifier 1446. The sense amplifier 1446 has a function of precharging the bit line pair, a function of amplifying a voltage difference of the bit line pair, and a function of retaining the voltage difference. The switch array 1444 has a function of selecting a bit line pair and electrically connecting the selected bit line pair and a global bit line pair to each other.

Here, two bit lines that are compared simultaneously by the sense amplifier are collectively referred to as the bit line pair. Two global bit lines that are compared simultaneously by the global sense amplifier are collectively referred to as the global bit line pair. The bit line pair can be referred to as a pair of bit lines, and the global bit line pair can be referred to as a pair of global bit lines. Here, a bit line BLL and a bit line BLR form one bit line pair. A global bit line GBLL and a global bit line GBLR form one global bit line pair. In the following description, the expressions “bit line pair (BLL, BLR)” and “global bit line pair (GBLL, GBLR)” are also used.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### (Row Circuit 1410)

The row circuit 1410 has a function of driving the MC-SA array 1420. The decoder 1411 has a function of decoding an address signal. The word line driver circuit 1412 generates a selection signal for selecting the word line WL of a row that is to be accessed.

The column selector 1413 and the sense amplifier driver circuit 1414 are circuits for driving the sense amplifier array 1423. The column selector 1413 has a function of generating a selection signal for selecting the bit line of a column that is to be accessed. The selection signal from the column selector 1413 controls the switch array 1444 of each local sense amplifier array 1426. The control signal from the sense amplifier driver circuit 1414 drives each of the plurality of local sense amplifier arrays 1426 independently.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference of the global bit line pair (GBLL, GBLR), and a function of retaining the voltage difference. Data are written to and read from the global bit line pair (GBLL, GBLR) by the input/output circuit 1417.

The write operation of the DOSRAM 1400 is briefly described. Data are written to the global bit line pair by the input/output circuit 1417. The data of the global bit line pair are retained by the global sense amplifier array 1416. By the switch array 1444 of the local sense amplifier array 1426 specified by the address signal, the data of the global bit line pair are written to the bit line pair of the column where data are to be written. The local sense amplifier array 1426 amplifies the written data, and then retains the amplified data. In the specified local memory cell array 1425, the word line WL of the row where data are to be written is selected by the row circuit 1410, and the data retained at the local sense amplifier array 1426 are written to the memory cell 1445 of the selected row.

The read operation of the DOSRAM 1400 is briefly described. One row of the local memory cell array 1425 is specified with the address signal. In the specified local memory cell array 1425, the word line WL of the row where data are to be read is selected, and data of the memory cell 1445 are written to the bit line. The local sense amplifier array 1426 detects a voltage difference between the bit line pair of each column as data, and retains the data. The switch array 1444 writes the data of a column specified by the address signal to the global bit line pair; the data are chosen from the data retained at the local sense amplifier array 1426. The global sense amplifier array 1416 determines and retains the data of the global bit line pair. The data retained at the global sense amplifier array 1416 are output to the input/output circuit 1417. Thus, the read operation is completed.

The DOSRAM 1400 has no limitations on the number of rewrites in principle and data can be read and written with low energy consumption, because data are rewritten by charging and discharging the capacitor CS1. Simple circuit configuration of the memory cell 1445 allows a high memory capacity.

The transistor MW1 is an OS transistor. The extremely low off-state current of the OS transistor can inhibit leakage of charge from the capacitor CS1. Therefore, the retention time of the DOSRAM 1400 is considerably longer than that of DRAM. This allows less frequent refresh, which can reduce power needed for refresh operations. For this reason, the DOSRAM 1400 used as the frame memory can reduce the power consumption of the display controller IC and the source driver IC.

Since the MC-SA array 1420 has a stacked-layer structure, the bit line can be shortened to a length that is close to the length of the local sense amplifier array 1426. A shorter bit line results in smaller bit line capacitance, which allows the storage capacitance of the memory cell 1445 to be reduced. In addition, providing the switch array 1444 in the local sense amplifier array 1426 allows the number of long bit lines to be reduced. For the reasons described above, a load to be driven during access to the DOSRAM 1400 is reduced, enabling a reduction in the energy consumption of the display controller IC and the source driver IC.

The structure described in this embodiment can be used in appropriate combination with any of the structures described in the other embodiments.

### Embodiment 4

In this embodiment, a field-programmable gate array (FPGA) is described as an example of a semiconductor device in which the transistor whose semiconductor includes an oxide (OS transistor) of one embodiment of the present invention is used. In an FPGA of this embodiment, an OS memory is used for a configuration memory and a register. Here, such an FPGA is referred to as an “OS-FPGA.”

The OS memory is a memory including at least a capacitor and an OS transistor that controls charge and discharge of the capacitor. The OS memory has excellent retention characteristics because the OS transistor has an extremely low off-state current and thus can function as a nonvolatile memory.

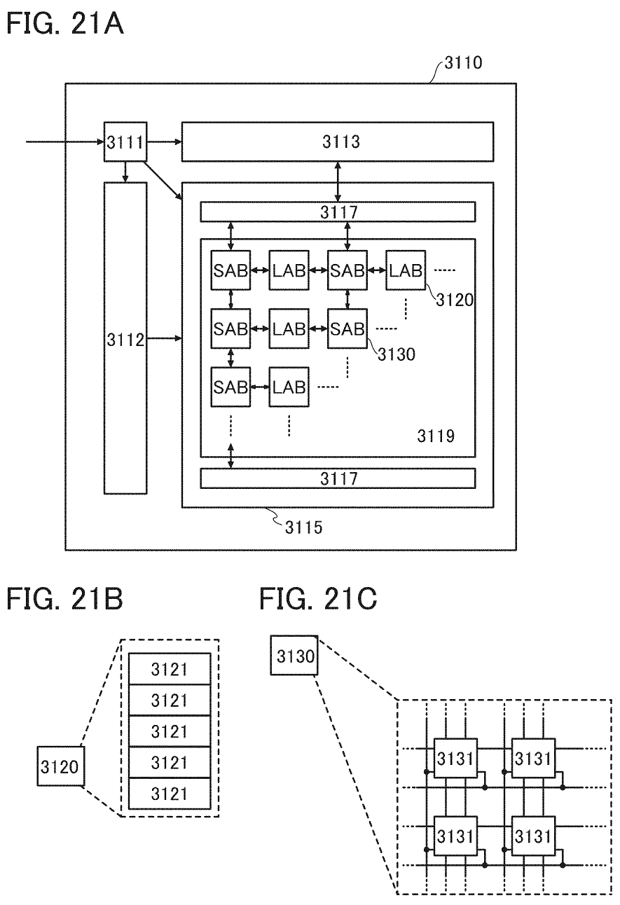

FIG. 21A illustrates a configuration example of an OS-FPGA. An OS-FPGA 3110 illustrated in FIG. 21A is capable of normally-off (NOFF) computing for context switching by a multi-context configuration and fine-grained power gating in each PLE. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of PLEs 3121. FIG. 21B illustrates an example in which the LAB 3120 includes five PLEs 3121. As illustrated in FIG. 21C, the SAB 3130 includes a plurality of switch blocks (SBs) 3131 arranged in array. The LAB 3120 is connected to the LABs 3120 in four directions (on the left, right, top, and bottom sides) through its input terminals and the SABs 3130.

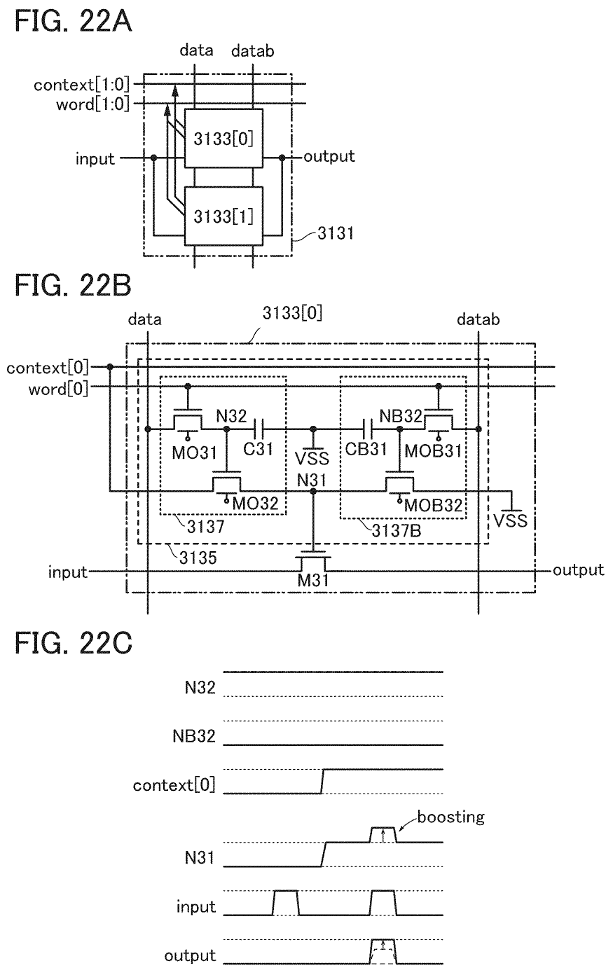

The SB 3131 is described with reference to FIGS. 22A to 22C. To the SB 3131 in FIG. 22A, data, datab, signals context[1:0], and signals word[1:0] are input. The data and the datab are configuration data, and the logics of the data and the datab are complementary to each other. The number of contexts in the OS-FPGA 3110 is two, and the signals context[1:0] are context selection signals. The signals word[1:0] are word line selection signals, and wirings to which the signals word[1: 0] are input are each a word line.

The SB 3131 includes a programmable routing switch (PRS) 3133[0] and a PRS 3133[1]. The PRS 3133[0] and the PRS 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 22B illustrates a circuit configuration example of the PRS 3133[0]. The PRS 3133[0] and the PRS 3133[1] have the same circuit configuration. The PRS 3133[0] and the PRS 3133[1] are different from each other in a context selection signal and a word line selection signal which are input. The signal context[0] and the signal word[0] are input to the PRS 3133[0], and the signal context[1] and the signal word[1] are input to the PRS 3133[1]. For example, in the SB 3131, when the signal context[0] is set to “H,” the PRS 3133[0] is activated.

The PRS 3133[0] includes a CM 3135 and a Si transistor M31. The Si transistor M31 is a pass transistor that is controlled by the CM 3135. The CM 3135 includes a memory circuit 3137 and a memory circuit 3137B. The memory circuit 3137 and the memory circuit 3137B have the same circuit configuration. The memory circuit 3137 includes a capacitor C31, an OS transistor MO31, and an OS transistor M32. The memory circuit 3137B includes a capacitor CB31, an OS transistor MOB31, and an OS transistor MOB32.

The OS transistors MO31, MO32, MOB31, and MOB32 each include a back gate, and these back gates are electrically connected to power supply lines that each apply a fixed voltage.

A gate of the Si transistor M31, a gate of the OS transistor MO32, and a gate of the OS transistor MOB32 correspond to a node N31, a node N32, and a node NB32, respectively. The node N32 and the node NB32 are each a charge retention node of the CM 3135. The OS transistor MO32 controls the conduction state between the node N31 and a signal line for the signal context[0]. The OS transistor MOB32 controls the conduction state between the node N31 and a low-potential power supply line VSS.

A logic of data that the memory circuit 3137 retains and a logic of data that the memory circuit 3137B retains are complementary to each other. Thus, either the OS transistor MO32 or the OS transistor MOB32 is turned on.

The operation example of the PRS 3133[0] is described with reference to FIG. 22C. In the PRS 3133[0], in which configuration data has already been written, the node N32 of the PRS 3133[0] is at “H,” whereas the node NB32 is at “L.”

The PRS 3133[0] is inactivated while the signal context[0] is at “L.” During this period, even when an input terminal of the PRS 3133[0] is transferred to “H,” the gate of the Si transistor M31 is kept at “L” and an output terminal of the PRS 3133[0] is also kept at “L.”

The PRS 3133[0] is activated while the signal context[0] is at “H.” When the signal context[0] is transferred to “H,” the gate of the Si transistor M31 is transferred to “H” by the configuration data stored in the CM 3135.

While the PRS 3133 [0] is active, when the potential of the input terminal is changed to “H,” the gate voltage of the Si transistor M31 is increased by boosting because the OS transistor MO32 of the memory circuit 3137 is a source follower. As a result, the OS transistor MO32 of the memory circuit 3137 loses the driving capability, and the gate of the Si transistor M31 is brought into a floating state.

In the PRS 3133 with a multi-context function, the CM 3135 also functions as a multiplexer.

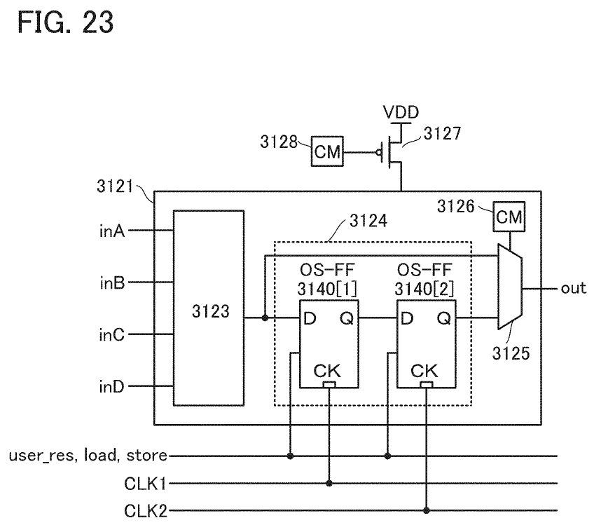

FIG. 23 illustrates a configuration example of the PLE 3121. The PLE 3121 includes a lookup table (LUT) block 3123, a register block 3124, a selector 3125, and a CM 3126. The LUT block 3123 is configured to select and output data in the LUT block in accordance with inputs inA to inD. The selector 3125 selects an output of the LUT block 3123 or an output of the register block 3124 in accordance with the configuration data stored in the CM 3126.

The PLE 3121 is electrically connected to a power supply line for a voltage VDD through a power switch 3127. Whether the power switch 3127 is turned on or off is determined in accordance with configuration data stored in a CM 3128. Fine-grained power gating can be performed by providing the power switch 3127 for each PLE 3121. The PLE 3121 which is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as OS-FF).

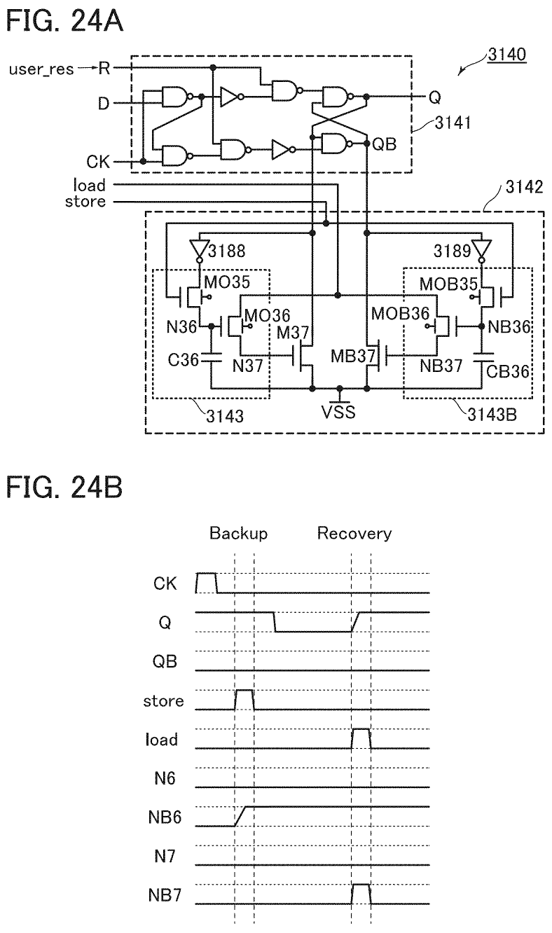

The register block 3124 includes an OS-FF 3140[1] and an OS-FF 3140[2]. A signal user_res, a signal load, and a signal store are input to the OS-FF 3140[1] and the OS-FF 3140[2]. A clock signal CLK1 is input to the OS-FF 3140[1] and a clock signal CLK2 is input to the OS-FF 3140[2]. FIG. 24A illustrates a configuration example of the OS-FF 3140.

The OS-FF 3140 includes a FF 3141 and a shadow register 3142. The FF 3141 includes a node CK, a node R, a node D, a node Q, and a node QB. A clock signal is input to the node CK. The signal user_res is input to the node R. The signal user_res is a reset signal. The node D is a data input node, and the node Q is a data output node. The logics of the node Q and the node QB are complementary to each other.

The shadow register 3142 can function as a backup circuit of the FF 3141. The shadow register 3142 backs up data of the node Q and data of the node QB in response to the signal store and writes back the backed-up data to the node Q and the node QB in response to the signal load.

The shadow register 3142 includes an inverter circuit 3188, an inverter circuit 3189, a Si transistor M37, a Si transistor MB37, a memory circuit 3143, and a memory circuit 3143B. The memory circuit 3143 and the memory circuit 3143B each have the same circuit configuration as the memory circuit 3137 of the PRS 3133. The memory circuit 3143 includes a capacitor C36, an OS transistor MO35, and an OS transistor MO36. The memory circuit 3143B includes a capacitor CB36, an OS transistor MOB35, and an OS transistor MOB36. A node N36 and a node NB36 correspond to a gate of the OS transistor MO36 and a gate of the OS transistor MOB36, respectively, and are each a charge retention node. A node N37 and a node NB37 correspond to a gate of the Si transistor M37 and a gate of the Si transistor MB37, respectively.

The OS transistors MO35, MO36, MOB35, and MOB36 each include a back gate, and these back gates are electrically connected to power supply lines that each apply a fixed voltage.

An example of an operation method of the OS-FF 3140 is described with reference to FIG. 24B.

### (Backup)

When the signal store at “H” is input to the OS-FF 3140, the shadow register 3142 backs up data of the FF 3141. The node N36 shifts to “L” when the data of the node Q is written thereto, and the node NB36 shifts to “H” when the data of the node QB is written thereto. After that, power gating is performed and the power switch 3127 is turned off. Although the data of the node Q and the data of the node QB of the FF 3141 are lost, the shadow register 3142 retains the backed-up data even when power supply is stopped.

### (Recovery)

The power switch 3127 is turned on to supply power to the PLE 3121. After that, when the signal load at “H” is input to the OS -FF 3140, the shadow register 3142 writes back the backed-up data to the FF 3141. The node N37 is kept at “L” because the node N36 is at “L,” and the node NB37 shifts to “H” because the node NB36 is at “H.” Thus, the node Q shifts to “H” and the node QB shifts to “L.” That is, the OS-FF 3140 returns to a state at the backup operation.

A combination of the fine-grained power gating and backup/recovery operation of the OS-FF 3140 allows power consumption of the OS-FPGA 3110 to be effectively reduced.

A possible error in a memory circuit is a soft error due to the entry of radiation. The soft error is a phenomenon in which a malfunction such as inversion of data stored in a memory is caused by electron-hole pair generation when a transistor is irradiated with a rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory including an OS transistor has a high soft-error tolerance. Therefore, the OS-FPGA 3110 including an OS memory can have high reliability.

The structure described in this embodiment can be used in appropriate combination with any of the structures described in the other embodiments.

### Embodiment 5

In this embodiment, an example of a CPU including the semiconductor device of one embodiment of the present invention, such as the above-described memory device, will be described.

### <Configuration of CPU>

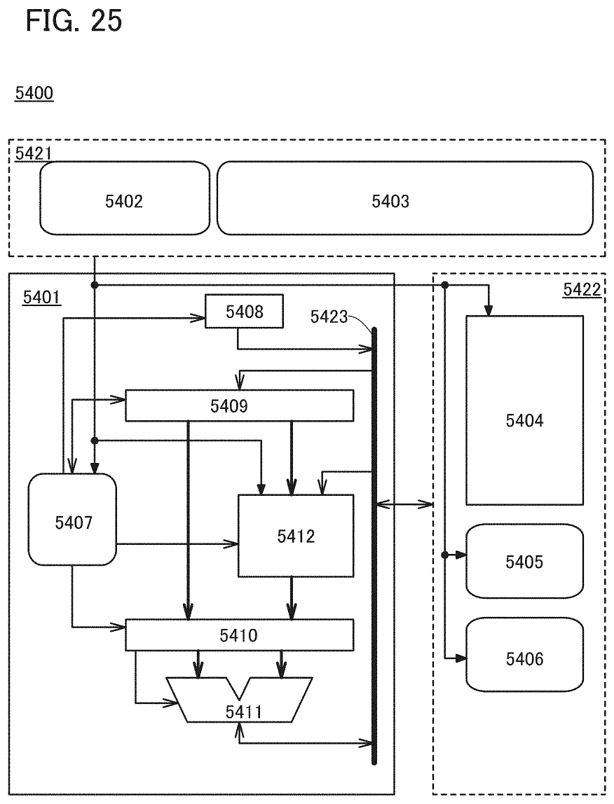

A semiconductor device 5400 illustrated in FIG. 25 includes a CPU core 5401, a power management unit 5421, and a peripheral circuit 5422. The power management unit 5421 includes a power controller 5402 and a power switch 5403. The peripheral circuit 5422 includes a cache 5404 including a cache memory, a bus interface (BUS I/F) 5405, and a debug interface (Debug I/F) 5406. The CPU core 5401 includes a data bus 5423, a control unit 5407, a PC (program counter) 5408, a pipeline register 5409, a pipeline register 5410, an ALU (arithmetic logic unit) 5411, and a register file 5412. Data is transmitted between the CPU core 5401 and the peripheral circuit 5422 such as the cache 5404 via the data bus 5423.

The semiconductor device (cell) can be used for many logic circuits typified by the power controller 5402 and the control unit 5407, particularly for all logic circuits that can be constituted using standard cells. Accordingly, the semiconductor device 5400 can be small. The semiconductor device 5400 can have reduced power consumption. The semiconductor device 5400 can have a higher operating speed. The semiconductor device 5400 can have a smaller power supply voltage variation.

When p-channel Si transistors and the transistor described in the above embodiment which includes an oxide semiconductor (preferably an oxide containing In, Ga, and Zn) in a channel formation region are used in the semiconductor device (cell) and the semiconductor device (cell) is used in the semiconductor device 5400, the semiconductor device 5400 can be small. The semiconductor device 5400 can have reduced power consumption. The semiconductor device 5400 can have a higher operating speed. Particularly when the Si transistors are only p-channel ones, the manufacturing cost can be reduced.

The control unit 5407 has functions of decoding and executing instructions contained in a program such as input applications by controlling the overall operations of the PC 5408, the pipeline registers 5409 and 5410, the ALU 5411, the register file 5412, the cache 5404, the bus interface 5405, the debug interface 5406, and the power controller 5402.

The ALU 5411 has a function of performing a variety of arithmetic operations such as four arithmetic operations and logic operations.

The cache 5404 has a function of temporarily storing frequently used data. The PC 5408 is a register having a function of storing an address of an instruction to be executed next. Note that although not illustrated in FIG. 25, the cache 5404 is provided with a cache controller for controlling the operation of the cache memory.

The pipeline register 5409 has a function of temporarily storing instruction data.

The register file 5412 includes a plurality of registers including a general-purpose register and can store data that is read from the main memory, data obtained as a result of arithmetic operations in the ALU 5411, or the like.

The pipeline register 5410 has a function of temporarily storing data used for arithmetic operations of the ALU 5411, data obtained as a result of arithmetic operations of the ALU 5411, or the like.

The bus interface 5405 has a function of a path for data between the semiconductor device 5400 and various devices outside the semiconductor device 5400. The debug interface 5406 has a function of a path of a signal for inputting an instruction to control debugging to the semiconductor device 5400.

The power switch 5403 has a function of controlling application of a power supply voltage to various circuits included in the semiconductor device 5400 other than the power controller 5402. The above various circuits belong to several different power domains. The power switch 5403 controls whether the power supply voltage is applied to the various circuits in the same power domain. In addition, the power controller 5402 has a function of controlling the operation of the power switch 5403.

The semiconductor device 5400 having the above structure is capable of performing power gating. A description is given of an example of the power gating operation sequence.

First, by the CPU core 5401, timing for stopping the application of the power supply voltage is set in a register of the power controller 5402. Then, an instruction to start power gating is sent from the CPU core 5401 to the power controller 5402. Then, various registers and the cache 5404 included in the semiconductor device 5400 start data saving. Then, the power switch 5403 stops the application of a power supply voltage to the various circuits included in the semiconductor device 5400 other than the power controller 5402. Then, an interrupt signal is input to the power controller 5402, whereby the application of the power supply voltage to the various circuits included in the semiconductor device 5400 is started. Note that a counter may be provided in the power controller 5402 to be used to determine the timing of starting the application of the power supply voltage regardless of input of an interrupt signal. Next, the various registers and the cache 5404 start data restoration. Then, execution of an instruction is resumed in the control unit 5407.

Such power gating can be performed in the whole processor or one or a plurality of logic circuits included in the processor. Furthermore, power supply can be stopped even for a short time. Consequently, power consumption can be reduced at a fine spatial or temporal granularity.

In performing power gating, data held by the CPU core 5401 or the peripheral circuit 5422 is preferably saved in a short time. In that case, the power can be turned on or off in a short time, and an effect of saving power becomes significant.

In order that the data held by the CPU core 5401 or the peripheral circuit 5422 be saved in a short time, the data is preferably saved in a flip-flop circuit itself (referred to as a flip-flop circuit capable of backup operation). Furthermore, the data is preferably saved in an SRAM cell itself (referred to as an SRAM cell capable of backup operation). The flip-flop circuit and SRAM cell which are capable of backup operation preferably include transistors including an oxide semiconductor (preferably an oxide containing In, Ga, and Zn) in a channel formation region. Consequently, the transistor has a low off-state current; thus, the flip-flop circuit and SRAM cell which are capable of backup operation can retain data for a long time without power supply. When the transistor has a high switching speed, the flip-flop circuit and SRAM cell which are capable of backup operation can save and restore data in a short time in some cases.

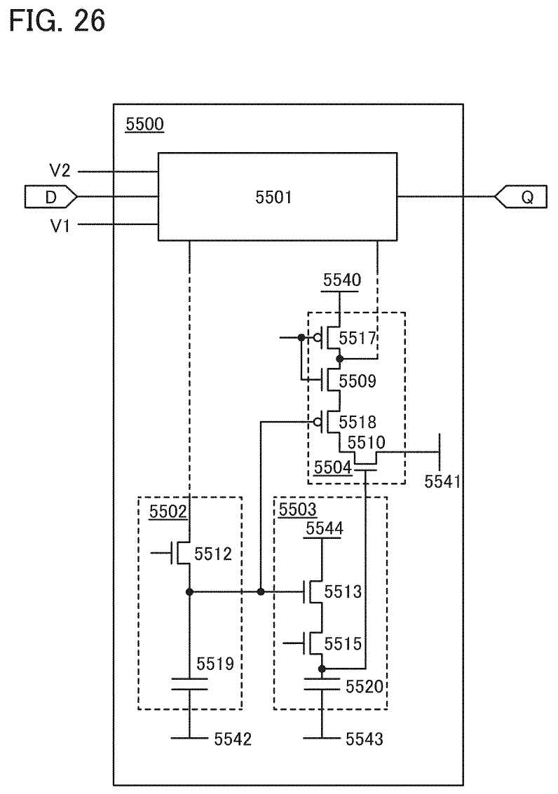

An example of the flip-flop circuit capable of backup operation will be described with reference to FIG. 26.

A semiconductor device 5500 illustrated in FIG. 26 is an example of the flip-flop circuit capable of backup operation. The semiconductor device 5500 includes a first memory circuit 5501, a second memory circuit 5502, a third memory circuit 5503, and a read circuit 5504. As a power supply voltage, a potential difference between a potential V1 and a potential V2 is applied to the semiconductor device 5500. One of the potential V1 and the potential V2 is at a high level, and the other is at a low level. An example of the configuration of the semiconductor device 5500 when the potential V1 is at a low level and the potential V2 is at a high level is described below.

The first memory circuit 5501 has a function of retaining data when a signal D including the data is input in a period during which the power supply voltage is applied to the semiconductor device 5500. Furthermore, the first memory circuit 5501 outputs a signal Q including the retained data in the period during which the power supply voltage is applied to the semiconductor device 5500. On the other hand, the first memory circuit 5501 cannot retain data in a period during which the power supply voltage is not applied to the semiconductor device 5500. That is, the first memory circuit 5501 can be referred to as a volatile memory circuit.

The second memory circuit 5502 has a function of reading the data held in the first memory circuit 5501 to store (or save) it. The third memory circuit 5503 has a function of reading the data held in the second memory circuit 5502 to store (or save) it. The read circuit 5504 has a function of reading the data held in the second memory circuit 5502 or the third memory circuit 5503 to store (or restore) it in the first memory circuit 5501.

In particular, the third memory circuit 5503 has a function of reading the data held in the second memory circuit 5502 to store (or save) it even in the period during which the power supply voltage is not applied to the semiconductor device 5500.

As illustrated in FIG. 26, the second memory circuit 5502 includes a transistor 5512 and a capacitor 5519. The third memory circuit 5503 includes a transistor 5513, a transistor 5515, and a capacitor 5520. The read circuit 5504 includes a transistor 5510, a transistor 5518, a transistor 5509, and a transistor 5517.

The transistor 5512 has a function of charging and discharging the capacitor 5519 in accordance with data held in the first memory circuit 5501. The transistor 5512 is desirably capable of charging and discharging the capacitor 5519 at a high speed in accordance with data held in the first memory circuit 5501. Specifically, the transistor 5512 desirably contains crystalline silicon (preferably polycrystalline silicon, further preferably single crystal silicon) in a channel formation region.

The conduction state or the non-conduction state of the transistor 5513 is determined in accordance with the charge held in the capacitor 5519. The transistor 5515 has a function of charging and discharging the capacitor 5520 in accordance with the potential of a wiring 5544 when the transistor 5513 is in a conduction state. It is desirable that the off-state current of the transistor 5515 be extremely low. Specifically, the transistor 5515 desirably contains an oxide semiconductor (preferably an oxide containing In, Ga, and Zn) in a channel formation region.

Specific connection relations between the elements are described. One of a source and a drain of the transistor 5512 is connected to the first memory circuit 5501. The other of the source and the drain of the transistor 5512 is connected to one electrode of the capacitor 5519, a gate of the transistor 5513, and a gate of the transistor 5518. The other electrode of the capacitor 5519 is connected to a wiring 5542. One of a source and a drain of the transistor 5513 is connected to the wiring 5544. The other of the source and the drain of the transistor 5513 is connected to one of a source and a drain of the transistor 5515. The other of the source and the drain of the transistor 5515 is connected to one electrode of the capacitor 5520 and a gate of the transistor 5510. The other electrode of the capacitor 5520 is connected to a wiring 5543. One of a source and a drain of the transistor 5510 is connected to a wiring 5541. The other of the source and the drain of the transistor 5510 is connected to one of a source and a drain of the transistor 5518. The other of the source and the drain of the transistor 5518 is connected to one of a source and a drain of the transistor 5509. The other of the source and the drain of the transistor 5509 is connected to one of a source and a drain of the transistor 5517 and the first memory circuit 5501. The other of the source and the drain of the transistor 5517 is connected to a wiring 5540. Although a gate of the transistor 5509 is connected to a gate of the transistor 5517 in FIG. 26, the gate of the transistor 5509 is not necessarily connected to the gate of the transistor 5517.

The transistor described in the above embodiment as an example can be used as the transistor 5515. Because of the low off-state current of the transistor 5515, the semiconductor device 5500 can retain data for a long time without power supply. The favorable switching characteristics of the transistor 5515 allow the semiconductor device 5500 to perform high-speed backup and recovery.

The structure described in this embodiment can be used in appropriate combination with any of the structures described in the other embodiments.

### Embodiment 6

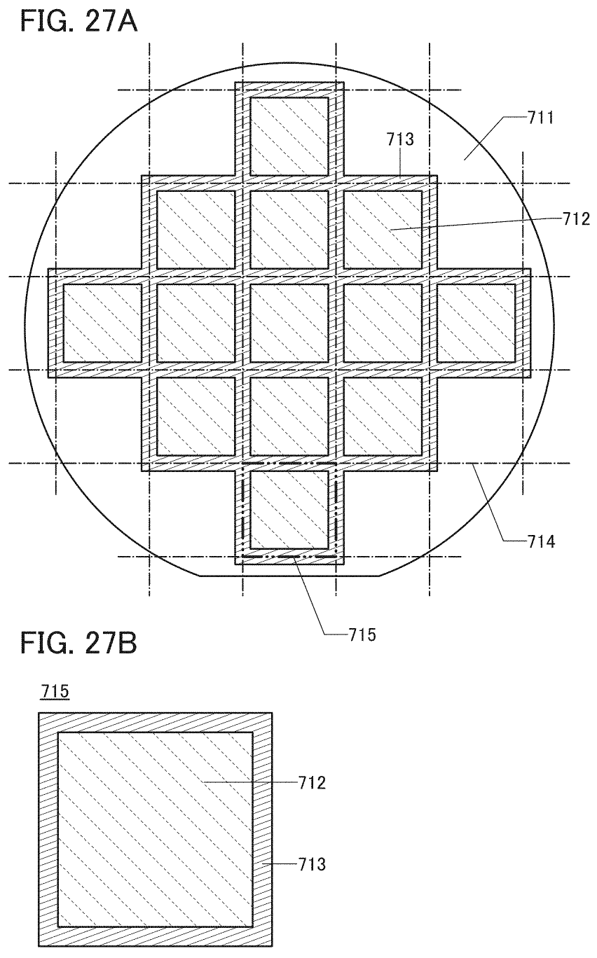

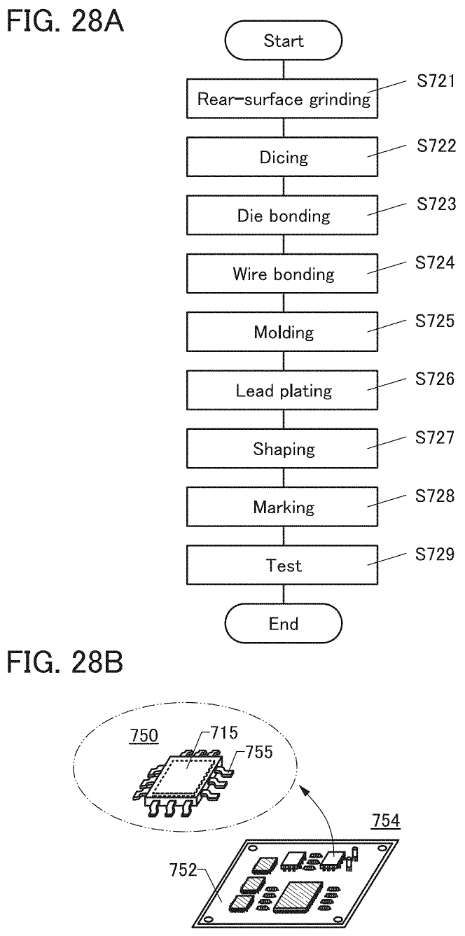

In this embodiment, one mode of a semiconductor device of one embodiment of the present invention will be described with reference to FIGS. 27A and 27B and FIGS. 28A and 28B.

### <Semiconductor Wafer and Chip>

FIG. 27A is a top view of a substrate 711 before dicing treatment. As the substrate 711, a semiconductor substrate (also referred to as a “semiconductor wafer”) can be used, for example. A plurality of circuit regions 712 are provided over the substrate 711. A semiconductor device of one embodiment of the present invention or the like can be provided in the circuit region 712.

Each of the circuit regions 712 is surrounded by a separation region 713. Separation lines (also referred to as “dicing lines”) 714 are set at a position overlapping with the separation regions 713. The substrate 711 can be cut along the separation lines 714 into chips 715 including the circuit regions 712. FIG. 27B is an enlarged view of the chip 715.

A conductive layer, a semiconductor layer, or the like may be provided in the separation regions 713. Providing a conductive layer, a semiconductor layer, or the like in the separation regions 713 relieves ESD that might be caused in a dicing step, preventing a decrease in the yield of the dicing step. A dicing step is generally performed while pure water whose specific resistance is decreased by dissolution of a carbonic acid gas or the like is supplied to a cut portion, in order to cool down the substrate, remove swarf, and prevent electrification, for example. Providing a conductive layer, a semiconductor layer, or the like in the separation regions 713 allows a reduction in the usage of the pure water. Thus, the cost of manufacturing semiconductor devices can be reduced. In addition, semiconductor devices can be manufactured with improved productivity.

### <Electronic Component>

An example of an electronic component using the chip 715 will be described with reference to FIGS. 28A and 28B. Note that an electronic component is also referred to as a semiconductor package or an IC package. For electronic components, there are various standards, names, and the like depending on the direction in which terminals are extracted, the shapes of terminals, and the like.

The electronic component is completed when the semiconductor device described in any of the above embodiments is combined with components other than the semiconductor device in an assembly process (post-process).

The post-process is described with reference to a flow chart in FIG. 28A. After the semiconductor device of one embodiment of the present invention and the like are formed over the substrate 711 in a pre-process, a back surface grinding step in which the back surface (the surface where a semiconductor device and the like are not formed) of the substrate 711 is ground is performed (Step S721). When the substrate 711 is thinned by grinding, the size of the electronic component can be reduced.

Next, the substrate 711 is divided into a plurality of chips 715 in a dicing step (Step S722). Then, the divided chips 715 are individually bonded to a lead frame in a die bonding step (Step S723). To bond the chip 715 and a lead frame in the die bonding step, a method such as resin bonding or tape-automated bonding is selected as appropriate depending on products. Note that the chip 715 may be bonded to an interposer substrate instead of the lead frame.

Next, a wire bonding step for electrically connecting a lead of the lead frame and an electrode on the chip 715 through a metal wire is performed (Step S724). As the metal wire, a silver wire, a gold wire, or the like can be used. Ball bonding or wedge bonding can be used as the wire bonding.

The wire-bonded chip 715 is subjected to a sealing step (molding step) of sealing the chip with an epoxy resin or the like (Step S725). Through the sealing step, the inside of the electronic component is filled with a resin, so that a wire for connecting the chip 715 to the lead can be protected from external mechanical force, and deterioration of characteristics (decrease in reliability) due to moisture or dust can be reduced.

Subsequently, the lead of the lead frame is plated in a lead plating step (Step S726). Through the plating process, corrosion of the lead can be prevented, and soldering for mounting the electronic component on a printed circuit board in a later step can be performed with higher reliability. Then, the lead is cut and processed in a formation step (Step S727).

Next, a printing (marking) step is performed on a surface of the package (Step S728). After a testing step (Step S729) for checking whether an external shape is good and whether there is malfunction, for example, the electronic component is completed.

FIG. 28B is a perspective schematic diagram of a completed electronic component. FIG. 28B illustrates a perspective schematic diagram of a quad flat package (QFP) as an example of an electronic component. An electronic component 750 in FIG. 28B includes a lead 755 and the chip 715. The electronic component 750 may include multiple chips 715.

The electronic component 750 in FIG. 28B is mounted on a printed circuit board 752, for example. A plurality of electronic components 750 are combined and electrically connected to each other over the printed circuit board 752; thus, a circuit board on which the electronic components are mounted (a circuit board 754) is completed. The completed circuit board 754 is provided in an electronic device or the like.

### Embodiment 7

### <Electronic Device>

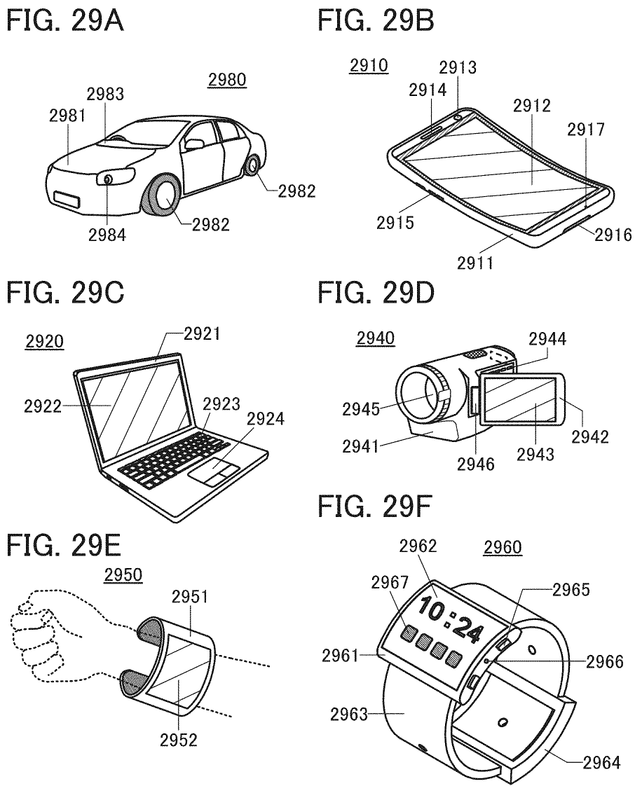

A semiconductor device of one embodiment of the present invention can be used for a variety of electronic devices. FIGS. 29A to 29F each illustrate a specific example of an electronic device including the semiconductor device of one embodiment of the present invention.

FIG. 29A is an external view illustrating an example of a car. An automobile 2980 includes a car body 2981, wheels 2982, a dashboard 2983, lights 2984, and the like. The automobile 2980 also includes an antenna, a battery, and the like.

An information terminal 2910 illustrated in FIG. 29B includes a housing 2911, a display portion 2912, a microphone 2917, a speaker portion 2914, a camera 2913, an external connection portion 2916, an operation switch 2915, and the like. A display panel and a touch screen that use a flexible substrate are provided in the display portion 2912. The information terminal 2910 also includes an antenna, a battery, and the like inside the housing 2911. The information terminal 2910 can be used as, for example, a smartphone, a mobile phone, a tablet information terminal, a tablet personal computer, or an e-book reader.

A notebook personal computer 2920 illustrated in FIG. 29C includes a housing 2921, a display portion 2922, a keyboard 2923, a pointing device 2924, and the like. The notebook personal computer 2920 also includes an antenna, a battery, and the like inside the housing 2921.

A video camera 2940 illustrated in FIG. 29D includes a housing 2941, a housing 2942, a display portion 2943, operation switches 2944, a lens 2945, a joint 2946, and the like. The operation switches 2944 and the lens 2945 are provided on the housing 2941, and the display portion 2943 is provided on the housing 2942. The video camera 2940 also includes an antenna, a battery, and the like inside the housing 2941. The housing 2941 and the housing 2942 are connected to each other with the joint 2946, and the angle between the housing 2941 and the housing 2942 can be changed with the joint 2946. By changing the angle between the housings 2941 and 2942, the orientation of an image displayed on the display portion 2943 can be changed or display and non-display of an image can be switched.

FIG. 29E illustrates an example of a bangle-type information terminal. An information terminal 2950 includes a housing 2951, a display portion 2952, and the like. The information terminal 2950 also includes an antenna, a battery, and the like inside the housing 2951. The display portion 2952 is supported by the housing 2951 having a curved surface. A display panel with a flexible substrate is provided in the display portion 2952, so that the information terminal 2950 can be a user-friendly information terminal that is flexible and lightweight.

FIG. 29F illustrates an example of a watch-type information terminal. An information terminal 2960 includes a housing 2961, a display portion 2962, a band 2963, a buckle 2964, an operation switch 2965, an input/output terminal 2966, and the like. The information terminal 2960 also includes an antenna, a battery, and the like inside the housing 2961. The information terminal 2960 is capable of executing a variety of applications such as mobile phone calls, e-mailing, text viewing and editing, music reproduction, Internet communication, and computer games.

The display surface of the display portion 2962 is curved, and images can be displayed on the curved display surface. Furthermore, the display portion 2962 includes a touch sensor, and operation can be performed by touching the screen with a finger, a stylus, or the like. For example, an application can be started by touching an icon 2967 displayed on the display portion 2962. With the operation switch 2965, a variety of functions such as time setting, on/off of the power, on/off of wireless communication, setting and cancellation of a silent mode, and setting and cancellation of a power saving mode can be performed. The functions of the operation switch 2965 can be set by setting the operating system incorporated in the information terminal 2960, for example.

The information terminal 2960 can employ near field communication that is a communication method based on an existing communication standard. In that case, for example, mutual communication between the information terminal 2960 and a headset capable of wireless communication can be performed, and thus hands-free calling is possible. Moreover, the information terminal 2960 includes the input/output terminal 2966, and data can be directly transmitted to and received from another information terminal via a connector. Power charging through the input/output terminal 2966 is also possible. The charging operation may be performed by wireless power feeding without using the input/output terminal 2966.

A memory device including the semiconductor device of one embodiment of the present invention, for example, can hold control data, a control program, or the like of the above electronic device for a long time. With the use of the semiconductor device of one embodiment of the present invention, a highly reliable electronic device can be provided.

This embodiment can be implemented in an appropriate combination with any of the structures described in the other embodiments and Example.

### EXAMPLE 1

In this example, the results of computational verification of the characteristics of transistors in one embodiment of the present invention will be described. Specifically, the characteristics of five transistors whose oxide semiconductors including channel formation regions have different thicknesses were compared. For the calculation, device simulation software Atlas (produced by Silvaco, Inc.) was used.

For the calculation, the transistors were each assumed to have a channel length L of 60 nm and a channel width W of 70 nm. The thicknesses of the oxide semiconductors were assumed to be 20 nm, 35 nm, 50 nm, 65 nm, and 105 nm. The table below shows specific conditions for the oxide semiconductors.

TABLE 1

| Electron affinity | 4.8 | eV |
|---|---|---|
| Eg | 2.9 | eV |
| Relative permittivity | 15 | |
| Electron mobility | 30 | cm²/Vs |
| Hole mobility | 0.01 | cm²/Vs |
| Nc | 5.0E+18 | cm⁻³ |
| Nv | 5.0E+18 | cm⁻³ |

In each of the transistors, the relative permittivity of a top gate insulator provided between a top gate and the oxide semiconductor was 4.1 and the thickness of the top gate insulator was 10 nm. In addition, a back gate insulator provided between a back gate and the oxide semiconductor was assumed to have a three-layer stacked structure including a first insulator over the back gate, a second insulator over the first insulator, and a third insulator over the second insulator. Note that the relative permittivity of the first insulator was 4.1 and the thickness thereof was 10 nm. The relative permittivity of the second insulator was 16.4 and the thickness thereof was 20 nm. The relative permittivity of the third insulator was 4.1 and the thickness thereof was 30 nm.

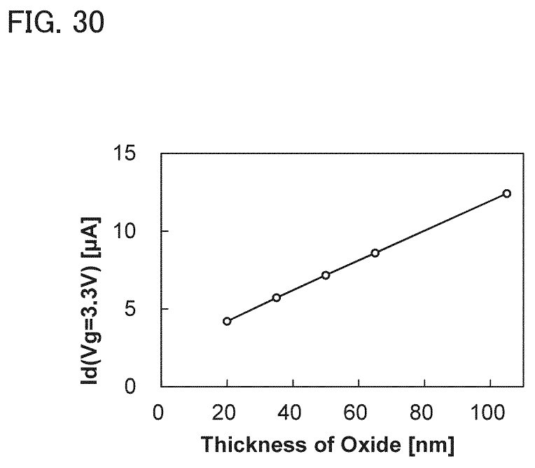

FIG. 30 shows the calculation results of the on-state current of the transistors when 3.3 V was applied to the top gate, −6.0 V was applied to the back gate, 0.1 V was applied to one of a source region and a drain region, and 0.0 V was applied to the other of the source region and the drain region. FIG. 30 indicates that the larger the thickness of the oxide semiconductor is, the higher the on-state current is.

At least part of the structure, method, and the like described in this example can be implemented in appropriate combination with any of those in the embodiments described in this specification.

### REFERENCE NUMERALS

100: capacitor, 110: conductor, 112: conductor, 120: conductor, 130: insulator, 150: insulator, 200: transistor, 203: conductor, 203a: conductor, 203b: conductor, 205: conductor, 205a: conductor, 205b: conductor, 210: insulator, 212: insulator, 214: insulator, 216: insulator, 218: conductor, 220: insulator, 222: insulator, 224: insulator, 230: oxide, 230a: oxide, 230A: oxide film, 230b: oxide, 230b1: layer, 230b2: layer, 230B: oxide film, 230c: oxide, 231: region, 231a: region, 231b: region, 232: region, 232a: region, 232b: region, 233: region, 233a: region, 233b: region, 234: region, 235: insulator, 239: region, 246: conductor, 248: conductor, 250: insulator, 250A: insulating film, 252: conductor, 252a: conductor, 252b: conductor, 260: conductor, 260a: conductor, 260A: conductive film, 260b: conductor, 260B: conductive film, 270: insulator, 270A: insulating film, 272: insulator, 272A: insulating film, 274: insulator, 280: insulator, 282: insulator, 286: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 360: insulator, 362: insulator, 364: insulator, 366: conductor, 370: insulator, 372: insulator, 374: insulator, 376: conductor, 380: insulator, 382: insulator, 384: insulator, 386: conductor, 711: substrate, 712: circuit region, 713: separation region, 714: separation line, 715: chip, 750: electronic component, 752: printed circuit board, 754: circuit board, 755: lead, 1400: DOSRAM, 1405: controller, 1410: row circuit, 1411: decoder, 1412: word line driver circuit, 1413: column selector, 1414: sense amplifier driver circuit, 1415: column circuit, 1416: global sense amplifier array, 1417: input/output circuit, 1420: memory cell and sense amplifier array, 1422: memory cell array, 1423: sense amplifier array, 1425: local memory cell array, 1426: local sense amplifier array, 1444: switch array, 1445: memory cell, 1446: sense amplifier, 1447: global sense amplifier, 2910: information terminal, 2911: housing, 2912: display portion, 2913: camera, 2914: speaker portion, 2915: operation switch, 2916: external connection portion, 2917: microphone, 2920: notebook personal computer, 2921: housing, 2922: display portion, 2923: keyboard, 2924: pointing device, 2940: video camera, 2941: housing, 2942: housing, 2943: display portion, 2944: operation switch, 2945: lens, 2946: joint, 2950: information terminal, 2951: housing, 2952: display portion, 2960: information terminal, 2961: housing, 2962: display portion, 2963: band, 2964: buckle, 2965: operation switch, 2966: input-output terminal, 2967: icon, 2980: automobile, 2981: car body, 2982: wheel, 2983: dashboard, 2984: light, 3001: wiring, 3002: wiring, 3003: wiring, 3004: wiring, 3005: wiring, 3006: wiring, 3110: OS-FPGA, 3111: controller, 3112: word driver, 3113: data driver, 3115: programmable area, 3117: JOB, 3119: core, 3120: LAB, 3121: PLE, 3123: LUT block, 3124: register block, 3125: selector, 3126: CM, 3127: power switch, 3128: CM, 3130: SAB, 3131: SB, 3133: PRS, 3135: CM, 3137: memory circuit, 3137B: memory circuit, 3140: OS-FF, 3141: FF, 3142: shadow register, 3143: memory circuit, 3143B: memory circuit, 3188: inverter circuit, 3189: inverter circuit, 5400: semiconductor device, 5401: CPU core, 5402: power controller, 5403: power switch, 5404: cache, 5405: bus interface, 5406: debug interface, 5407: control unit, 5408: PC, 5409: pipeline register, 5410: pipeline register, 5411: ALU, 5412: register file, 5421: power management unit, 5422: peripheral circuit, 5423: data bus, 5500: semiconductor device, 5501: memory circuit, 5502: memory circuit, 5503: memory circuit, 5504: circuit, 5509: transistor, 5510: transistor, 5512: transistor, 5513: transistor, 5515: transistor, 5517: transistor, 5518: transistor, 5519: capacitor, 5520: capacitor, 5540: wiring, 5541: wiring, 5542: wiring, 5543: wiring, and 5544: wiring.

This application is based on Japanese Patent Application Serial No. 2016-253737 filed with Japan Patent Office on Dec. 27, 2016, the entire contents of which are hereby incorporated by reference.

1. A semiconductor device comprising:
a first conductor over a substrate;
a first insulator over the first conductor;
a first oxide over the first insulator;
a second oxide over the first oxide;
a second insulator in contact with a top surface of the second oxide and a side surface of the second oxide;
a second conductor over the second insulator, the second conductor comprising a region facing the top surface of the second oxide and the side surface of the second oxide with the second insulator positioned therebetween; and
a third insulator in contact with a side surface of the second insulator and a side surface of the second conductor,
wherein a thickness of the second oxide is greater than or equal to a length of the second oxide in a channel width direction, and
wherein a carrier density of the side surface of the second oxide is higher than a carrier density of the top surface of the second oxide.

2. The semiconductor device according to claim 1, wherein the second oxide comprises a curved surface between the side surface of the second oxide and the top surface of the second oxide.

3. The semiconductor device according to claim 2, wherein the curved surface of the second oxide has a radius of curvature greater than or equal to 3 nm and less than or equal to 10 nm.

4. The semiconductor device according to claim 1, wherein a conduction band minimum of the first oxide is higher than a conduction band minimum of the second oxide.

5. The semiconductor device according to claim 1, wherein the second insulator has a smaller thickness in a region near the side surface of the second oxide than in a region near the top surface of the second oxide.

6. The semiconductor device according to claim 1, wherein each of the first oxide and the second oxide has a tapered cross-sectional shape.

7. The semiconductor device according to claim 1, wherein the second oxide comprises a crystal structure having c-axis alignment.

8. The semiconductor device according to claim 1,
wherein the second oxide comprises alternately stacked first layers and second layers, and
wherein a band gap of each of the first layers is larger than a band gap of each of the second layers.

9. The semiconductor device according to claim 1,
wherein each of the first oxide and the second oxide comprises In, an element M, and Zn,
wherein the element M is Al, Ga, Y, or Sn, and
wherein an atomic ratio of In to the element M in the second oxide is greater than an atomic ratio of In to the element M in the first oxide.

10. A semiconductor device comprising:
a first conductor over a substrate;
a first insulator over the first conductor;
a first oxide over the first insulator;
a second oxide over the first oxide;
a third oxide in contact with a side surface of the first oxide and a side surface of the second oxide;
a second insulator in contact with a top surface of the second oxide and a side surface of the third oxide;
a second conductor over the second insulator, the second conductor comprising a region facing the top surface of the second oxide and the side surface of the second oxide with the second insulator positioned therebetween; and
a third insulator in contact with a side surface of the second insulator and a side surface of the second conductor,
wherein a thickness of the second oxide is greater than or equal to a length of the second oxide in a channel width direction, and
wherein a carrier density of the side surface of the second oxide is higher than a carrier density of the top surface of the second oxide.

11. The semiconductor device according to claim 10, wherein the second oxide comprises a curved surface between the side surface of the second oxide and the top surface of the second oxide.

12. The semiconductor device according to claim 11, wherein the curved surface of the second oxide has a radius of curvature greater than or equal to 3 nm and less than or equal to 10 nm.

13. The semiconductor device according to claim 10, wherein a conduction band minimum of each of the first oxide and the third oxide is higher than a conduction band minimum of the second oxide.

14. The semiconductor device according to claim 10, wherein the second insulator has a smaller thickness in a region near the side surface of the third oxide than in a region near the top surface of the second oxide.

15. The semiconductor device according to claim 10, wherein the second oxide comprises a crystal structure having c-axis alignment.

16. The semiconductor device according to claim 10,
wherein each of the first oxide, the second oxide, and the third oxide comprises In, an element M, and Zn,
wherein the element M is Al, Ga, Y, or Sn, and
wherein an atomic ratio of In to the element M in the second oxide is greater than an atomic ratio of In to the element M in each of the first oxide and the third oxide.
